(19) United States
(12) Patent Application Publication
(10) Pub. No.: US 2025/0098187 A1
(43) Pub. Date: Mar. 20, 2025

(54) SEMICONDUCTOR MEMORY CELL STRUCTURE INCLUDING A HYDROGEN ABSORPTION LAYER

(71) Applicant: Taiwan Semiconductor Manufacturing Company, Ltd., Hsinchu (TW)

(72) Inventors: Yu-Chien CHIU, Hsinchu County (TW); Chen-Han CHOU, Tainan City (TW); Ya-Yun CHENG, Taichung City (TW); Ya-Chun CHANG, Hsinchu County (TW); Wen-Ling LU, Taoyuan County (TW); Yu-Kai CHANG, Hsinchu City (TW); Pei-Chun LIAO, Ju-Bei City (TW); Chung-Wei WU, Ju-Bei City (TW)

(21) Appl. No.: 18/469,094

(22) Filed: Sep. 18, 2023

(51) Int. Cl. H10B 12/00

(52) U.S. Cl. CPC H10D 1/696; H10B 12/0335; H10B 12/315

(57) ABSTRACT

A memory cell structure includes a transistor structure and a capacitor structure, where the capacitor structure includes a hydrogen absorption layer. The hydrogen absorption layer absorbs hydrogen, which prevents or reduces the likelihood of the hydrogen diffusing into an underlying metal-oxide channel of the transistor structure. In this way, the hydrogen absorption layer minimizes and/or reduces the likelihood of hydrogen contamination in the metal-oxide channel, which may enable a low current leakage to be achieved for the memory cell structure and reduces the likelihood of data corruption and/or failure of the memory cell structure, among other examples.

### BACKGROUND

Memory devices are used in a wide variety of applications. Memory devices are made up of a plurality of memory cells that are typically arranged in an array of a plurality of rows and a plurality of columns. One type of memory cell includes a dynamic random access memory (DRAM) cell. In some applications, a DRAM cell-based memory device may be selected as opposed to other types of memory cell-based memory devices due to DRAM cells' lower cost, smaller area, and ability to hold a greater amount of data relative to, for example, a static random access memory (SRAM) cell or another type of memory cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of an example semiconductor device described herein.

FIGS. 3A-3C are diagrams of examples of parameters associated with a memory cell structure that includes a hydrogen absorption layer described herein.

FIGS. 4A-4T are diagrams of an example implementation of forming a memory cell structure of the semiconductor device described herein.

FIGS. 5A-5C are diagrams of an example semiconductor device described herein.

FIGS. 6A-6F are diagrams of an example implementation of forming a memory cell structure of the semiconductor device described herein.

FIGS. 7A-7C are diagrams of an example semiconductor device described herein.

FIGS. 8A-8O are diagrams of an example implementation of forming a memory cell structure of the semiconductor device described herein.

FIGS. 9A-9C are diagrams of an example semiconductor device described herein.

FIGS. 10A-10F are diagrams of an example implementation of forming a memory cell structure of the semiconductor device described herein.

FIG. 11 is a diagram of example components of a device described herein.

FIG. 12 is a flowchart of an example process associated with forming a memory cell structure described herein.

FIGS. 13A-13C are diagrams of an example semiconductor device described herein.

FIGS. 14A-14H are diagrams of an example implementation of forming a memory cell structure of the semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A dynamic random access memory (DRAM) memory cell is a type of volatile memory cell that typically includes a transistor connected in series with a capacitor. This may be referred to as a one transistor-one capacitor (1T-1C) DRAM cell. The capacitor in a 1T-1C DRAM cell functions as a storage device by selectively storing electric charge. The capacitor may be charged through the transistor, and the amount of charge that is stored in the capacitor may be sensed by discharging the charge that is stored by the capacitor. The logical value (e.g., a 1-value or a 0-value) stored by the 1T-1C DRAM cell may correspond to the amount of charge that is stored by the capacitor.

In some cases, the transistor of a 1T-1C DRAM cell may include a metal-oxide channel (e.g., a channel layer that includes a metal-oxide material). The use of a metal-oxide channel may provide reduced current leakage in the 1T-1C DRAM cell relative to an elemental semiconductor channel or a III-V compound semiconductor channel, which may improve charge retention (and thus, data retention) in the capacitor of the 1T-1C DRAM cell. However, metal-oxide materials are highly susceptible to hydrogen contamination. If hydrogen diffuses into the metal-oxide channel of the 1T-1C DRAM cell, charge carrier concentration can increase in the metal-oxide channel. The increased charge carrier concentration can cause increased off-current leakage for the 1T-1C DRAM cell, increased positive bias temperature instability (PBTI), and/or increased negative bias temperature instability (NBTI). Additionally and/or alternatively, hydrogen contamination in the metal-oxide channel can increase the charge carrier concentration to a point where the 1T-1C DRAM cell becomes stuck in a normally-on configuration, thereby rendering the 1T-1C DRAM cell non-operational.

In some implementations described herein, a memory cell structure (e.g., a 1T-1C DRAM cell or another type of memory cell structure) includes a transistor structure and a capacitor structure, where the capacitor structure includes a hydrogen absorption layer. The hydrogen absorption layer absorbs hydrogen such as atmospheric hydrogen and/or hydrogen that is used in various types of deposition processes such as plasma enhanced chemical vapor deposition (PE-CVD) and atomic layer deposition (ALD). The hydrogen absorption layer absorbs the hydrogen, which prevents or reduces the likelihood of the hydrogen diffusing into the underlying metal-oxide channel of the transistor structure. In this way, the hydrogen absorption layer minimizes and/or reduces the likelihood of hydrogen contamination in the metal-oxide channel, which may enable a low current leakage to be achieved for the memory cell structure, and reduces the likelihood of data corruption and/or failure of the memory cell structure, among other examples.

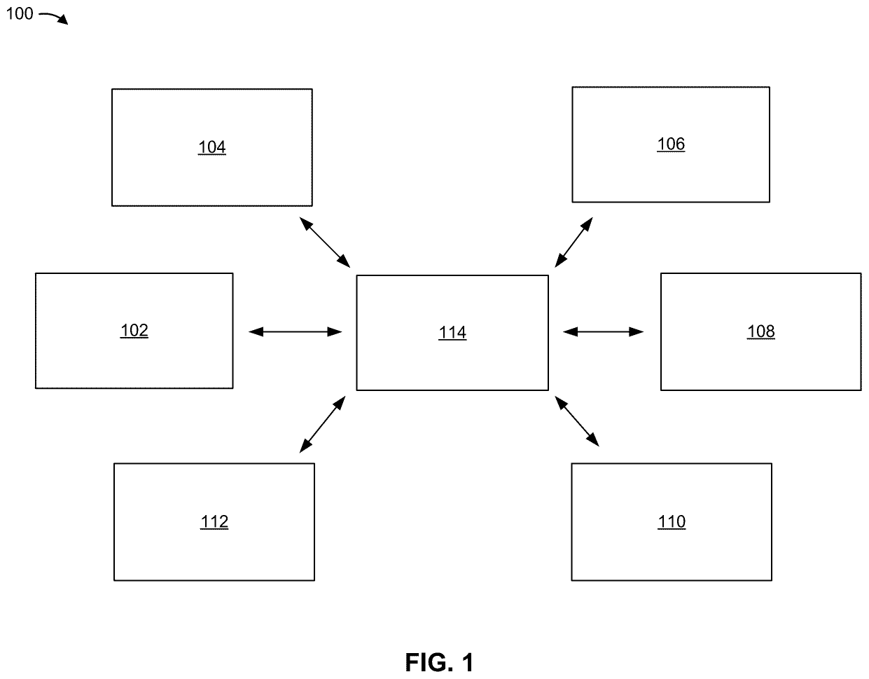

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

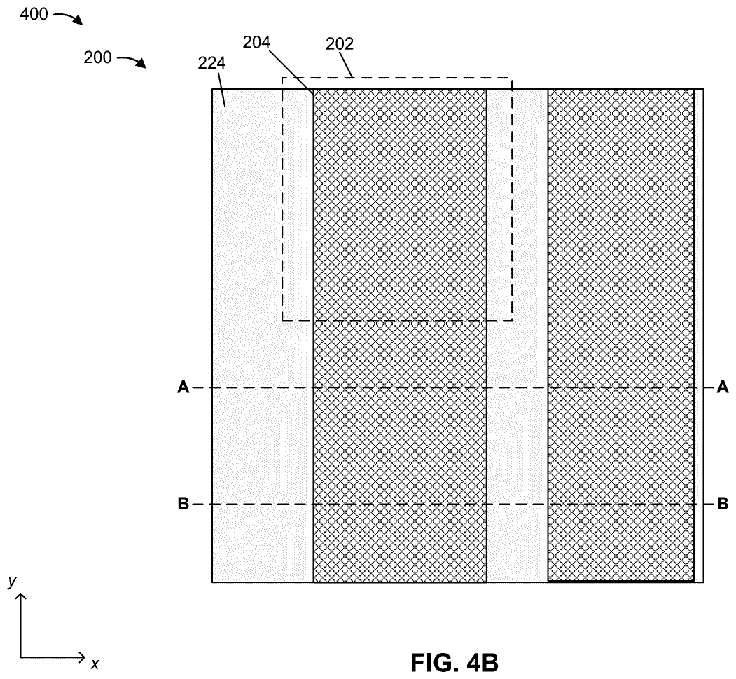

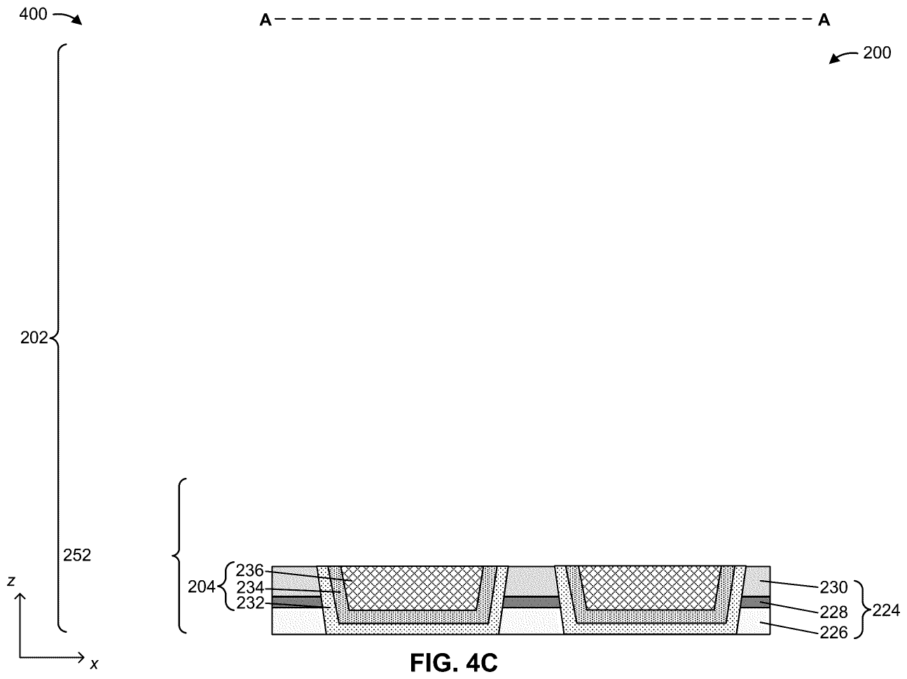

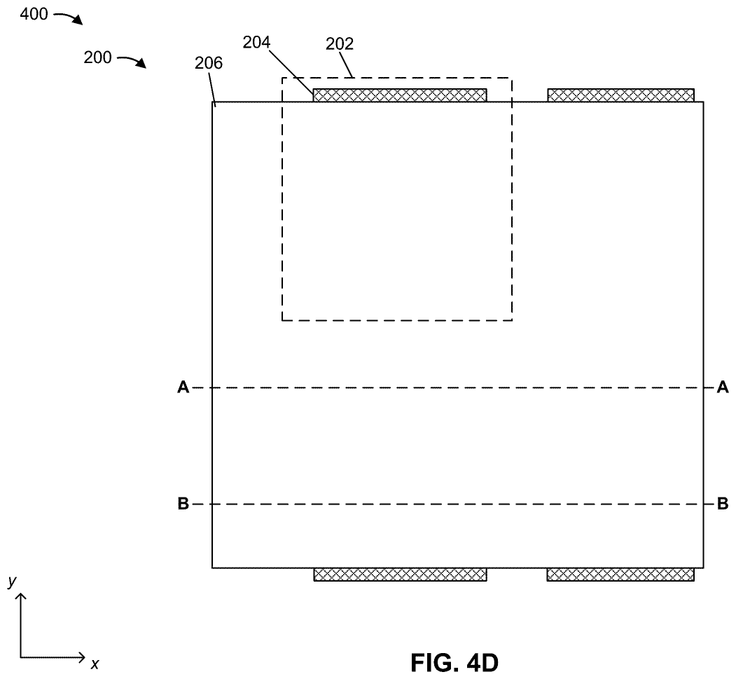

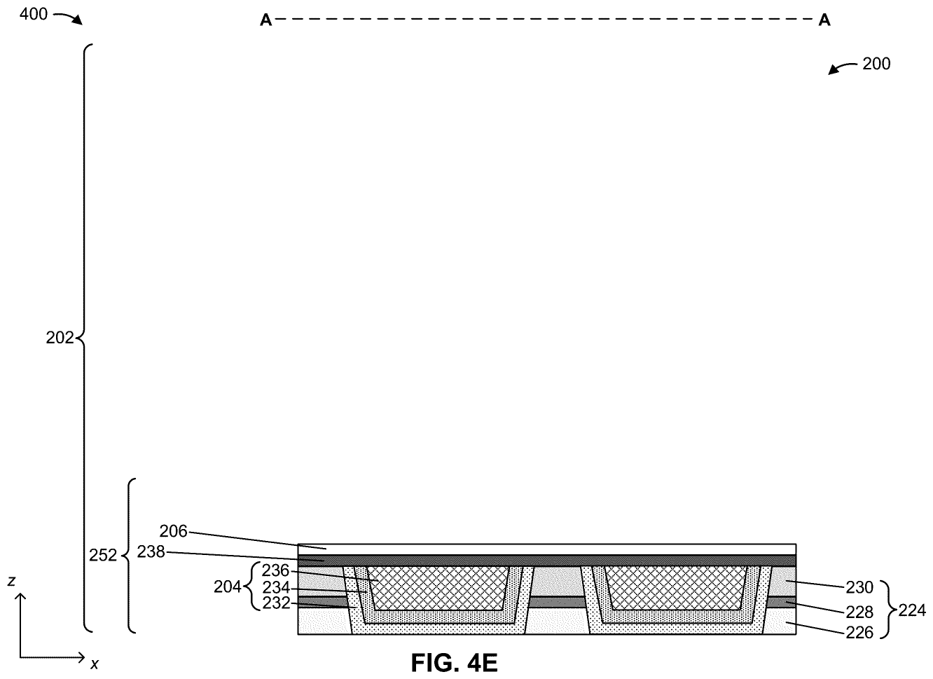

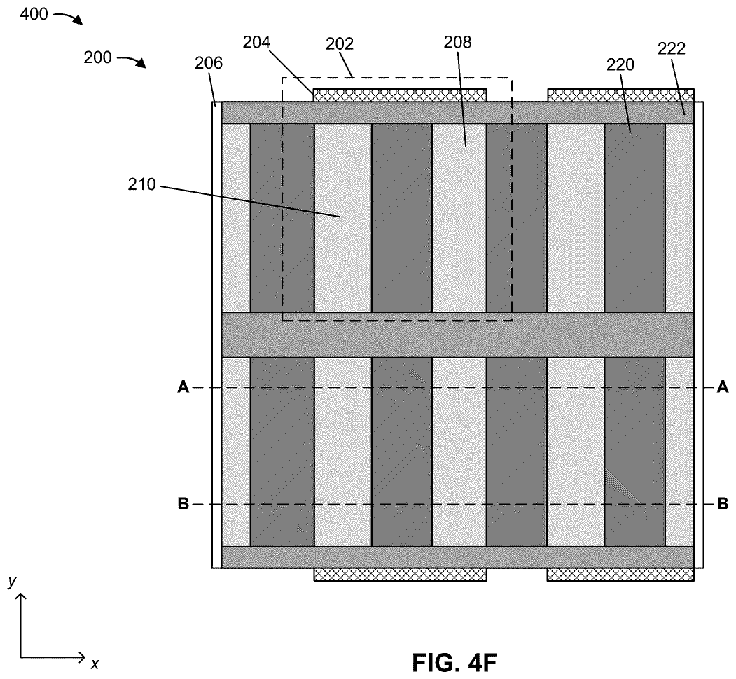

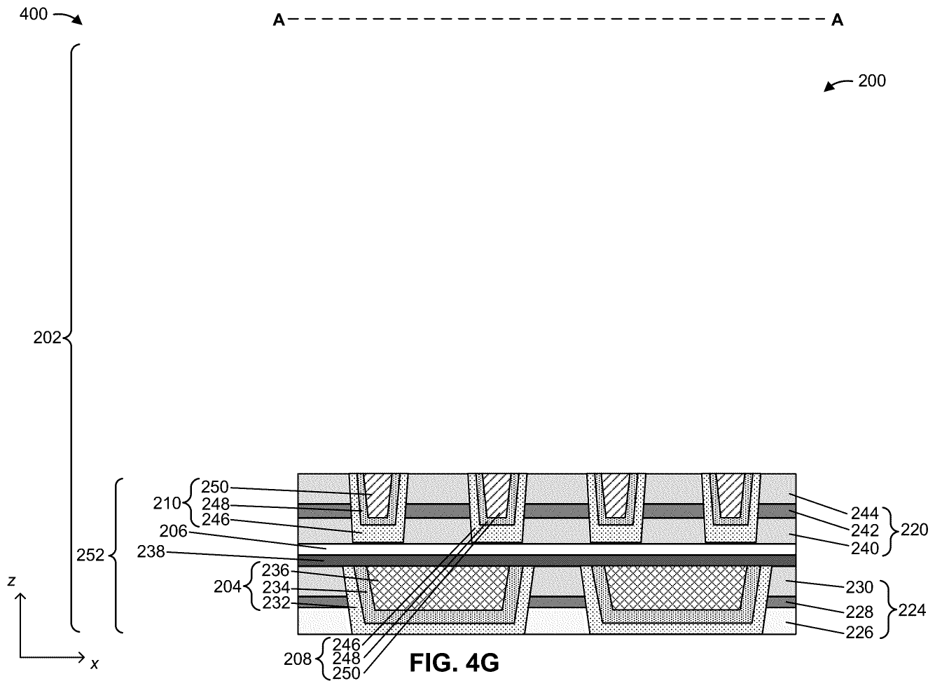

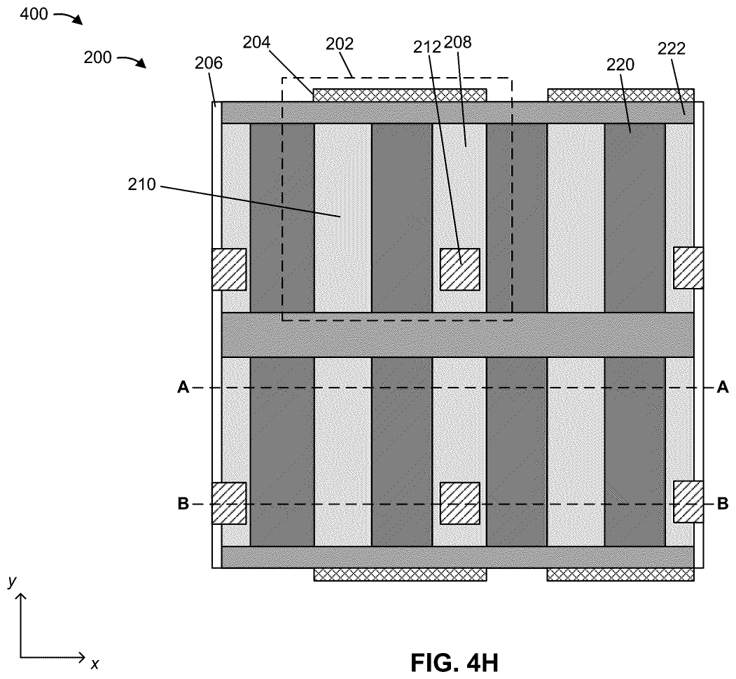

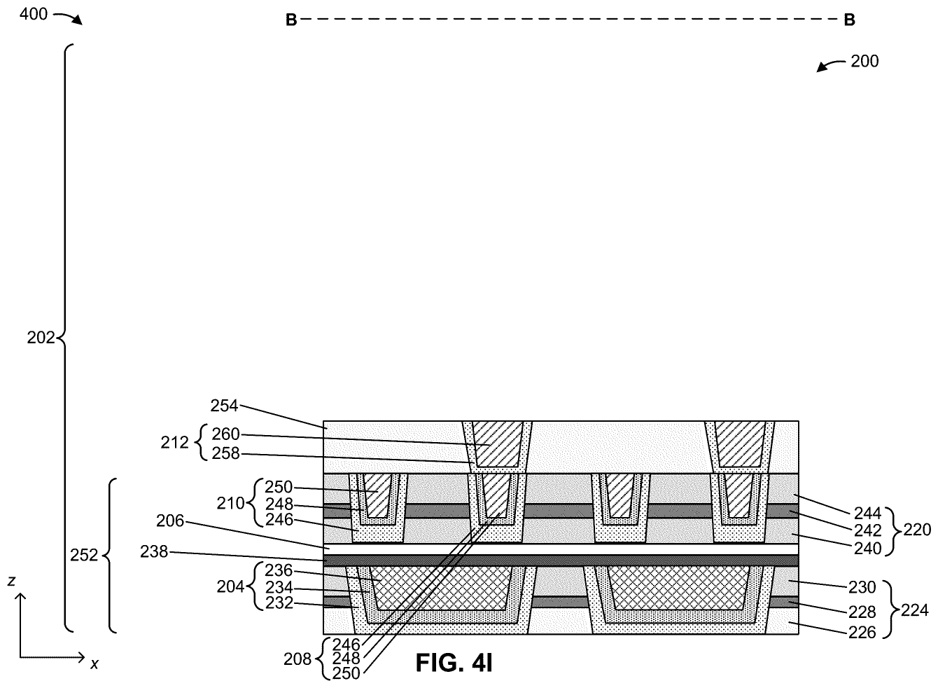

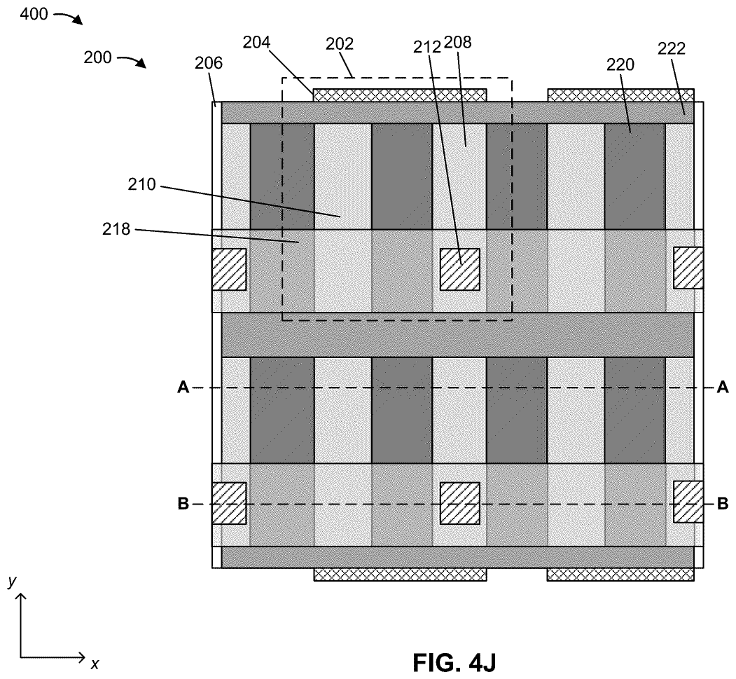

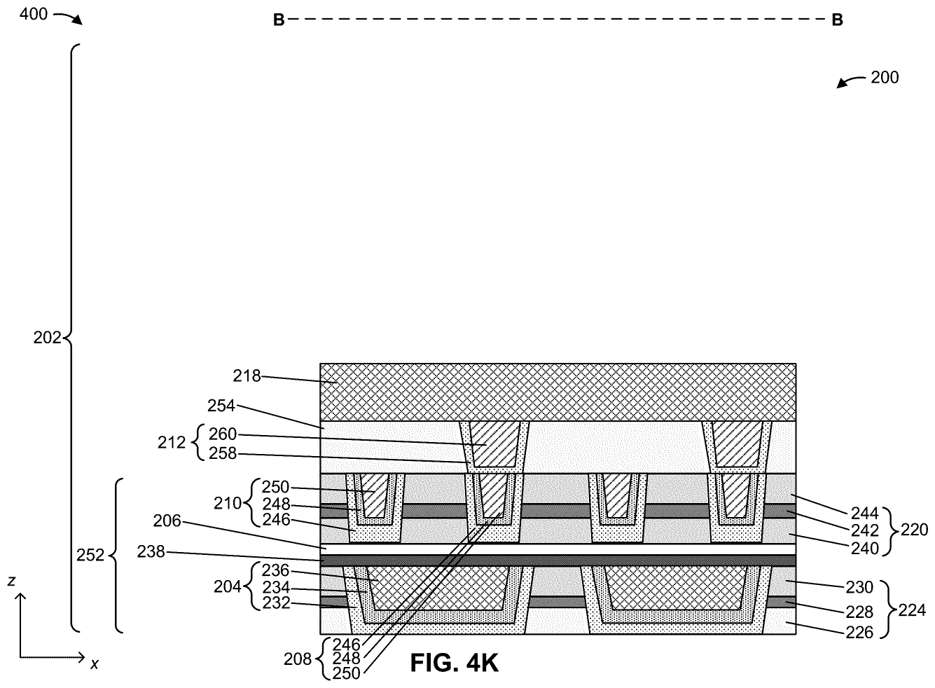

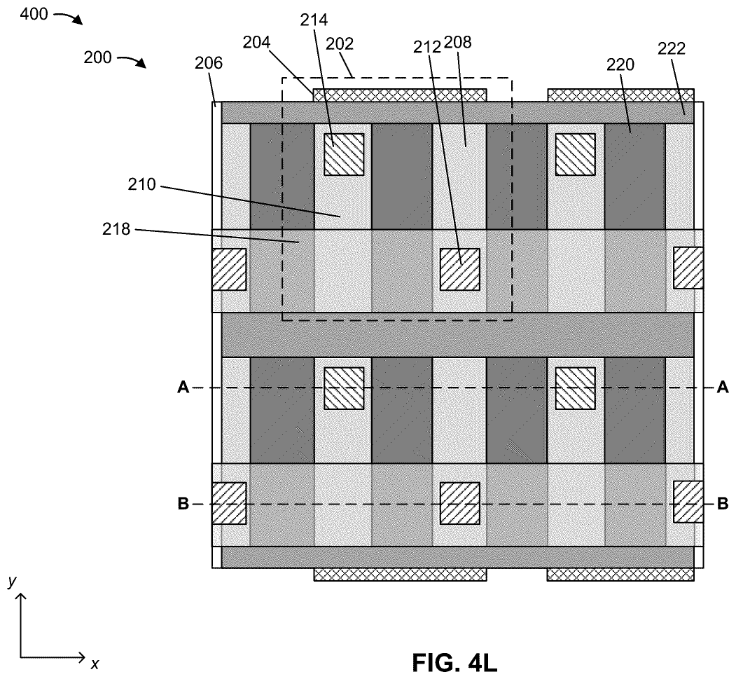

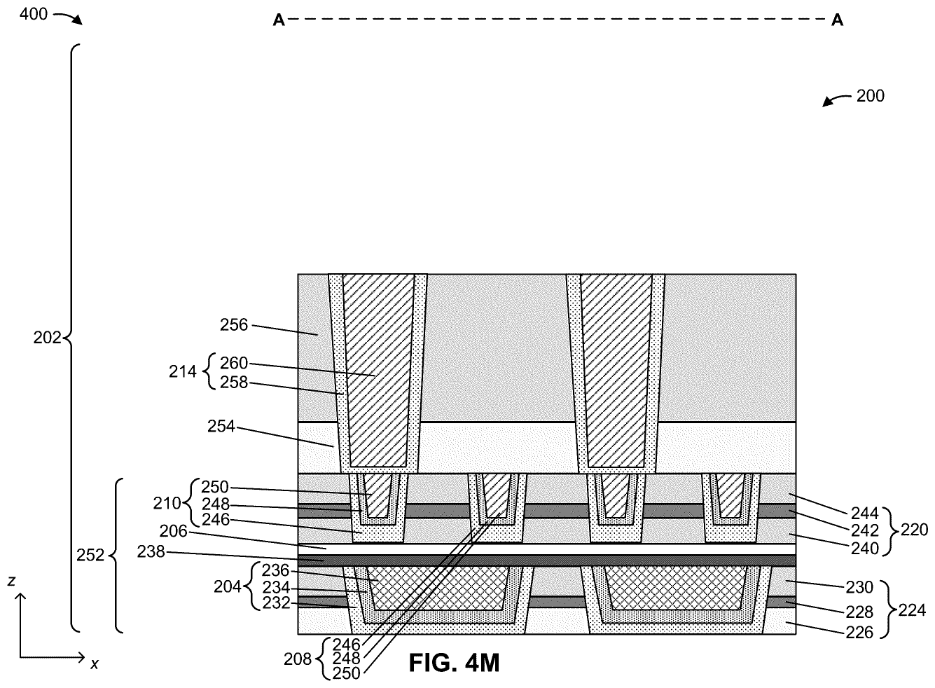

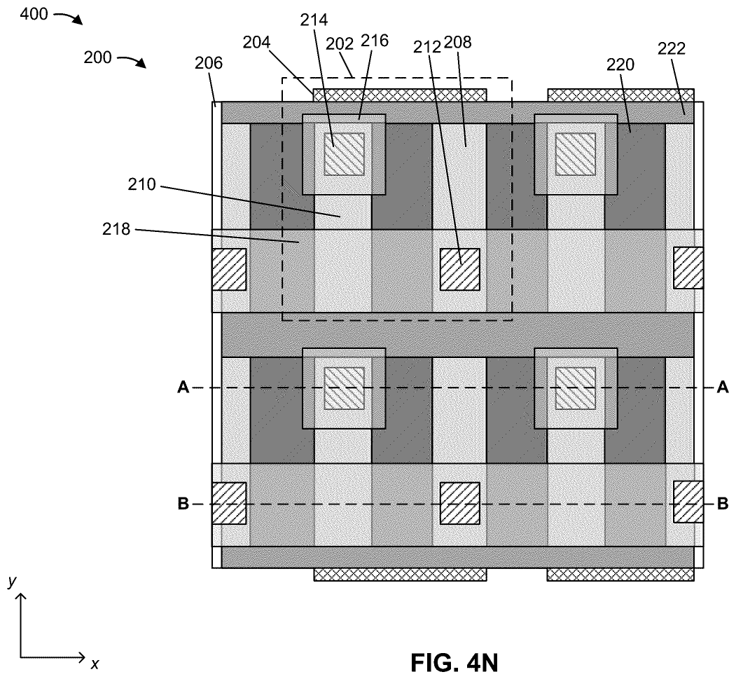

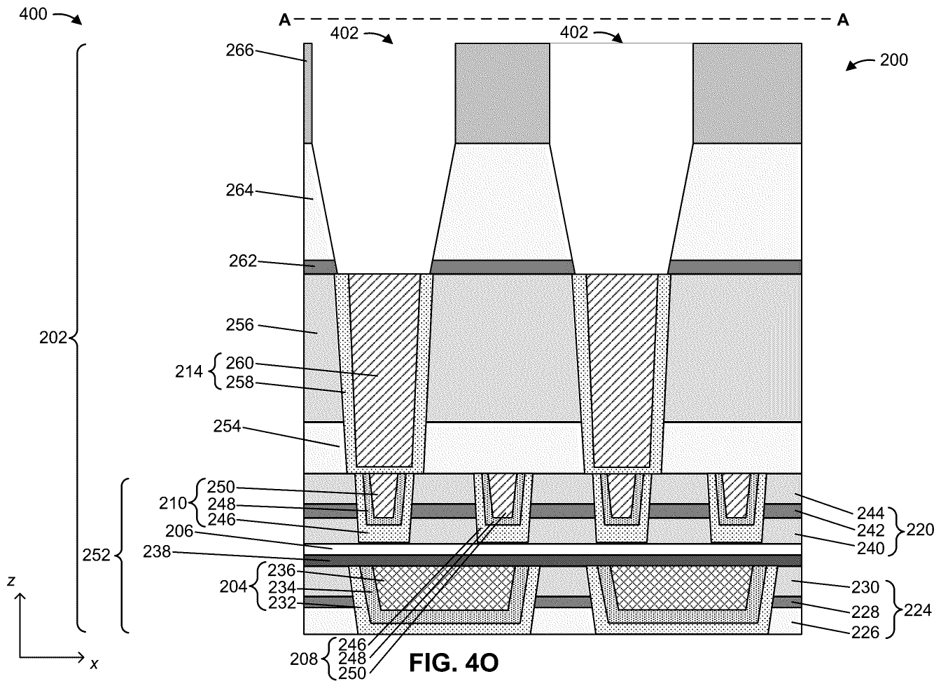

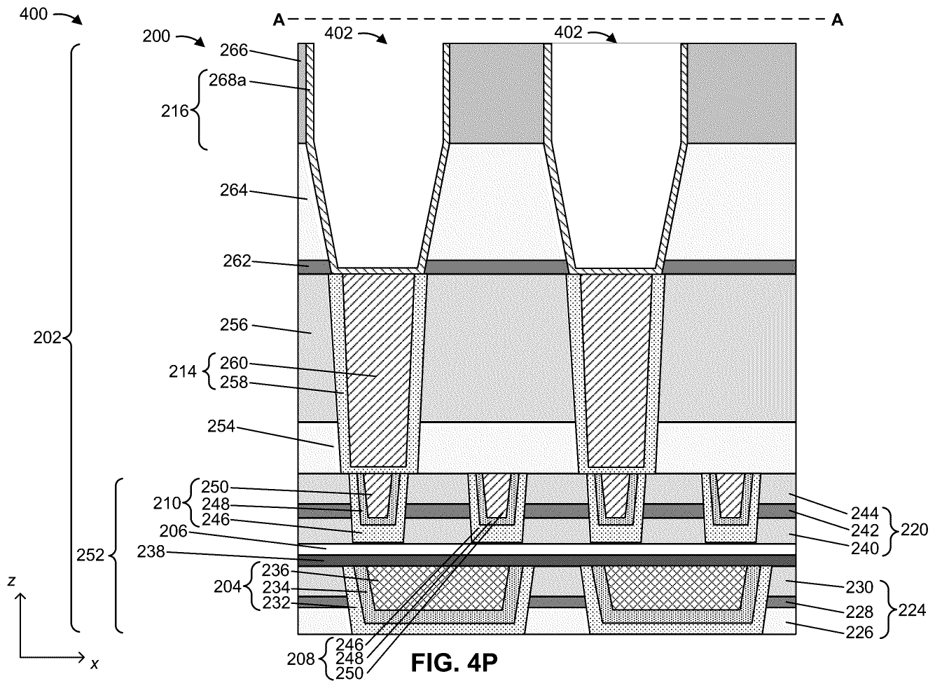

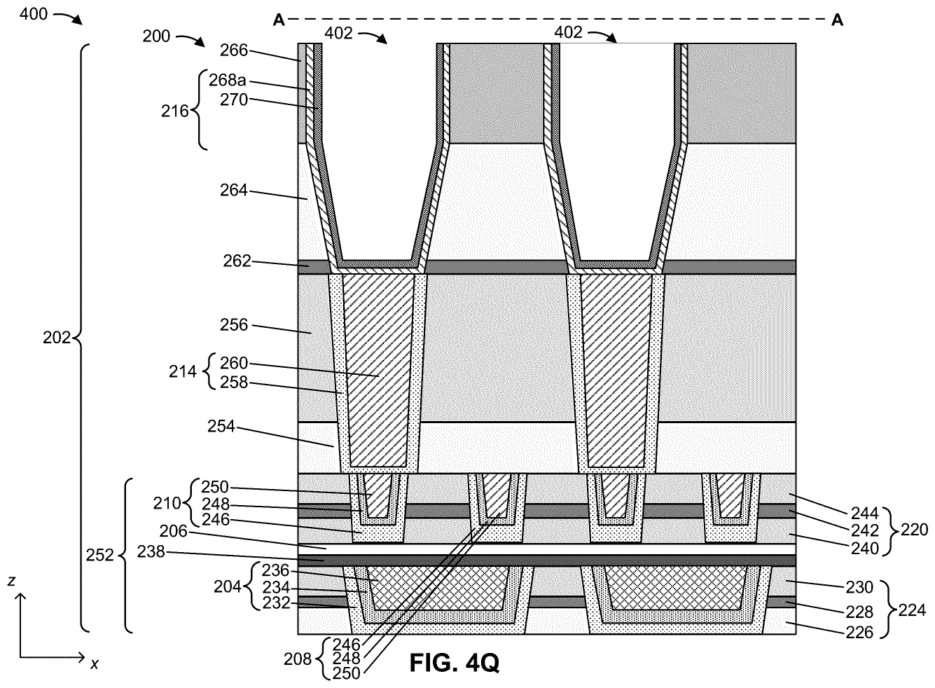

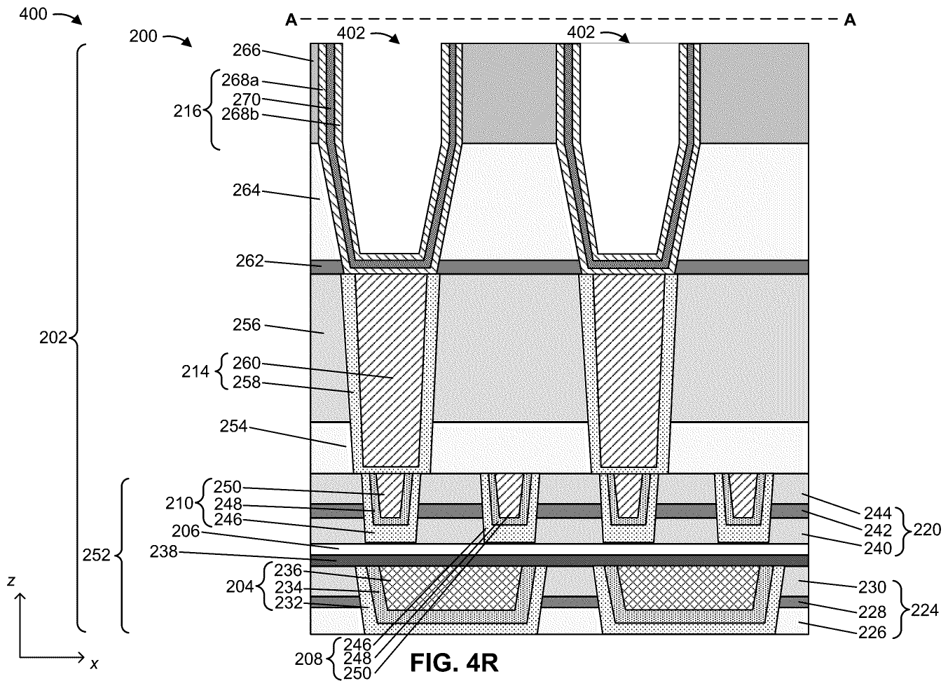

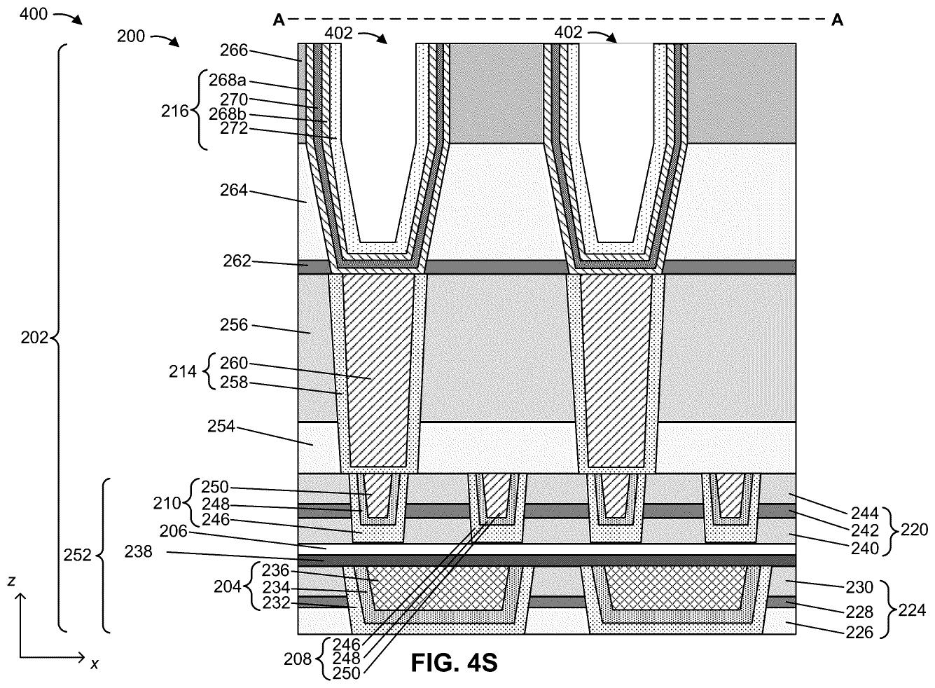

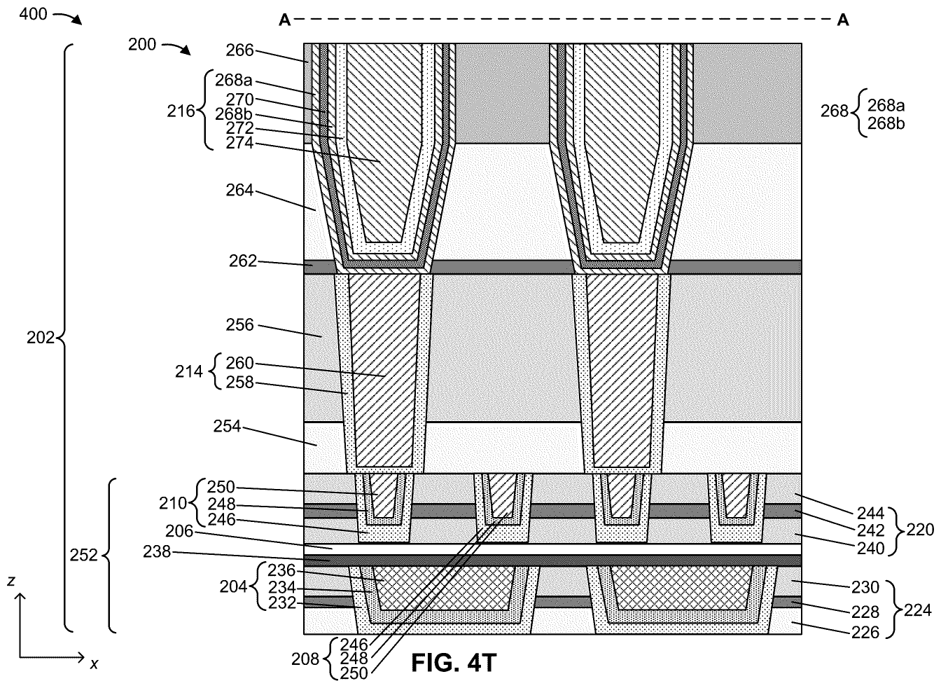

In some implementations, one or more of the semiconductor processing tools 102-112 may perform one or more semiconductor processing operations described herein. For example, one or more of the semiconductor processing tools 102-112 may form a gate structure of a transistor structure included in a memory cell structure of a semiconductor device; may form a gate dielectric layer of the transistor structure over the gate structure; may form a channel layer of the transistor structure on the gate dielectric layer; may form a plurality of source/drain regions of the transistor structure on the channel layer; may form a source/drain interconnect structure of the memory cell structure on a source/drain region of the plurality of source/drain regions; may form a bottom electrode, of a capacitor structure included in the memory cell structure, on the source/drain interconnect structure; may form a hydrogen absorption layer of the capacitor structure over the bottom electrode; and/or may form a top electrode of the capacitor structure over the hydrogen absorption layer, among other examples. One or more of the semiconductor processing tools 102-112 may perform other semiconductor processing operations described herein, such as in connection with FIGS. 4A-4T, 6A-6F, 8A-8O, 10A-10F, 12, and/or 13, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

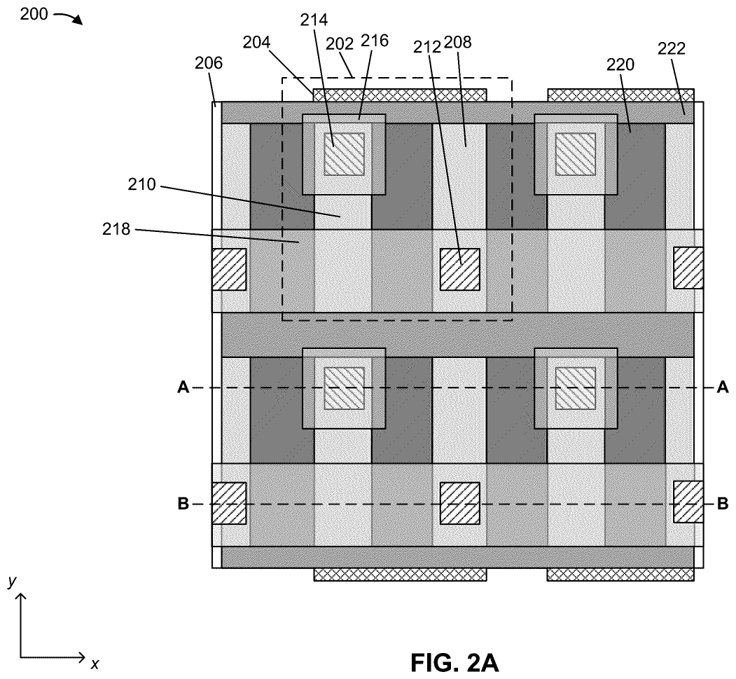

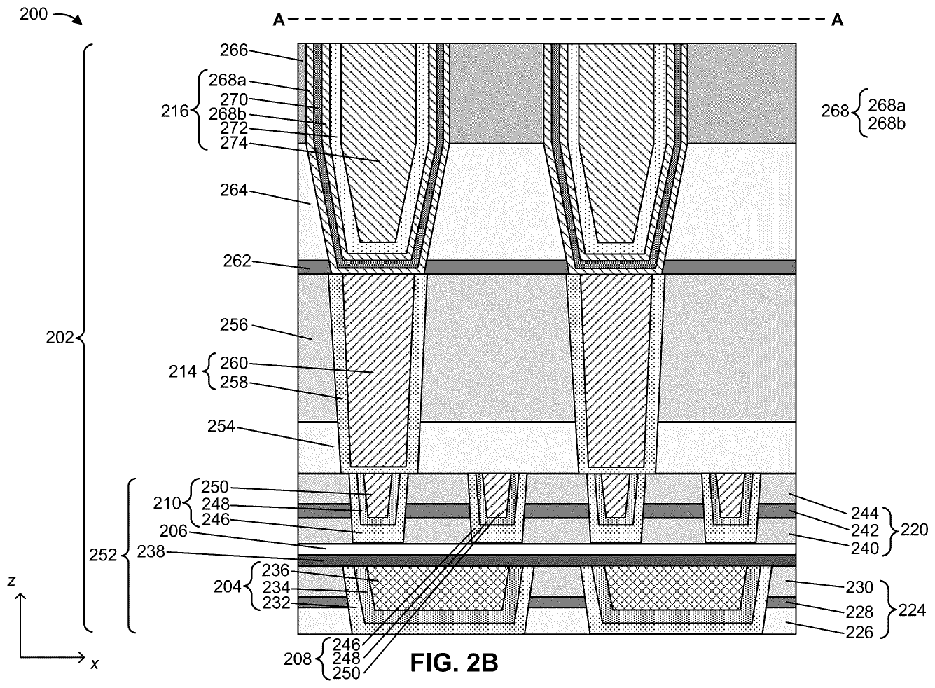

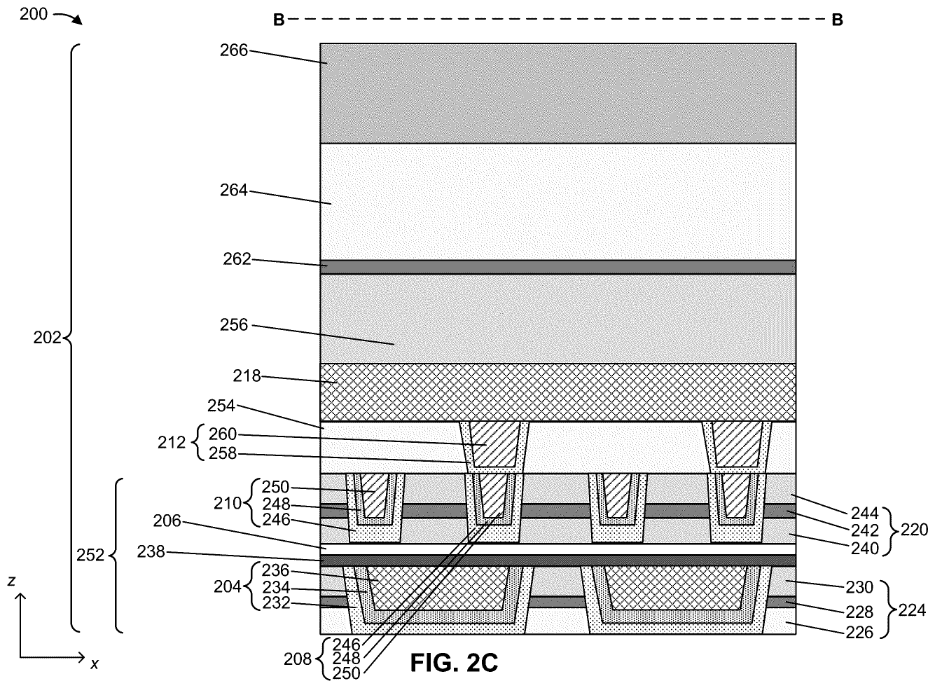

FIGS. 2A-2C are diagrams of an example semiconductor device 200 described herein. In particular, FIG. 2A illustrates a top-down view of a back end (BEOL) region of the semiconductor device 200, FIG. 2B illustrates a cross-sectional view of the BEOL region along the cross-sectional plane A-A in FIG. 2A, and FIG. 2C illustrates a cross-sectional view of the BEOL region along the cross-sectional plane B-B in FIG. 2A. The semiconductor device 200 includes an example of a semiconductor device, such as a semiconductor memory device, an image sensor device (e.g., a complementary metal oxide semiconductor (CMOS) image sensor (CIS) device), a semiconductor logic device (e.g., a processor, a central processing unit (CPU), a graphics processing unit (GPU), a digital signal processor (DSP)), an input/output device, an application specific integrated circuit (ASIC), or another type of semiconductor device. In some implementations, the semiconductor device 200 includes a front end of line (FEOL) region that includes integrated circuitry that is connected with the BEOL region of the semiconductor device 200.

As shown in FIG. 2A, the semiconductor device 200 may include a memory array that includes a plurality of memory cell structures 202. The memory array may be included in one or more back end dielectric layers (e.g., BEOL dielectric layers) in the BEOL region of the semiconductor device 200. The memory cell structures 202 may include volatile memory structures, such as DRAM memory structures and/or another type of volatile memory structures.

A memory cell structure 202 in the memory array may include a gate structure 204, a channel layer 206 above the gate structure 204, and a plurality of source/drain regions 208 and 210 above the channel layer 206. The gate structure 204, the channel layer 206, and the source/drain regions 208 and 210 may correspond to a transistor structure of the memory cell structure 202. A source/drain region, as used herein, may refer to a source region, a drain region, or both a source region and a drain region, depending on the context. The memory cell structure 202 may further include an interconnect structure 212 above the source/drain region 208, an interconnect structure 214 above the source/drain region 210, a capacitor structure 216 above the interconnect structure 214, and a bit line conductive structure 218 above the interconnect structure 212. The interconnect structure 212 may electrically couple the transistor of the memory cell structure 202 with the bit line conductive structure 218, and the interconnect structure 214 may electrically couple the transistor of the memory cell structure 202 with the capacitor structure 216. The capacitor structure 216 may be configured to selectively store an electrical charge for the memory cell structure 202, enabling one or more logical values to be stored by the memory cell structure 202 based on an amount of electrical charge stored in the capacitor structure 216. The capacitor structure 216 may be referred to as a programmable charge-based memory cell of the memory cell structure 202.

As further shown in FIG. 2A, one or more bit line conductive structures 218 in the memory array may extend in a first direction (e.g., an x-direction) in the semiconductor device 200. One or more gate structures 204 in the memory array may extend in a second direction (e.g., an y-direction) in the semiconductor device 200 that is approximately orthogonal to the first direction. This enables a gate structure 204 to span multiple memory cell structures 202 in the memory array, and enables a single bit line conductive structure 218 to span multiple memory cell structures 202 in the memory array. Thus, the memory cell structures 202 in the memory array may be arranged in a grid and each electrically coupled to a single gate structure 204 and a single bit line conductive structure 218, which enables each memory cell structure 202 in the memory array to be accessed by a specific combination of a gate structure 204 and a bit line conductive structure 218.

In some implementations, one or more channel layers 206 in the memory array may extend in the first direction in the semiconductor device 200 and may span across a plurality of memory cell structures 202. A source/drain region 208 and a source/drain region 210 may extend in the second direction. In some implementations, each memory cell structure 202 may include its own set of source/drain regions 208 and 210, and a single channel layer 206 coupled with the source/drain regions 208 and 210. Thus, the memory cell structures 202 may be referred to as single-channel memory cell structures. The source/drain regions 208 and 210 may be included directly above and/or within a perimeter of the gate structure 204.

In some implementations, dielectric layers 220 and 224 may be included to provide electrical isolation between source/drain regions 208 and/or 210. The dielectric layers 220 may provide electrical isolation in the x-direction between adjacent source/drain regions 208 and/or 210. The dielectric layers 222 may provide electrical isolation in the y-direction between two or more source/drain regions 208 and/or between two or more source/drain regions 210.

FIG. 2B illustrates a cross-sectional view of a memory cell structure 202 along the cross-sectional plane A-A shown in FIG. 2A. The cross-sectional view along the cross-sectional plane A-A includes the interconnect structure 214 and the capacitor structure 216 of the memory cell structure 202.

As shown in FIG. 2B, the memory cell structure 202 may be included in one or more back end layers of a semiconductor device 200. The back end dielectric layer(s) (e.g., BEOL layers or BEOL dielectric layers) may include a dielectric layer 224 in which the gate structure 204 of the memory cell structure 202 is included. The dielectric layer 224 may include one or more layers, such as a passivation layer 226, an etch stop layer (ESL) 228, and/or an isolation layer 230, among other examples. The gate structure 204 may include one or more liner layers 232 and 234 between a gate electrode 236 of the gate structure 204 and the dielectric layer 224.

The passivation layer 226 may include one or more high dielectric constant (high-k) dielectric materials to provide etch selectivity relative to the isolation layer 230. Examples of high-k dielectric materials include dielectric materials having a dielectric constant greater than the dielectric constant of silicon oxide (approximately 3.6), such as silicon oxynitride (SiONₓ) and/or silicon nitride (SiₓN_{y}), among other examples. The ESL 228 may include an aluminum oxide (AlOₓ), an aluminum nitride (AlNₓ), and/or another suitable ESL material. The isolation layer 230 may include one or more low dielectric constant (low-k) dielectric materials such as a silicon oxide (SiOₓ), fluoride-doped silicate glass (FSG), and/or another low-k dielectric material.

The gate electrode 236 may include polysilicon (e.g., polycrystalline silicon), one or more conductive materials such as tungsten (W) and/or aluminum (Al), one or more high-k materials, and/or a combination thereof. The liner layer(s) 232 and/or 234 may include adhesion liners (e.g., liners that are included to promote adhesion between the gate electrode 236 and the dielectric layer 224), barrier layers (e.g., layers that are included to reduce or minimize diffusion of the material of the gate electrode 236 into the dielectric layer 224, and/or another type of liner layers. Examples of materials for the liner layer(s) 232 and/or 234 include tantalum nitride (TaN) and/or titanium nitride (TiN), among other examples.

A gate dielectric layer 238 may be included over and/or on the gate structure 204. The gate dielectric layer 238 may be included above the dielectric layer 224. The gate dielectric layer 238 may include one or more dielectric materials, such as hafnium oxide (HfOₓ such as HfO₂), silicon oxide (SiOₓ such as SiO₂), aluminum oxide (AlₓO_{y} such as Al₂O₃), zirconium oxide (ZrₓO_{y}), titanium oxide (TiₓO_{y}), and/or silicon oxynitride (SiON), among other examples.

The channel layer 206 may be included over and/or on the gate dielectric layer 238. In this way, the gate dielectric layer 238 is between the gate structure 204 and the channel layer 206. The channel layer 206 may include one or more metal-oxide materials or metal-oxide semiconductor materials. In some implementations, the channel layer 206 is an n-type channel that includes tin oxide (SnOₓ such as SnO₂), indium oxide (InₓO_{y} such as In₂O₃), zinc oxide (ZnO), indium gallium zinc oxide (InGaZnO or IGZO), and/or another n-type metal-oxide material. In some implementations, the channel layer 206 is a p-type channel that includes nickel oxide (NiO), copper oxide (CuₓO such as Cu₂O), copper aluminum oxide (CuAlOₓ such as CuAlO₂), copper gallium oxide (CuGaOₓ such as CuGaO₂), copper indium oxide (CuInOₓ such as CuInO₂), strontium cuprate (SrCuₓO_{y} such as SrCu₂O₂), tin oxide (SnO), and/or another p-type metal-oxide material.

The semiconductor device 200 may include additional back end dielectric layer(s), such as the dielectric layer 220 above the channel layer 206. The dielectric layer 220 may include one or more layers such as an isolation layer 240, an ESL 242, and an isolation layer 244. The source/drain regions 208 and 210 of the memory cell structure 202 may be included in the dielectric layer 220. The source/drain regions 208 and 210 may each include one or more liner layers 246 and/or 248, and an electrode 250. The source/drain regions 208 and 210 may be included over and/or on the channel layer 206. The source/drain regions 208 and 210 may be electrically coupled with channel layer 206 such that current is selectively permitted to flow between the source/drain regions 208 and 210 through the channel layer 206.

The isolation layers 240 and 244 may each include one or more low-k dielectric materials such as a silicon oxide (SiOₓ), FSG, and/or another low-k dielectric material. The ESL 242 may include an aluminum oxide (AlOₓ), an aluminum nitride (AlNₓ), and/or another suitable ESL material.

The one or more liner layers 246 and/or 248 of the source/drain regions 208 and/or 210 may include a barrier liner included to prevent material migration from the electrode 250 into the surrounding dielectric layers 220, an adhesion layer included to promote adhesion between the electrode 250 and the surrounding dielectric layers 220, and/or another type of liner layer. Examples of materials for the electrodes 250 of the source/drain regions 208 and/or 210 include polysilicon, copper (Cu), cobalt (Co), ruthenium (Ru), titanium (Ti), tungsten (W), and/or aluminum (Al), among other examples. Examples of liner layers 246 and/or 248 include tantalum nitride (TaN), titanium nitride (TiN), indium tin oxide (ITO), and/or another suitable liner layer, among other examples.

The gate structure 204, the gate dielectric layer 238, the channel layer 206, and the source/drain regions 208 and 210 may correspond to a transistor structure 252 of the memory cell structure 202. The gate structure 204 of the transistor structure 252 may be included under (e.g., in a z-direction in the semiconductor device 200) the channel layer 206 and under the source/drain regions 208 and 210. Accordingly, the gate structure 204 may be referred to as a bottom gate.

The transistor structure 252 may be electrically coupled with the capacitor structure 216, above the transistor structure 252, through the interconnect structure 214. The transistor structure 252 may be configured to selectively control access to the capacitor structure 216. For example, the transistor structure 252 may be activated to enable a charge to be provided to the capacitor structure 216 through the transistor structure 252. As another example, the transistor structure 252 may be deactivated to enable a charge to be stored in (e.g., to remain in) the capacitor structure 216. As another example, the transistor structure 252 may be activated to perform a “read” operation in which a charge stored in the capacitor structure 216 is discharged through the transistor structure 252 and measured.

In some implementations, memory cell structure 202 may be physically coupled and/or electrically coupled with a word line conductive structure (not shown) under the transistor structure 252. The word line conductive structure may also be referred to as an access line conductive structure, a select line conductive structure, an address line conductive structure, and/or a row line conductive structure, among other examples. The word line conductive structure may be configured to selectively provide a voltage or current to a gate structure 204 of the transistor structure 252 for performing access operations associated with the memory cell structure 202.

The interconnect structure 214 may be included in one or more back end dielectric layers, such as a passivation layer 254 and/or an isolation layer 256 above the passivation layer 254, among other examples. The interconnect structure 214 may be included on the source/drain region 210, and may be electrically coupled and/or physically coupled with the source/drain region 210.

The passivation layer 254 may include one or more high-k dielectric materials such as silicon oxynitride (SiONₓ) and/or silicon nitride (SiₓN_{y}), among other examples. The isolation layer 256 may include one or more low-k dielectric materials such as a silicon oxide (SiOₓ), FSG, and/or another low-k dielectric material.

The interconnect structure 214 may include a via, a plug, a trench, a dual damascene structure, and/or another type of conductive structure. The interconnect structure 214 may include one or more liner layers 258 and an electrode 260. The electrode 260 may include one or more electrically conductive materials, such as copper (Cu), cobalt (Co), ruthenium (Ru), titanium (Ti), tungsten (W), gold (Au), and/or silver (Ag), among other examples. The one or more liner layers 258 may be included between the electrode 260 and the passivation layer 254 and/or the isolation layer 256. The one or more liner layers 258 may include a barrier liner included to prevent material migration from the electrode 260 into the passivation layer 254 and/or the isolation layer 256, an adhesion layer included to promote adhesion between the electrode 260 and the passivation layer 254 and/or the isolation layer 256, and/or another type of liner layer. Examples of materials included in the liner layers 258 include tantalum nitride (TaN), titanium nitride (TiN), and/or another suitable liner layer, among other examples.

The capacitor structure 216 may include a deep trench capacitor (DTC) having a relatively high aspect ratio between the height of the capacitor structure 216 and a width or critical dimension (CD) of the capacitor structure 216. Alternatively, the capacitor structure 216 may include a planar capacitor and/or another type of capacitor structure. The bottom surface of the capacitor structure 216 may be electrically coupled and/or physically coupled with the interconnect structure 214. The capacitor structure 216 may be included one or more back end dielectric layers of the semiconductor device 200, such as an ESL 262, a passivation layer 264, and/or an isolation layer 266, among other examples.

The ESL 262 may include an aluminum oxide (AlOₓ), an aluminum nitride (AlNₓ), and/or another suitable ESL material. The passivation layer 264 may include one or more high-k dielectric materials such as silicon oxynitride (SiONₓ) and/or silicon nitride (SiₓN_{y}), among other examples. The isolation layer 266 may include a low-k dielectric materials such as a silicon oxide (SiOₓ), FSG, and/or another low-k dielectric material.

The capacitor structure 216 may include a bottom electrode 268 over and/or on the sidewalls and the bottom surface of the capacitor structure 216. The bottom electrode 268 may include a first bottom electrode layer 268a and a second bottom electrode layer 268b. The first bottom electrode layer 268a and the second bottom electrode layer 268b may each include an electrically conductive (or semiconductive) material, such as tantalum nitride (TaN), titanium nitride (TiN), tungsten (W), aluminum (Al), polysilicon, and/or another suitable material.

The capacitor structure 216 may further include a hydrogen absorption layer 270 between the first bottom electrode layer 268a and the second bottom electrode layer 268b. Thus, the hydrogen absorption layer 270 may be included over and/or on the first bottom electrode layer 268a, and the second bottom electrode layer 268b may be included over and/or on the hydrogen absorption layer 270. The hydrogen absorption layer 270 may conform to a profile of the deep trench capacitor structure of the capacitor structure 216. The hydrogen absorption layer may include a metal-oxide material (or metal-oxide semiconductor material) that readily absorbs hydrogen (H). Examples of metal-oxide material may include an indium oxide (InₓO_{y} such as In₂O₃), a titanium oxide (TiOₓ such as TiO₂), an ITO, an indium tin oxide (ITO), a cerium oxide (CeOₓ), a zinc oxide (ZnO), and/or an indium gallium zinc oxide (IGZO), among other examples.

The metal-oxide material of the hydrogen absorption layer 270 may absorb and retain hydrogen before the hydrogen can diffuse downward into the metal-oxide material of the channel layer 206. At least some of the back end dielectric layers (and/or other layers) of the semiconductor device 200 may be deposited using deposition techniques in which hydrogen is used as a carrier gas and/or a purge gas, resulting in difficulty in regulating the hydrogen content in the semiconductor device 200. Moreover, the metal layers of the capacitor structure 216, the interconnect structure 214, and/or the source/drain region 210 may generally have low hydrogen migration energy, enabling hydrogen to quickly diffuse through these structures and into the channel layer 206. Heat treatment operations for the semiconductor device 200 can further promote diffusion of hydrogen downward into the channel layer 206. The hydrogen may ionize and bond with oxygen in the metal-oxide material of the channel to form oxygen-hydrogen (O—H) bonds.

The hydrogen absorption layer 270 may instead absorb the hydrogen before the hydrogen diffuses downward into the metal-oxide material of the channel layer 206. In particular, the metal-oxide material of the hydrogen absorption layer 270 captures free electrons in the surrounding area and combines the free electrons with the ionized hydrogen such that the ionized hydrogen remains immobilized within the hydrogen absorption layer 270. The chemical reaction of the absorption of the ionized hydrogen in the hydrogen absorption layer 270 may be represented as:

MOₓ+H⁺+e³¹→M(OH)ₓ

where M refers to the metal constituent of the metal-oxide material. Thus, the hydrogen absorption layer 270 may be deposited as a metal-oxide layer, and may subsequently contain one or more metal-hydroxide materials (e.g., In(OH)ₓ, Ti(OH)ₓ, Zn(OH)ₓ) after absorbing hydrogen in the semiconductor device 200.

In some implementations, the thickness of the hydrogen absorption layer 270 is included in a range of approximately 1 nanometer to approximately 100 nanometers. If the thickness of the hydrogen absorption layer 270 is less than approximately 1 nanometer, the hydrogen absorption layer 270 may not provide sufficient hydrogen absorption, resulting in an increased amount of hydrogen diffusion in the channel layer 206. If the thickness of the hydrogen absorption layer 270 is greater than approximately 100 nanometers, the hydrogen absorption layer 270 may occupy a large amount of volume of the capacitor structure 216, reducing the available volume for the electrodes of the capacitor structure 216. This may increase the resistivity and decrease the capacitance of the capacitor structure 216. If the thickness of the hydrogen absorption layer 270 is included in the range of approximately 1 nanometer to approximately 100 nanometers, a sufficient amount of hydrogen absorption may be achieved, and a sufficiently low resistance and sufficiently high capacitance may be achieved for the capacitor structure 216. However, other values for the thickness of the hydrogen absorption layer 270, and ranges other than approximately 1 nanometer to approximately 100 nanometers, are within the scope of the present disclosure.

The capacitor structure 216 may further include a dielectric layer 272 over and/or on the bottom electrode 268 (e.g., over and/or on the second bottom electrode layer 268b). The dielectric layer 272 may include a high-k dielectric material, which enables a high capacitance for the capacitor structure 216 to be achieved. Examples of high-k dielectric materials that may be included in the dielectric layer 272 of the capacitor structure 216 include a zirconium oxide (ZrOₓ such as ZrO₂), a hafnium oxide (HfOₓ such as HfO₂), hafnium zirconium oxide (HZO), zirconium aluminum oxide (ZAO), silicon doped hafnium oxide (HSO), and/or another high-k dielectric material. Splitting the bottom electrode 268 into the first bottom electrode layer 268a and the second bottom electrode layer 268b enables the hydrogen absorption layer 270 to be formed such that the hydrogen absorption layer 270 is not in direct contact with the dielectric layer 272, which might otherwise result in adverse reactions between the high-k material of the dielectric layer 272 and the hydrogen absorption layer 270. In this way, forming the hydrogen absorption layer 270 such that the hydrogen absorption layer 270 is not in direct contact with the dielectric layer 272 may enable a low surface roughness for the layers of the capacitor structure 216 to be achieved, which may enable a high capacitance value and/or low resistance to be achieved for the capacitor structure 216, among other examples.

A top electrode 274 may be included over and/or on the dielectric layer 272. The top electrode 274 may include an electrically conductive (or semiconductive) material, such as tantalum nitride (TaN), titanium nitride (TiN), tungsten (W), aluminum (Al), polysilicon, and/or another suitable material.

FIG. 2C illustrates another cross-sectional view of a memory cell structure 202 along the cross-sectional plane B-B shown in FIG. 2A. The cross-sectional view along the cross-sectional plane B-B includes the interconnect structure 212 and the bit line conductive structure 218 of the memory cell structure 202.

As shown in FIG. 2C, the source/drain region 208 may be electrically and/or physically coupled with the interconnect structure 212. The interconnect structure 212 may be included in the passivation layer 254 above the source/drain region 208. The interconnect structure 212 may electrically couple the source/drain region 208 to the bit line conductive structure 218 above the interconnect structure 212. The interconnect structure 212 may include one or more liner layers 258 and an electrode 260. The electrode 260 may include one or more electrically conductive materials, such as copper (Cu), cobalt (Co), ruthenium (Ru), titanium (Ti), tungsten (W), gold (Au), and/or silver (Ag), among other examples. The one or more liner layers 258 may be included between the electrode 260 and the passivation layer 254 and/or the isolation layer 256. Examples of materials included in the liner layers 258 include tantalum nitride (TaN), titanium nitride (TiN), and/or another suitable liner layer, among other examples.

The bit line conductive structure 218 may also be referred to as a column line conductive structure. The bit line conductive structure 218 may be located over and/or on the interconnect structure 212, and may be configured to selectively receive a current from the capacitor structure 216 or to provide a current to the capacitor structure 216 through the transistor structure 252. The bit line conductive structure 218 may include one or more electrically conductive materials, such as copper (Cu), cobalt (Co), ruthenium (Ru), titanium (Ti), tungsten (W), gold (Au), and/or silver (Ag), among other examples.

As indicated above, FIGS. 2A-2C are provided as an example. Other examples may differ from what is described with regard to FIGS. 2A-2C.

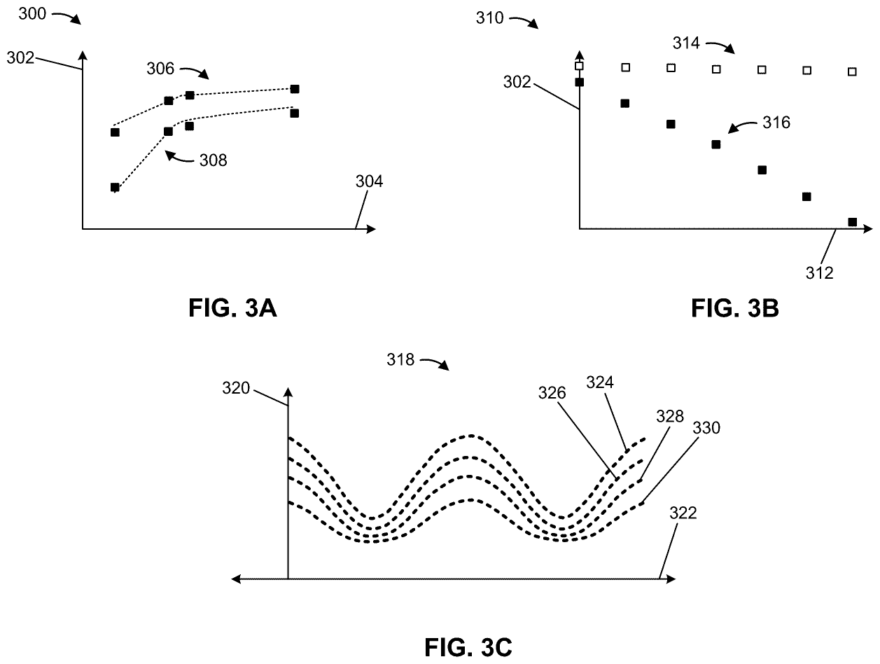

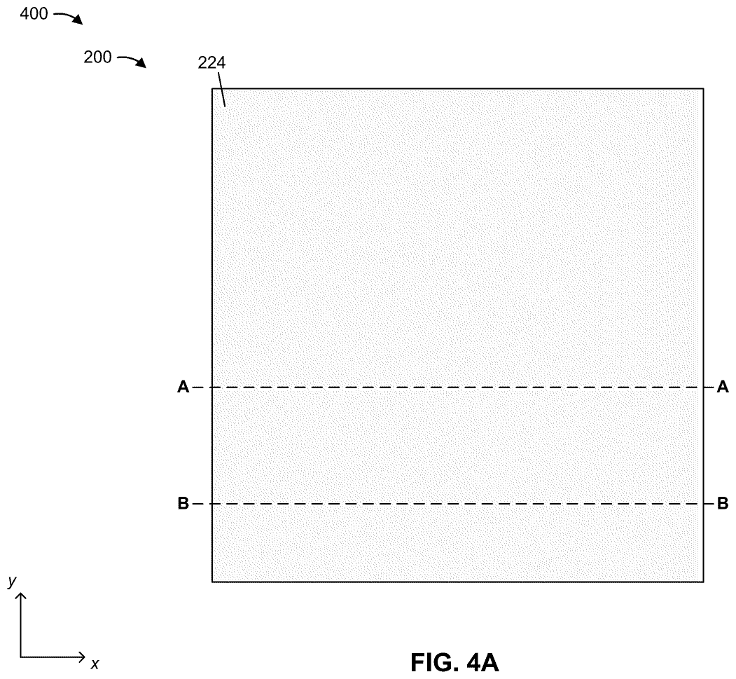

FIGS. 3A-3C are diagrams of examples of parameters associated with a memory cell structure that includes a hydrogen absorption layer 270 described herein. FIG. 3A illustrates an example 300 of threshold voltage (Vₜₛ) 302 as a function of gate length (L_{g}) of a transistor structure 252 included in the memory cell structure. As shown in FIG. 3A, a data plot 306 corresponds to the memory cell structure that includes the hydrogen absorption layer 270, where the hydrogen absorption layer 270 has a first thickness. A data plot 308 corresponds to another memory cell structure that includes another hydrogen absorption layer 270 having a second thickness. The first thickness may be greater than the second thickness. As shown by the data plots 306 and 308, the hydrogen absorption layer 270 with the greater thickness generally enables a greater threshold voltage 302 to be achieved for the same gate length 304. This may be due to the hydrogen absorption layer 270 with the greater thickness being able to better absorb hydrogen that would otherwise contaminate the channel layer of the memory cell structure and reduce the threshold voltage 302.

FIG. 3B illustrates an example 310 of a reduction threshold voltage (Vₜₛ) 302 as a function of stress time 312 of the memory cell structure. As shown in FIG. 3B, a data set 314 corresponds to the memory cell structure that includes the hydrogen absorption layer 270, and a data set 316 corresponds to another memory cell structure that does not include a hydrogen absorption layer 270. The hydrogen absorption layer 270 may reduce and/or minimize the effects of NBTI on the memory cell structure because of the hydrogen diffusion blocking of the hydrogen absorption layer 270. Without the hydrogen absorption layer 270, hydrogen diffusion may cause a reduction in threshold voltage as stress time 312 increases, as shown by the data set 316.

FIG. 3C illustrates an example 318 of hydrogen concentration 320 as a function of horizonal position 322 along channel layers 206 in transistor structures 252 of a plurality of memory cell structures. The data plots 324-330 may respectively correspond to increasing thicknesses of hydrogen absorption layers 270. As shown in FIG. 3C, the hydrogen concentration 320 may generally be less as the thickness of the hydrogen absorption layer 270 increases.

As indicated above, FIGS. 3A-3C are provided as examples. Other examples may differ from what is described with regard to FIGS. 3A-3C.

FIGS. 4A-4T are diagrams of an example implementation 400 of forming a memory cell structure 202 of the semiconductor device 200 described herein. In some implementations, one or more of the processing operations described in connection with FIGS. 4A-4T may be performed using one or more of the semiconductor processing tools 102-112 and/or the wafer/die transport tool 114. In some implementations, one or more of the processing operations described in connection with FIGS. 4A-4T may be performed using another semiconductor processing tool not shown in FIG. 1.

Turning to FIG. 4A, one or more of the processing operations described in connection with FIGS. 4A-4T may be performed after front end processing of the semiconductor device 200. Accordingly, the memory cell structure 202 may be formed in a back end region (e.g., a BEOL region) of the semiconductor device 200. As shown in FIG. 4A, the dielectric layer 224 may be formed. A deposition tool 102 may be used to deposit the dielectric layer 224 using a CVD technique, a PVD technique, an ALD technique, another deposition technique described above in connection with FIG. 1, and/or a deposition technique other than as described above in connection with FIG. 1. In some implementations, depositing the dielectric layer 224 includes depositing the passivation layer 226, depositing the ESL 228 on the passivation layer 226, and depositing the isolation layer 230 on the ESL 228.

As shown in FIGS. 4B and 4C, the gate structure 204 of the transistor structure 252 of the memory cell structure 202 may be formed in the dielectric layer 224. The gate structure 204 may extend in the y-direction in the semiconductor device 200, as shown in the top-down view in FIG. 4B. The dielectric layer 224 may electrically isolate adjacent gate structures 204 in the semiconductor device 200. As shown in FIG. 4C, forming the gate structure 204 may include forming the liner layer(s) 232 and/or 234 in a recess in the dielectric layer 224, and forming the gate electrode 236 over and/or on the liner layer(s) 232 and/or 234.

The recess may be formed in and/or through the dielectric layer 224 (e.g., in and/or through the passivation layer 226, the ESL 228, and the isolation layer 230). In some implementations, a pattern in a photoresist layer is used to form the recess in the dielectric layer 224. In these implementations, a deposition tool 102 is used to form the photoresist layer on the dielectric layer 224. An exposure tool 104 exposes the photoresist layer to a radiation source to pattern the photoresist layer. A developer tool 106 develops and removes portions of the photoresist layer to expose the pattern. An etch tool 108 etches into the dielectric layer 224 based on the pattern to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess based on a pattern.

To form the gate structure 204 in the recess, the deposition tool 102 and/or the plating tool 112 may be used to deposit the liner layer(s) 232 and/or 234 in the recess using a CVD technique, a PVD technique, an ALD technique, an electroplating technique, another deposition technique described above in connection with FIG. 1, and/or a deposition technique other than as described above in connection with FIG. 1. The deposition tool 102 and/or the plating tool 112 may be used to deposit the gate electrode 236 over and/or on the liner layer(s) 232 and/or 234 in the recess using a CVD technique, a PVD technique, an ALD technique, an electroplating technique, an epitaxy technique, another deposition technique described above in connection with FIG. 1, and/or a deposition technique other than as described above in connection with FIG. 1. In some implementations, a seed layer is first deposited on the liner layer(s) 232 and/or 234, and the gate electrode 236 is deposited on the seed layer, where the seed layer promotes adhesion between the liner layer(s) 232 and/or 234 and the gate electrode 236. In some implementations, a planarization tool 110 is used to planarize the liner layer(s) 232 and/or 234 and/or the gate electrode 236.

As shown in FIGS. 4D and 4E, a plurality of layers may be formed over and/or on the dielectric layer 224 and over and/or on the gate structure 204. For example, the gate dielectric layer 238 may be formed over and/or on the dielectric layer 224 and over and/or on the gate structure 204. As another example, the channel layer 206 may be formed over and/or on the gate dielectric layer 238. A deposition tool 102 may be used to deposit the gate dielectric layer 238 using a CVD technique, a PVD technique, an ALD technique, an oxidation technique, another deposition technique described above in connection with FIG. 1, and/or a deposition technique other than as described above in connection with FIG. 1. In some implementations, a planarization tool 110 may be used to planarize the gate dielectric layer 238. A deposition tool 102 may be used to deposit the channel layer 206 using a CVD technique, a PVD technique, an ALD technique, an oxidation technique, another deposition technique described above in connection with FIG. 1, and/or a deposition technique other than as described above in connection with FIG. 1. In some implementations, a planarization tool 110 may be used to planarize the channel layer 206.

As shown in FIGS. 4F and 4G, the dielectric layers 220 and 224 may be formed. A deposition tool 102 may be used to deposit the dielectric layers 220 and 224 using a CVD technique, a PVD technique, an ALD technique, an oxidation technique, another deposition technique described above in connection with FIG. 1, and/or a deposition technique other than as described above in connection with FIG. 1. In some implementations, a planarization tool 110 may be used to planarize the dielectric layers 220 and 224. In some implementations, depositing the dielectric layer 220 includes depositing the isolation layer 240, depositing the ESL 242 on the isolation layer 240, and depositing the isolation layer 244 on the ESL 242.

As further shown in FIGS. 4F and 4G, the source/drain regions 208 and 210 of the memory cell structure 202 may be formed in the dielectric layer 220. The source/drain regions 208 and 210 may extend in the y-direction in the semiconductor device 200, as shown in the top-down view in FIG. 4F. The dielectric layer 220 may electrically isolate adjacent source/drain regions 208 and 210 in the x-direction in the semiconductor device 200. The dielectric layer 222 may electrically isolate adjacent source/drain regions 208 and adjacent source/drain regions 210 in the y-direction in the semiconductor device 200. As shown in FIG. 4G, forming a source/drain regions 208 or 210 may include forming the liner layer(s) 246 and/or 248 in a recess in the dielectric layer 220, and forming the electrode 250 over and/or on the liner layer(s) 246 and/or 248.

The recesses for the source/drain regions 208 and 210 of the transistor structure 252 of the memory cell structure 202 may be formed over the gate structure 204 and in and/or through the dielectric layer 220. In this way, a single channel between the source/drain region 208 and the source/drain region 210 may be located in the channel layer 206 above the gate structure 204. The recesses may be formed in and/or through the isolation layer 240, the ESL 242, and the isolation layer 244 of the dielectric layer 220. In some implementations, a pattern in a photoresist layer is used to form the recesses in the dielectric layer 220. In these implementations, a deposition tool 102 is used to form the photoresist layer on the dielectric layer 220. An exposure tool 104 exposes the photoresist layer to a radiation source to pattern the photoresist layer. A developer tool 106 develops and removes portions of the photoresist layer to expose the pattern. An etch tool 108 etches into the dielectric layer 220 based on the pattern to form the recesses. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses based on a pattern.

To form a source/drain region 208 or a source/drain region 210 in a recess in the dielectric layer 220, the deposition tool 102 and/or the plating tool 112 may be used to deposit the liner layer(s) 246 and/or 248 in the recess using a CVD technique, a PVD technique, an ALD technique, an electroplating technique, an oxidation technique, another deposition technique described above in connection with FIG. 1, and/or a deposition technique other than as described above in connection with FIG. 1. The liner layer 246 may land on the channel layer 206 directly above the gate structure 204. The deposition tool 102 and/or the plating tool 112 may be used to deposit the electrode 250 over and/or on the liner layer(s) 246 and/or 248 in the recess using a CVD technique, a PVD technique, an ALD technique, an electroplating technique, an epitaxy technique, another deposition technique described above in connection with FIG. 1, and/or a deposition technique other than as described above in connection with FIG. 1. In some implementations, a seed layer is first deposited on the liner layer(s) 246 and/or 248, and the electrode 250 is deposited on the seed layer, where the seed layer promotes adhesion between the liner layer(s) 246 and/or 248 and the electrode 250. In some implementations, a planarization tool 110 is used to planarize the liner layer(s) 246 and/or 248 and/or the electrode 250.

As shown in FIGS. 4H and 4I, the interconnect structure 212 (e.g., a source/drain contact, a source/drain interconnect structure) of the memory cell structure 202 may be formed over and/or on the source/drain region 208. The interconnect structure 212 may land on the source/drain region 208 such that the interconnect structure 212 is physically coupled and/or electrically coupled with the source/drain region 208. As shown in FIG. 4I, the interconnect structure 212 may be formed in a passivation layer 254 above the dielectric layer 220. The interconnect structure 212 may be formed in a recess in the passivation layer 254.

The passivation layer 254 of the back end region of the semiconductor device 200 may be deposited over and/or on the dielectric layer 220. A deposition tool 102 may be used to deposit the passivation layer 254 using a CVD technique, a PVD technique, an ALD technique, an oxidation technique, another deposition technique described above in connection with FIG. 1, and/or a deposition technique other than as described above in connection with FIG. 1. In some implementations, a planarization tool 110 may be used to planarize the passivation layer 254.

In some implementations, a pattern in a photoresist layer is used to form the recess in the passivation layer 254 over and to the source/drain region 208. In these implementations, a deposition tool 102 may be used to form the photoresist layer on the passivation layer 254. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch into the passivation layer 254 based on the pattern to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses based on a pattern.

A deposition tool 102 and/or a plating tool 112 may be used to deposit the interconnect structure 212 in the recess. For example, a deposition tool 102 and/or a plating tool 112 may be used to deposit the liner layer(s) 258 of the interconnect structure 212 in the recess using a CVD technique, a PVD technique, an ALD technique, an electroplating technique, an oxidation technique, another deposition technique described above in connection with FIG. 1, and/or a deposition technique other than as described above in connection with FIG. 1. As another example, a deposition tool 102 and/or a plating tool 112 may be used to deposit the electrode 260 of the interconnect structure 212 on the liner layer(s) 258 in the recess using a CVD technique, a PVD technique, an ALD technique, an electroplating technique, another deposition technique described above in connection with FIG. 1, and/or a deposition technique other than as described above in connection with FIG. 1. In some implementations, a planarization tool 110 may be used to planarize the interconnect structure 212. In some implementations, a seed layer is deposited in the recess prior to formation of the electrode 260 to promote adhesion between the liner layer(s) 258 and the electrode 260.

As shown in FIGS. 4J and 4K, a bit line conductive structure 218 of the memory cell structure 202 may be formed over the interconnect structure 212 such that the bit line conductive structure 218 is located above the transistor structure 252. The bit line conductive structure 218 may land on the interconnect structure 212 such that the interconnect structure 212 is coupled with the bit line conductive structure 218. In this way, the interconnect structure 212 electrically couples the transistor structure 252 with the bit line conductive structure 218. The bit line conductive structure 218 may extend in the x-direction in the semiconductor device 200.

A deposition tool 102 and/or a plating tool 112 may be used to deposit the bit line conductive structure 218 using a CVD technique, a PVD technique, an ALD technique, an electroplating technique, another deposition technique described above in connection with FIG. 1, and/or a deposition technique other than as described above in connection with FIG. 1. In some implementations, a planarization tool 110 is used to planarize the bit line conductive structure 218.

As shown in FIGS. 4L and 4M, the interconnect structure 214 (e.g., a source/drain contact, a source/drain interconnect structure) of the memory cell structure 202 may be formed over and/or on the source/drain region 210. The interconnect structure 214 may land on the source/drain region 210 such that the interconnect structure 214 is physically coupled and/or electrically coupled with the source/drain region 210. As shown in FIG. 4M, the interconnect structure 214 may be formed in the passivation layer 254 and in an isolation layer 256 above the passivation layer 254. The interconnect structure 214 may be formed in a recess in the passivation layer 254 and in the isolation layer 256.

The isolation layer 256 of the back end region of the semiconductor device 200 may be deposited over and/or on the passivation layer 254. A deposition tool 102 may be used to deposit the isolation layer 256 using a CVD technique, a PVD technique, an ALD technique, an oxidation technique, another deposition technique described above in connection with FIG. 1, and/or a deposition technique other than as described above in connection with FIG. 1. In some implementations, a planarization tool 110 may be used to planarize the isolation layer 256.

In some implementations, a pattern in a photoresist layer is used to form the recess in the passivation layer 254 and in the isolation layer 256 over and to the source/drain region 210. In these implementations, a deposition tool 102 may be used to form the photoresist layer on the isolation layer 256. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch into the passivation layer 254 and into the isolation layer 256 based on the pattern to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses based on a pattern.

A deposition tool 102 and/or a plating tool 112 may be used to deposit the interconnect structure 214 in the recess. For example, a deposition tool 102 and/or a plating tool 112 may be used to deposit the liner layer(s) 258 of the interconnect structure 214 in the recess using a CVD technique, a PVD technique, an ALD technique, an electroplating technique, an oxidation technique, another deposition technique described above in connection with FIG. 1, and/or a deposition technique other than as described above in connection with FIG. 1. As another example, a deposition tool 102 and/or a plating tool 112 may be used to deposit the electrode 260 of the interconnect structure 214 on the liner layer(s) 258 in the recess using a CVD technique, a PVD technique, an ALD technique, an electroplating technique, another deposition technique described above in connection with FIG. 1, and/or a deposition technique other than as described above in connection with FIG. 1. In some implementations, a planarization tool 110 may be used to planarize the interconnect structure 214. In some implementations, a seed layer is deposited in the recess prior to formation of the electrode 260 to promote adhesion between the liner layer(s) 258 and the electrode 260.

As shown in FIG. 4N, the capacitor structure 216 of the memory cell structure 202 may be formed over the interconnect structure 214 of the memory cell structure 202. The capacitor structure 216 may be electrically coupled with the transistor structure 252 through the interconnect structure 214. FIGS. 4O-4T illustrate example operations for forming the capacitor structure 216.

As shown in FIG. 4O, the ESL 262 may be formed over and/or on the isolation layer 256. The passivation layer 264 may be formed over and/or on the ESL 262. The isolation layer 266 may be formed over and/or on the passivation layer 264. A deposition tool 102 may be used to deposit the ESL 262, the passivation layer 264, and/or the isolation layer 266 using a CVD technique, a PVD technique, an ALD technique, an oxidation technique, another deposition technique described above in connection with FIG. 1, and/or a deposition technique other than as described above in connection with FIG. 1. In some implementations, a planarization tool 110 is used to planarize the ESL 262, the passivation layer 264, and/or the isolation layer 266.

As further shown in FIG. 4O, a recess 402 is formed through the ESL 262, the passivation layer 264, and/or the isolation layer 266. The recess 402 may be formed over the interconnect structure 214 such that the top surface of the interconnect structure 214 is exposed through the recess 402.

In some implementations, a pattern in a photoresist layer is used to form the recess 402 in the ESL 262, the passivation layer 264, and/or the isolation layer 266 over and to the interconnect structure 214. In these implementations, a deposition tool 102 may be used to form the photoresist layer on the isolation layer 266. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch into the ESL 262, the passivation layer 264, and/or the isolation layer 266 based on the pattern to form the recess 402. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess 402 based on a pattern.

As shown in FIG. 4P, the first bottom electrode layer 268a of the bottom electrode 268 of the capacitor structure 216 may be formed in the recess 402. In particular, the first bottom electrode layer 268a may be conformally deposited on the sidewalls and on the bottom surface of the recess 402 such that the first bottom electrode layer 268a conforms to the shape or profile of the recess 402. The bottom surface of the recess 402 may correspond to the top surface of the interconnect structure 214. Accordingly, the first bottom electrode layer 268a is deposited on the top surface of the interconnect structure 214. A deposition tool 102 and/or a plating tool 112 may be used to deposit the first bottom electrode layer 268a using a CVD technique, a PVD technique, an ALD technique, an electroplating technique, another deposition technique described above in connection with FIG. 1, and/or a deposition technique other than as described above in connection with FIG. 1.

As shown in FIG. 4Q, the hydrogen absorption layer 270 of the capacitor structure 216 may be formed over and/or on the first bottom electrode layer 268a. In particular, the hydrogen absorption layer 270 may be conformally deposited over the sidewalls and over the bottom surface of the recess 402 such that the hydrogen absorption layer 270 conforms to the shape or profile of the recess 402. A deposition tool 102 and/or a plating tool 112 may be used to deposit the hydrogen absorption layer 270 using a CVD technique, a PVD technique, an ALD technique, an oxidation technique, another deposition technique described above in connection with FIG. 1, and/or a deposition technique other than as described above in connection with FIG. 1.

As shown in FIG. 4R, the second bottom electrode layer 268b of the bottom electrode 268 of the capacitor structure 216 may be formed over and/or on the hydrogen absorption layer 270 in the recess 402. In particular, the second bottom electrode layer 268b may be conformally deposited over the sidewalls and over the bottom surface of the recess 402 such that the second bottom electrode layer 268b conforms to the shape or profile of the recess 402. A deposition tool 102 and/or a plating tool 112 may be used to deposit the second bottom electrode layer 268b using a CVD technique, a PVD technique, an ALD technique, an electroplating technique, another deposition technique described above in connection with FIG. 1, and/or a deposition technique other than as described above in connection with FIG. 1.

As shown in FIG. 4S, the dielectric layer 272 of the capacitor structure 216 may be formed over and/or on the second bottom electrode layer 268b. In particular, the dielectric layer 272 may be conformally deposited over the sidewalls and over the bottom surface of the recess 402 such that the dielectric layer 272 conforms to the shape or profile of the recess 402. A deposition tool 102 and/or a plating tool 112 may be used to deposit the dielectric layer 272 using a CVD technique, a PVD technique, an ALD technique, an oxidation technique, another deposition technique described above in connection with FIG. 1, and/or a deposition technique other than as described above in connection with FIG. 1.

As shown in FIG. 4T, the top electrode 274 of the capacitor structure 216 may be formed over and/or on the dielectric layer 272 in the recess 402. In particular, the top electrode 274 may be deposited to fill the remaining volume in the recess 402. A deposition tool 102 and/or a plating tool 112 may be used to deposit the top electrode 274 using a CVD technique, a PVD technique, an ALD technique, an electroplating technique, another deposition technique described above in connection with FIG. 1, and/or a deposition technique other than as described above in connection with FIG. 1.

In some implementations, a planarization tool 110 may be used to planarize the first bottom electrode layer 268a, the second bottom electrode layer 268b, the hydrogen absorption layer 270, the dielectric layer 272, and/or the top electrode 274. In some implementations, the first bottom electrode layer 268a, the second bottom electrode layer 268b, the hydrogen absorption layer 270, the dielectric layer 272, and/or the top electrode 274 are deposited over the top surface of the isolation layer 266, and the planarization tool 110 is used to remove the excess material from the top surface of the isolation layer 266.

Subsequent semiconductor processing operations may be performed for forming layers and/or structures in the semiconductor device 200 after formation of the capacitor structure 216. For example, additional dielectric layers and/or additional metallization layers may be formed above the capacitor structure 216. The subsequent semiconductor processing operations may involve the use of hydrogen (e.g., as a carrier gas, as a purge gas, as an element of a deposited material) and/or heat treatment, either of which can cause hydrogen to diffuse down into the memory cell structure 202 and contaminate the channel layer 206 of the transistor structure 252, which can lead to degraded performance and/or failure of the memory cell structure 202. However, the hydrogen absorption layer 270 in the capacitor structure 216 instead absorbs the hydrogen, thereby blocking, minimizing, and/or reducing the likelihood of the hydrogen diffusing past the capacitor structure 216 and into the transistor structure 252. In this way, the hydrogen absorption layer 270 of the capacitor structure 216 may minimize and/or reduce the likelihood of contamination of the channel layer 206, which may minimize and/or reduce the likelihood of degraded performance and/or failure of the memory cell structure 202.

As indicated above, FIGS. 4A-4T are provided as an example. Other examples may differ from what is described with regard to FIGS. 4A-4T.

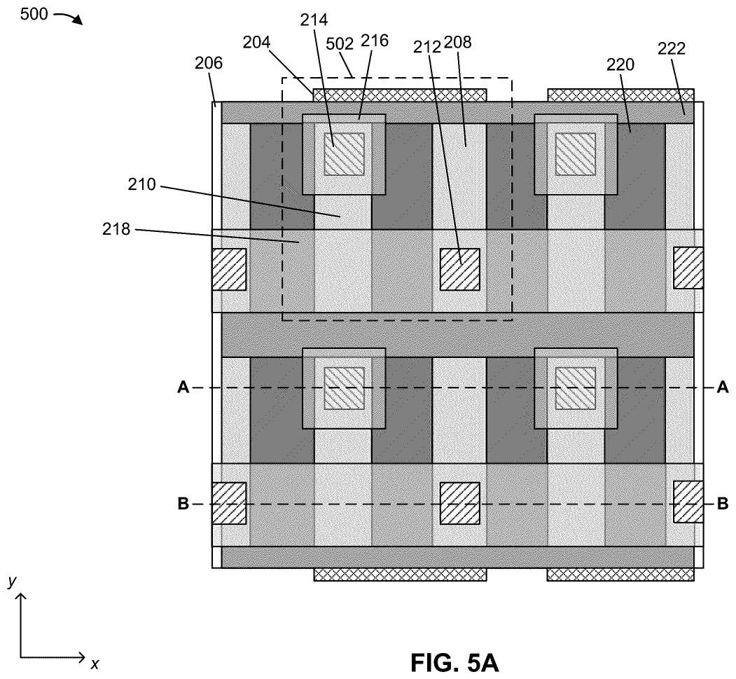

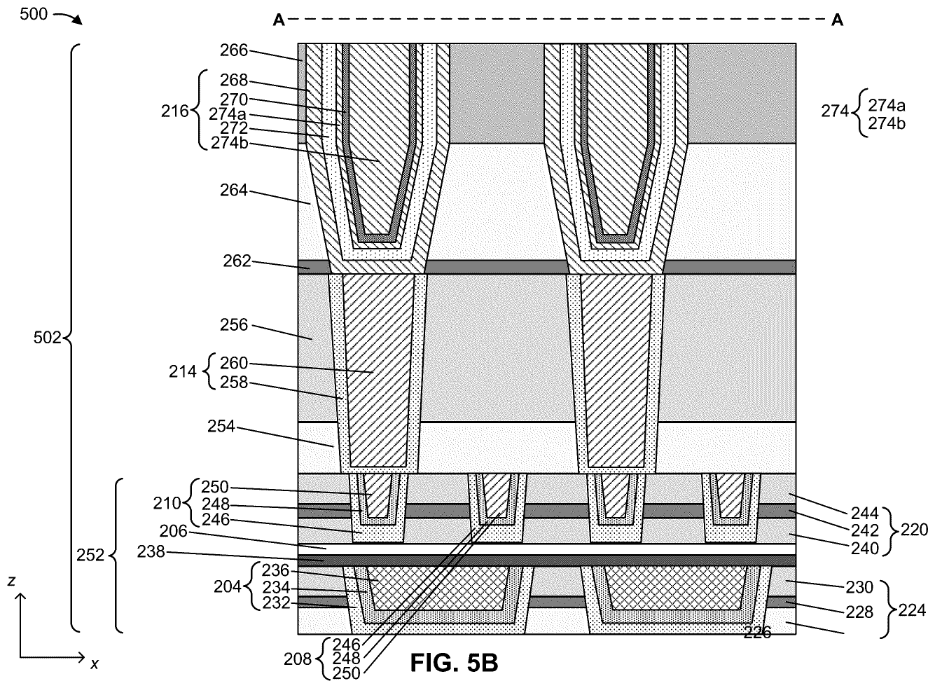

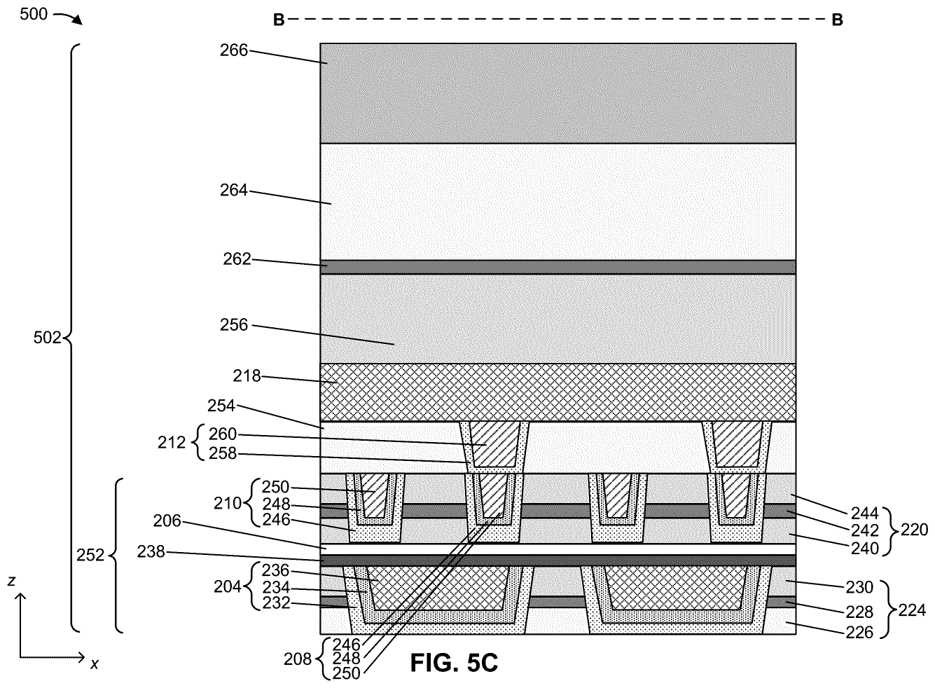

FIGS. 5A-5C are diagrams of an example semiconductor device 500 described herein. As shown in FIGS. 5A-5C, the semiconductor device 500 may include a memory array that includes a plurality of memory cell structures 502. The memory array may be included in one or more back end dielectric layers (e.g., BEOL dielectric layers) in the BEOL region of the semiconductor device 500. The memory cell structures 502 may include volatile memory structures, such as DRAM memory structures and/or another type of volatile memory structures.

As further shown in FIGS. 5A-5C, a memory cell structure 502 may include a similar combination and arrangement of components 204-276 as the memory cell structure 202. However, in the memory cell structure 502, the hydrogen absorption layer 270 is included between a first top electrode layer 274a and a second top electrode layer 274b of the top electrode. Thus, the capacitor structure 216 of the memory cell structure 502 may include a bottom electrode 268, a dielectric layer 272 between the bottom electrode 268 and the first top electrode layer 274a, and the hydrogen absorption layer 270 between the first top electrode layer 274a and the second top electrode layer 274b.

Including the hydrogen absorption layer 270 between the first bottom electrode layer 268a and the second bottom electrode layer 268b, as shown in the memory cell structure 202, provides a large radius area across which the hydrogen absorption layer 270 may absorb hydrogen in the semiconductor device 200. Including the hydrogen absorption layer 270 between the first top electrode layer 274a and the second top electrode layer 274b, as shown in the memory cell structure 502, provides flexibility for the thickness of the hydrogen absorption layer 270, and enables the thickness of the hydrogen absorption layer 270 to be determined based on a depth-to-width ratio of the capacitor structure 216.

As indicated above, FIGS. 5A-5C are provided as an example. Other examples may differ from what is described with regard to FIGS. 5A-5C.

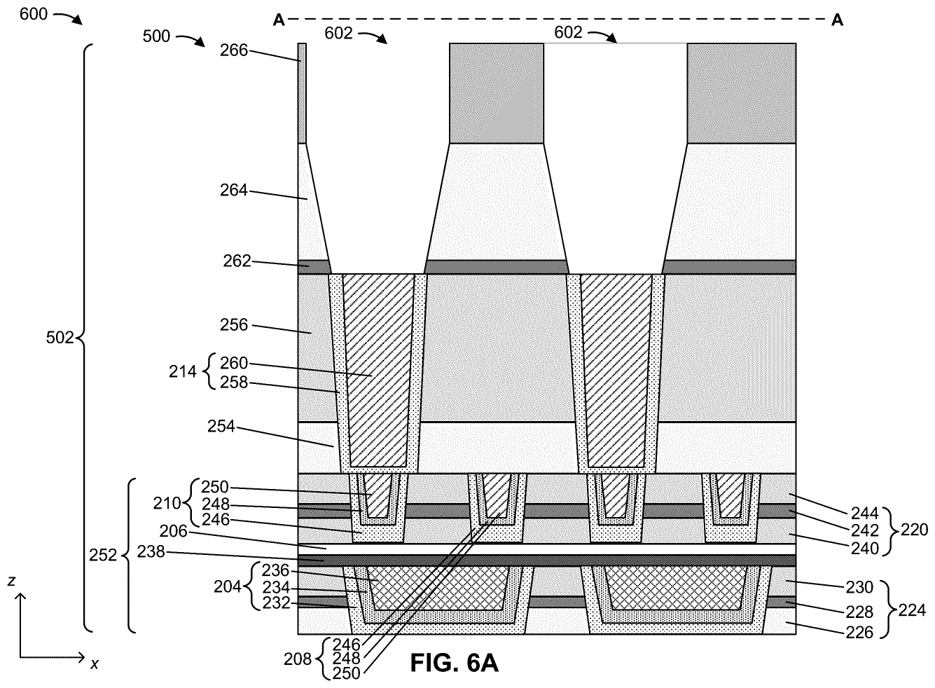

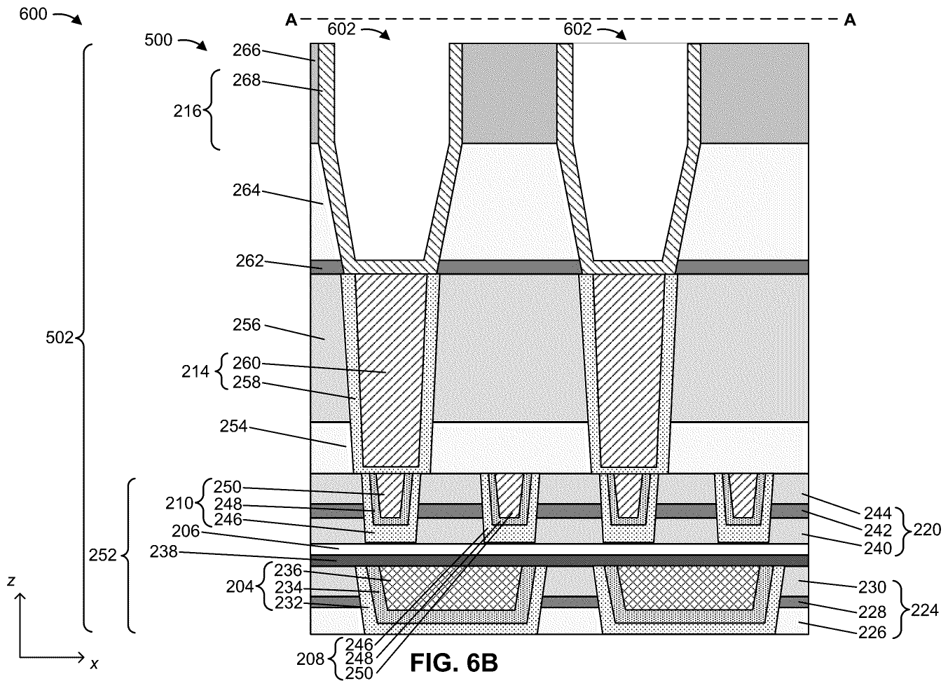

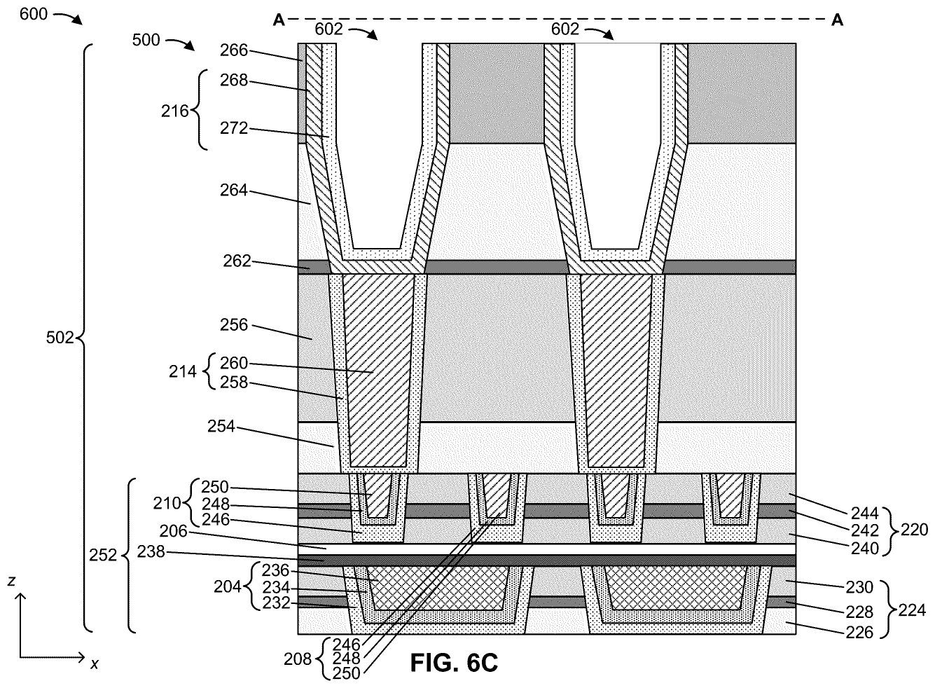

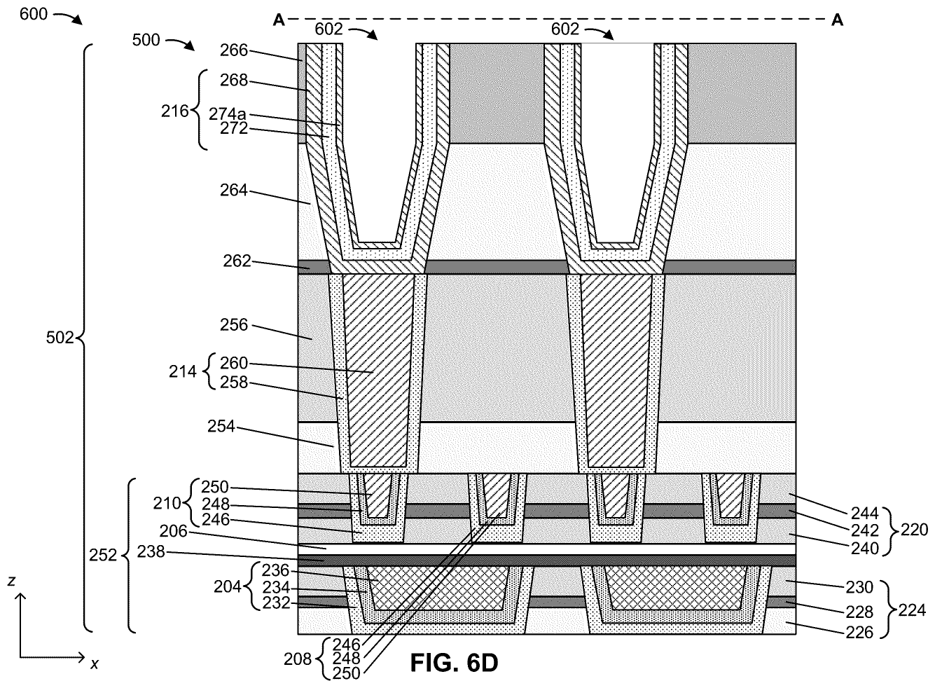

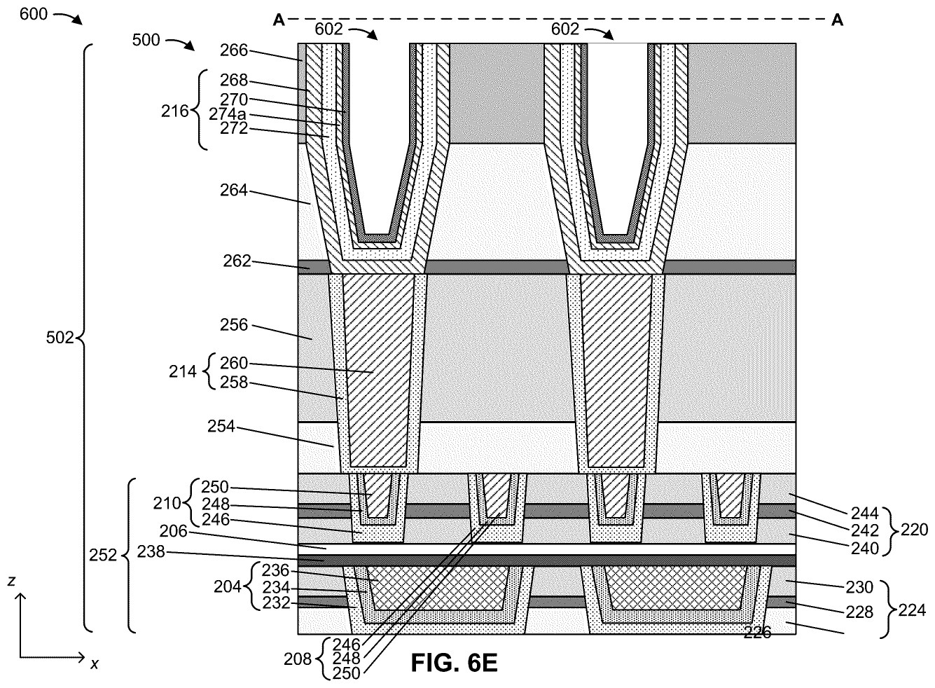

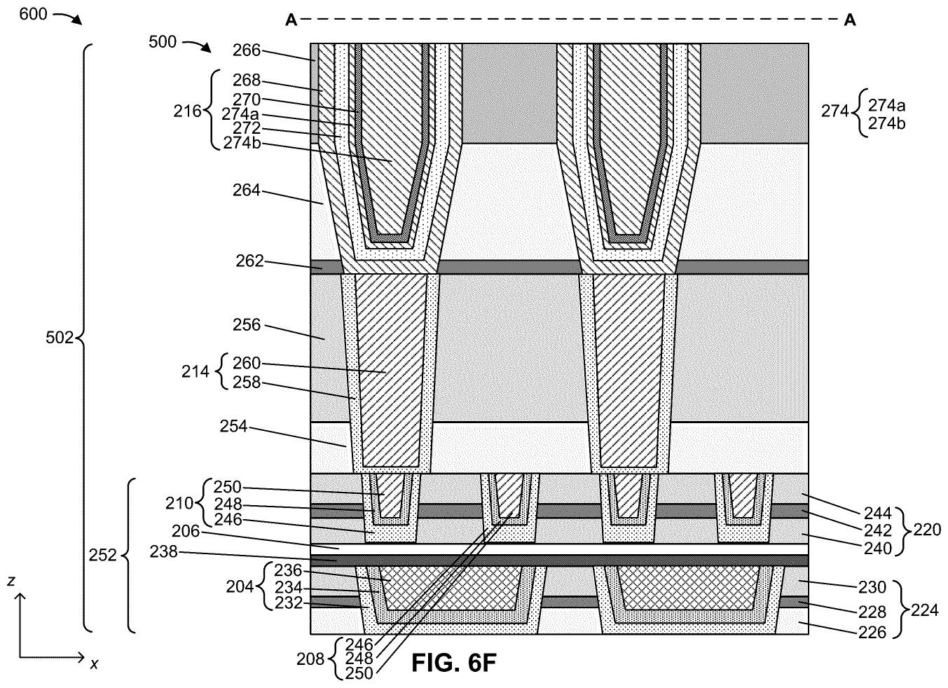

FIGS. 6A-6F are diagrams of an example implementation 600 of forming a memory cell structure 502 of the semiconductor device 500 described herein. In some implementations, one or more of the processing operations described in connection with FIGS. 6A-6F may be performed using one or more of the semiconductor processing tools 102-112 and/or the wafer/die transport tool 114. In some implementations, one or more of the processing operations described in connection with FIGS. 6A-6F may be performed using another semiconductor processing tool not shown in FIG. 1.

As shown in FIG. 6A, one or more semiconductor processing operations described in connection with FIGS. 4A-4M may be performed to form components 204-214 and 218-266 of the memory cell structure 502 of the semiconductor device 500. As further shown in FIG. 6A, a recess 602 is formed through the ESL 262, the passivation layer 264, and/or the isolation layer 266. The recess 602 may be formed over the interconnect structure 214 such that the top surface of the interconnect structure 214 is exposed through the recess 602.

As shown in FIG. 6B, the bottom electrode 268 of the capacitor structure 216 of the memory cell structure 502 may be formed in the recess 602. In particular, the bottom electrode 268 may be conformally deposited on the sidewalls and on the bottom surface of the recess 602 such that the bottom electrode 268 conforms to the shape or profile of the recess 602. The bottom surface of the recess 602 may correspond to the top surface of the interconnect structure 214. Accordingly, the bottom electrode 268 is deposited on the top surface of the interconnect structure 214. A deposition tool 102 and/or a plating tool 112 may be used to deposit the bottom electrode 268 using a CVD technique, a PVD technique, an ALD technique, an electroplating technique, another deposition technique described above in connection with FIG. 1, and/or a deposition technique other than as described above in connection with FIG. 1.

As shown in FIG. 6C, the dielectric layer 272 of the capacitor structure 216 of the memory cell structure 502 may be formed over and/or on the bottom electrode 268. In particular, the dielectric layer 272 may be conformally deposited over the sidewalls and over the bottom surface of the recess 602 such that the dielectric layer 272 conforms to the shape or profile of the recess 602. A deposition tool 102 and/or a plating tool 112 may be used to deposit the dielectric layer 272 using a CVD technique, a PVD technique, an ALD technique, an oxidation technique, another deposition technique described above in connection with FIG. 1, and/or a deposition technique other than as described above in connection with FIG. 1.

As shown in FIG. 6D, the first top electrode layer 274a of the top electrode 274 of the capacitor structure 216 may be formed over and/or on the dielectric layer 272 in the recess 602. In particular, the first top electrode layer 274a may be conformally deposited over the sidewalls and over the bottom surface of the recess 602 such that the first top electrode layer 274a conforms to the shape or profile of the recess 602. A deposition tool 102 and/or a plating tool 112 may be used to deposit the first top electrode layer 274a using a CVD technique, a PVD technique, an ALD technique, an electroplating technique, another deposition technique described above in connection with FIG. 1, and/or a deposition technique other than as described above in connection with FIG. 1.

As shown in FIG. 6E, the hydrogen absorption layer 270 of the capacitor structure 216 of the memory cell structure 502 may be formed over and/or on the first top electrode layer 274a. In particular, the hydrogen absorption layer 270 may be conformally deposited over the sidewalls and over the bottom surface of the recess 602 such that the hydrogen absorption layer 270 conforms to the shape or profile of the recess 602. A deposition tool 102 and/or a plating tool 112 may be used to deposit the hydrogen absorption layer 270 using a CVD technique, a PVD technique, an ALD technique, an oxidation technique, another deposition technique described above in connection with FIG. 1, and/or a deposition technique other than as described above in connection with FIG. 1.

As shown in FIG. 6F, the second top electrode layer 274b of the top electrode 274 of the capacitor structure 216 may be formed over and/or on the hydrogen absorption layer 270 in the recess 602. In particular, the second bottom electrode layer 268b may be deposited to fill the remaining volume in the recess 602. A deposition tool 102 and/or a plating tool 112 may be used to deposit the second top electrode layer 274b using a CVD technique, a PVD technique, an ALD technique, an electroplating technique, another deposition technique described above in connection with FIG. 1, and/or a deposition technique other than as described above in connection with FIG. 1.

In some implementations, a planarization tool 110 may be used to planarize the bottom electrode 268, the hydrogen absorption layer 270, the dielectric layer 272, the first top electrode layer 274a, and/or the second top electrode layer 274b. In some implementations, the bottom electrode 268, the hydrogen absorption layer 270, the dielectric layer 272, the first top electrode layer 274a, and/or the second top electrode layer 274b are deposited over the top surface of the isolation layer 266, and the planarization tool 110 is used to remove the excess material from the top surface of the isolation layer 266.

Subsequent semiconductor processing operations may be performed for forming layers and/or structures in the semiconductor device 500 after formation of the capacitor structure 216. For example, additional dielectric layers and/or additional metallization layers may be formed above the capacitor structure 216. The subsequent semiconductor processing operations may involve the use of hydrogen (e.g., as a carrier gas, as a purge gas, as an element of a deposited material) and/or heat treatment, either of which can cause hydrogen to diffuse down into the memory cell structure 502 and contaminate the channel layer 206 of the transistor structure 252, which can lead to degraded performance and/or failure of the memory cell structure 502. However, the hydrogen absorption layer 270 in the capacitor structure 216 instead absorbs the hydrogen, thereby blocking, minimizing, and/or reducing the likelihood of the hydrogen diffusing past the capacitor structure 216 and into the transistor structure 252. In this way, the hydrogen absorption layer 270 of the capacitor structure 216 may minimize and/or reduce the likelihood of contamination of the channel layer 206, which may minimize and/or reduce the likelihood of degraded performance and/or failure of the memory cell structure 502.

As indicated above, FIGS. 6A-6F are provided as an example. Other examples may differ from what is described with regard to FIGS. 6A-6F.

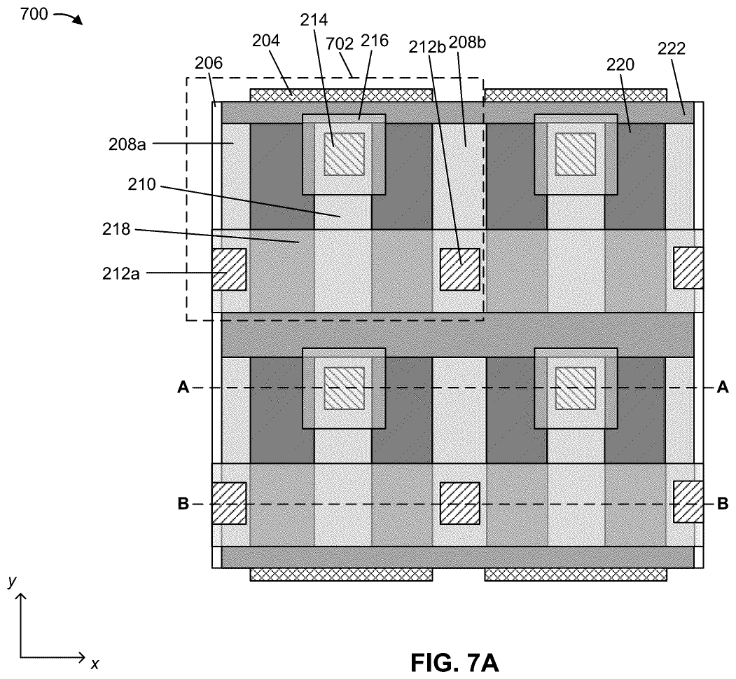

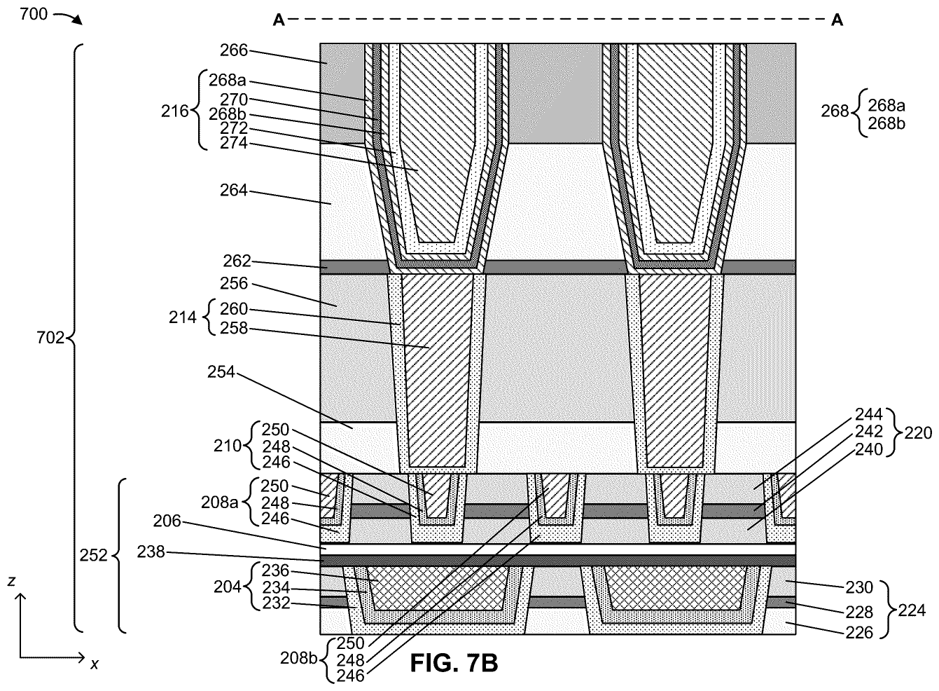

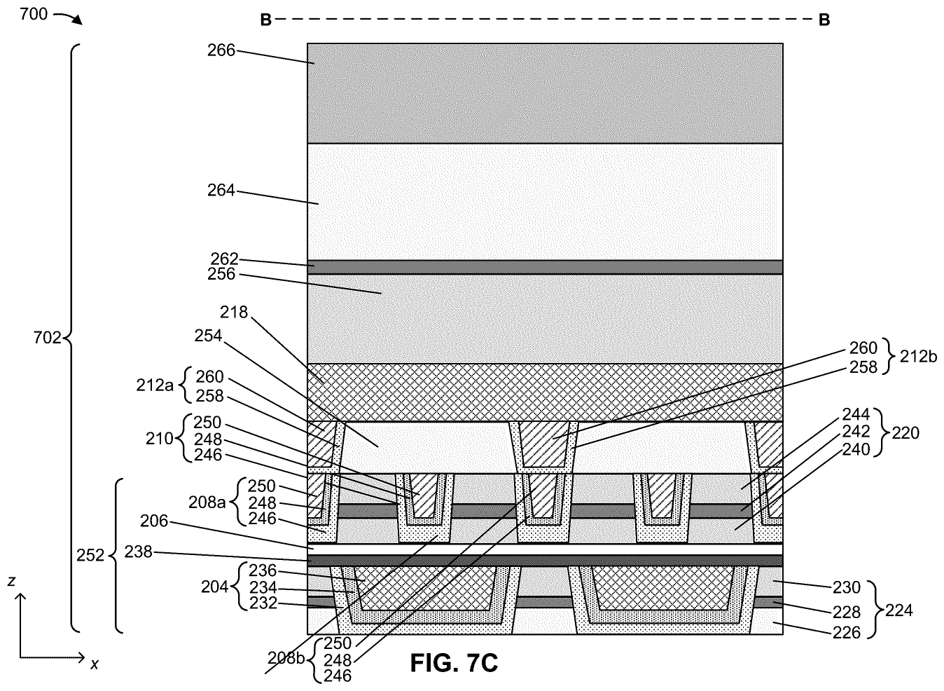

FIGS. 7A-7C are diagrams of an example semiconductor device 700 described herein. As shown in FIGS. 7A-7C, the semiconductor device 700 may include a memory array that includes a plurality of memory cell structures 702. The memory array may be included in one or more back end dielectric layers (e.g., BEOL dielectric layers) in the BEOL region of the semiconductor device 700. The memory cell structures 702 may include volatile memory structures, such as DRAM memory structures and/or another type of volatile memory structures.

As further shown in FIGS. 7A-7C, a memory cell structure 702 may include a similar combination and arrangement of components 204-276 as the memory cell structure 202. However, in the memory cell structure 702, the transistor structure 252 includes a dual-channel transistor structure as opposed to a single-channel transistor structure. In particular, and as illustrated in FIG. 7B, the source/drain region 210 that is coupled with the capacitor structure 216 through the interconnection structure 214 may be located directly over the gate structure 204, and the memory cell structure 702 may further include a plurality of source/drain regions 208a and 210b located above and adjacent to opposing sides of the gate structure 204. Thus, a first channel in the channel layer 206 of the transistor structure 252 is located between the source/drain region 208a and the source/drain region 210, and a second channel in the channel layer 206 of the transistor structure 252 is located between the source/drain region 208b and the source/drain region 210. The source/drain regions 208a and 210b may each be electrically coupled and/or physically coupled with the same bit line conductive structure 218, or may be electrically coupled and/or physically coupled with different bit line conductive structures 218.

The dual-channel configuration of the transistor structure 252 of the memory cell structure 702 enables an increased on current (e.g., approximately double the on current) to be achieved for the memory cell structure 702 relative to the memory cell structure 202. However, the memory cell structure 202 may offer reduced manufacturing complexity and increased memory cell density relative to the memory cell structure 702.

As indicated above, FIGS. 7A-7C are provided as an example. Other examples may differ from what is described with regard to FIGS. 7A-7C.

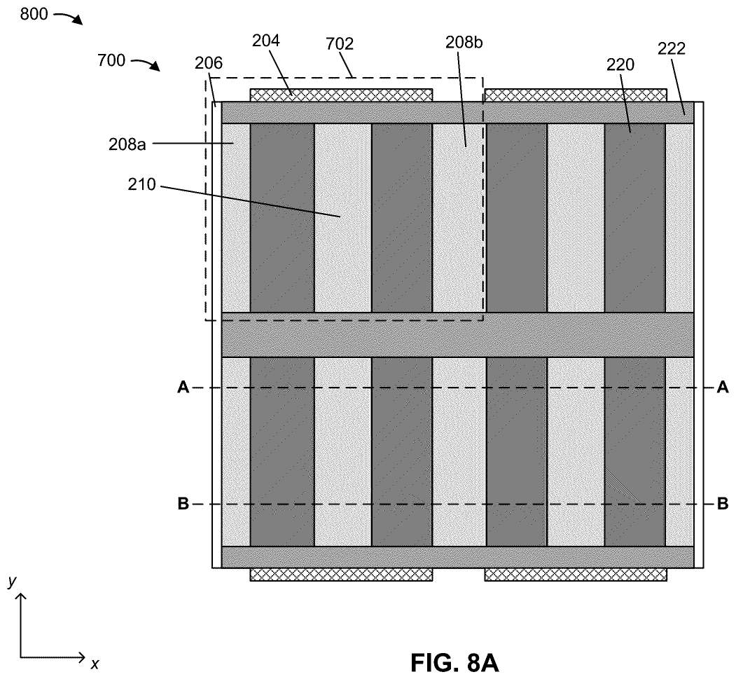

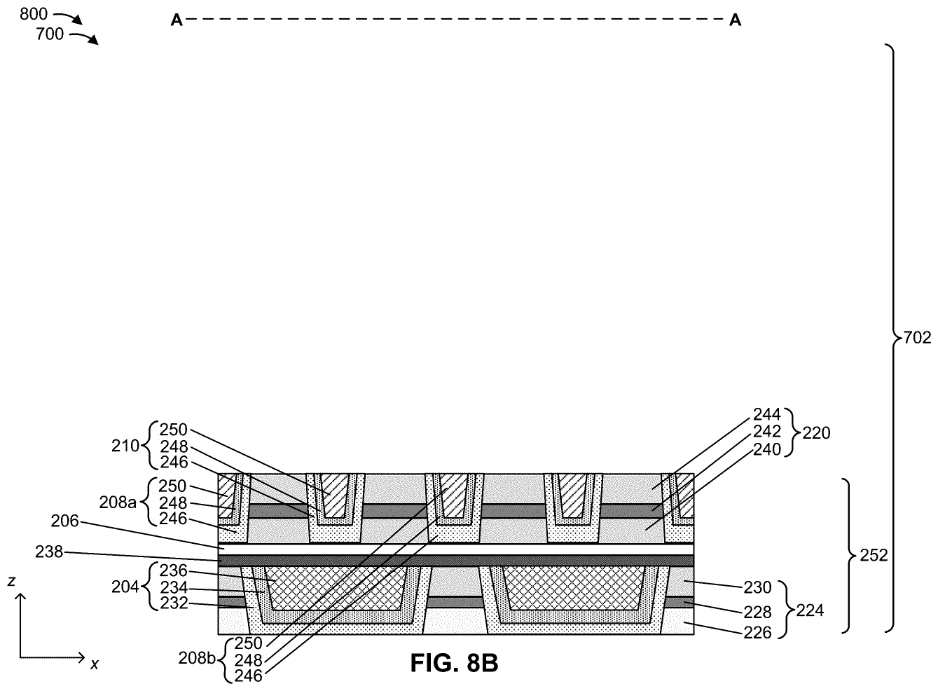

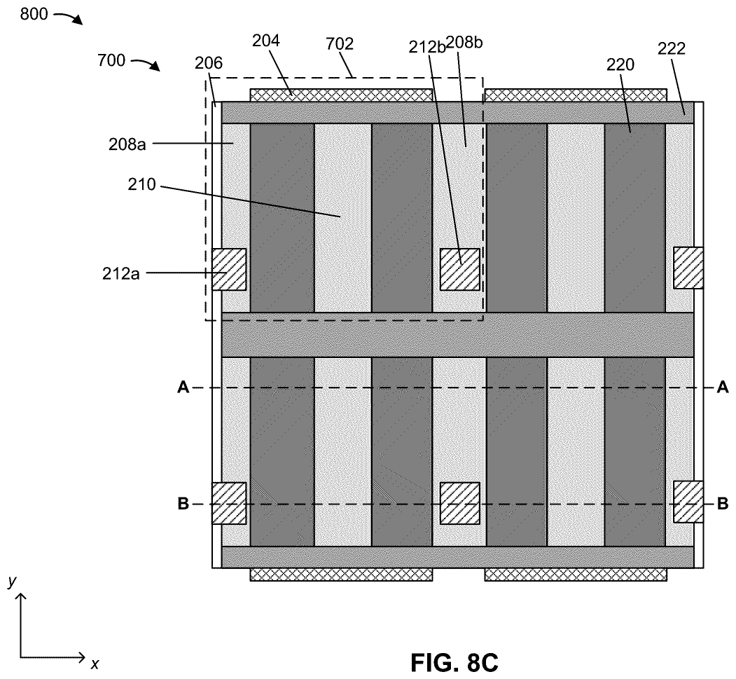

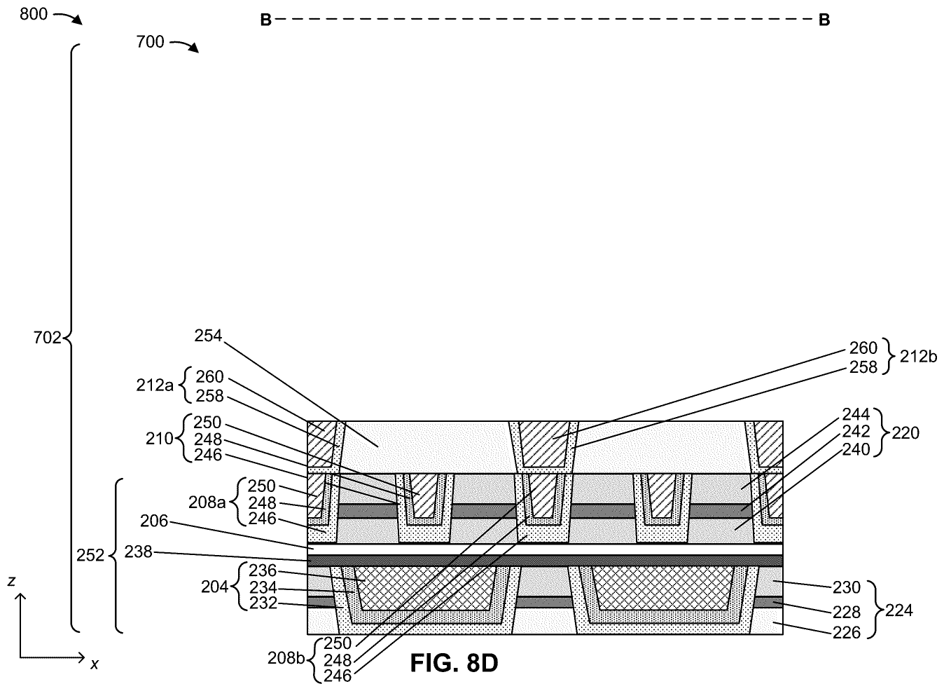

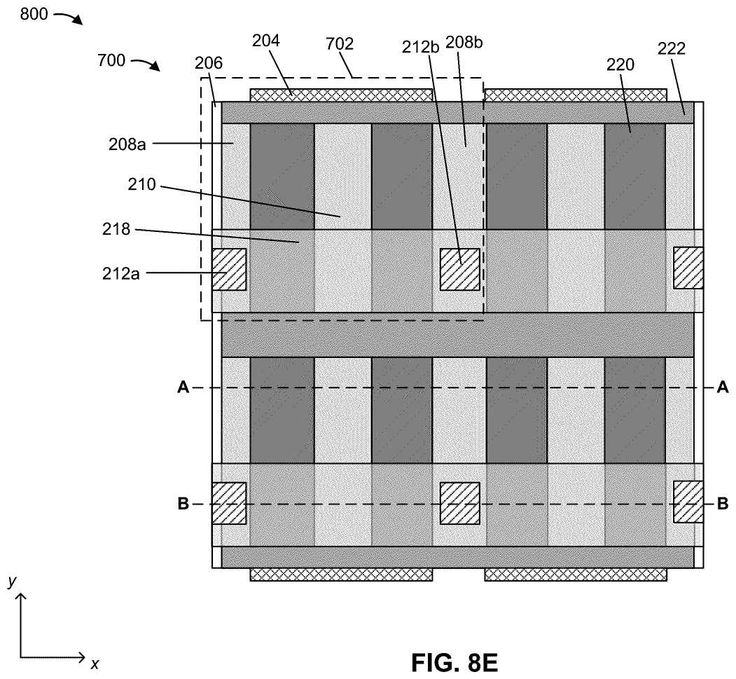

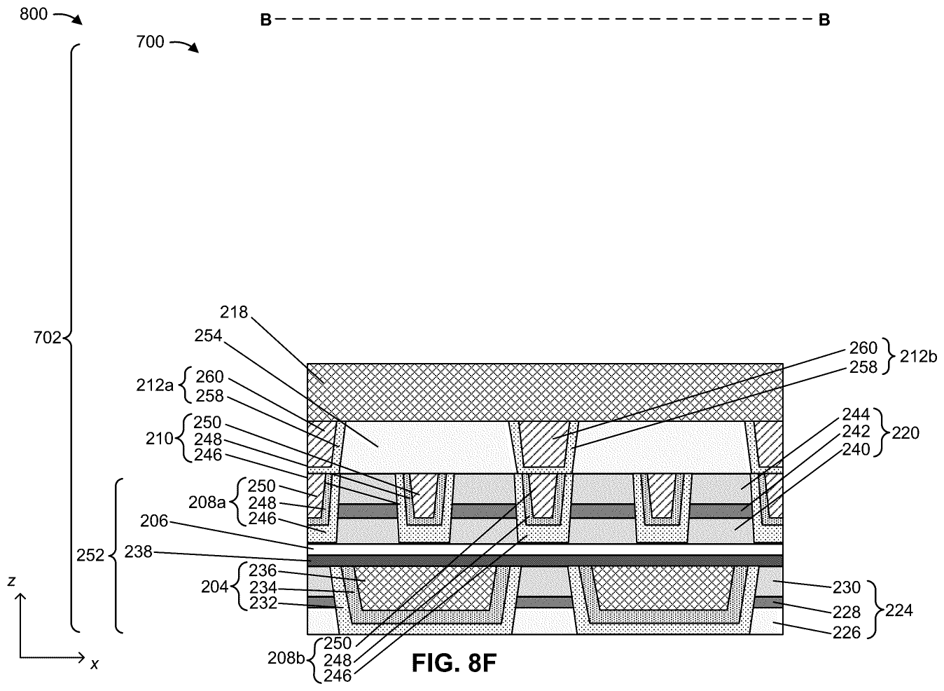

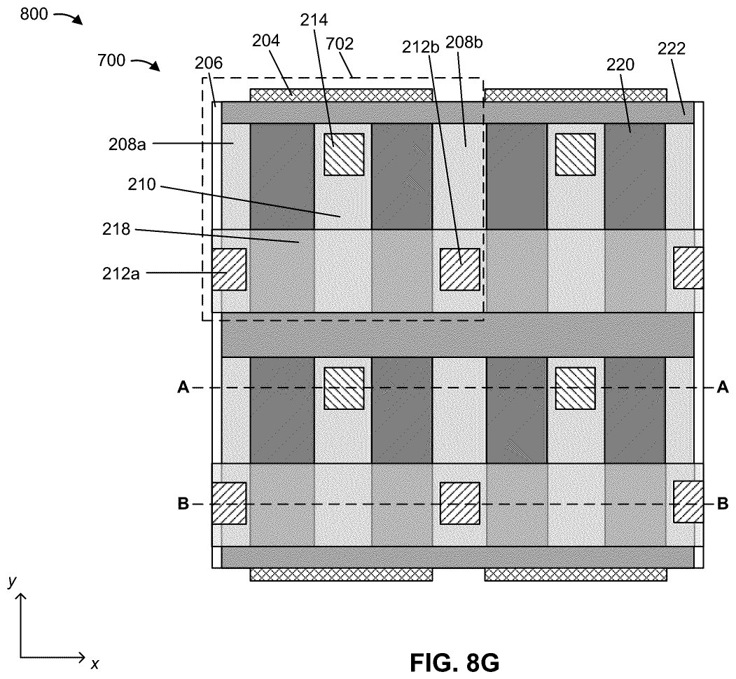

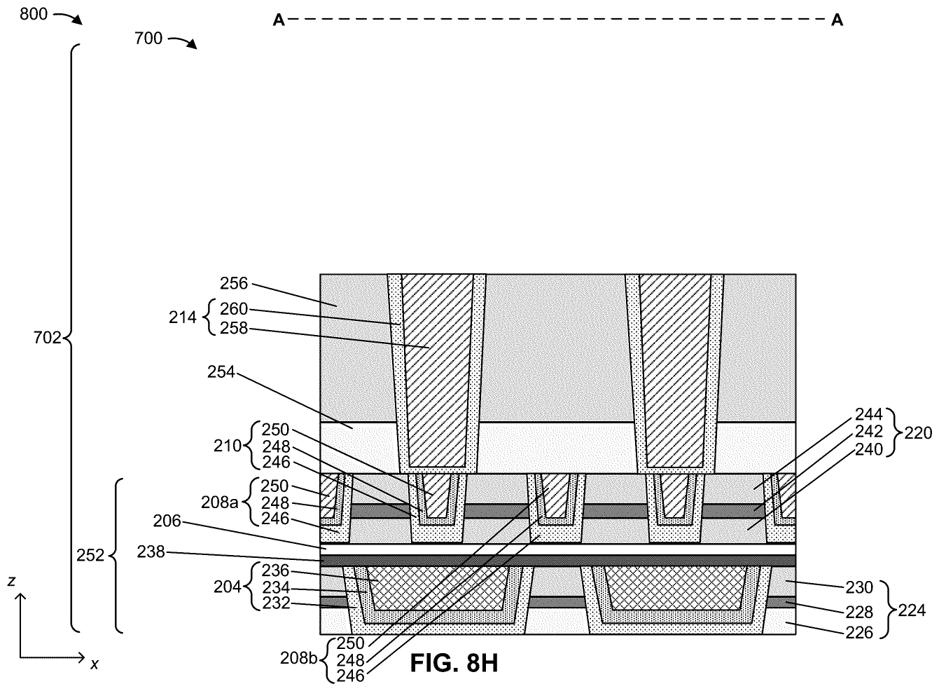

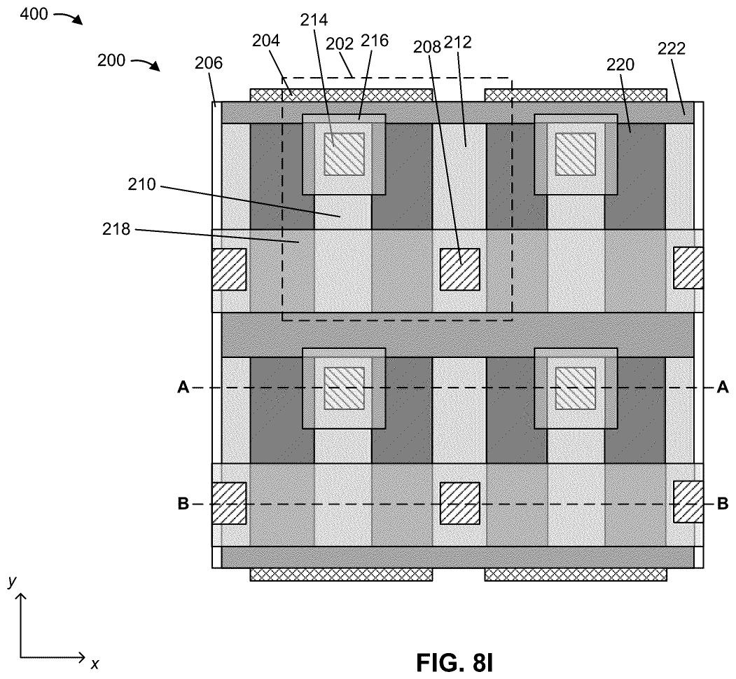

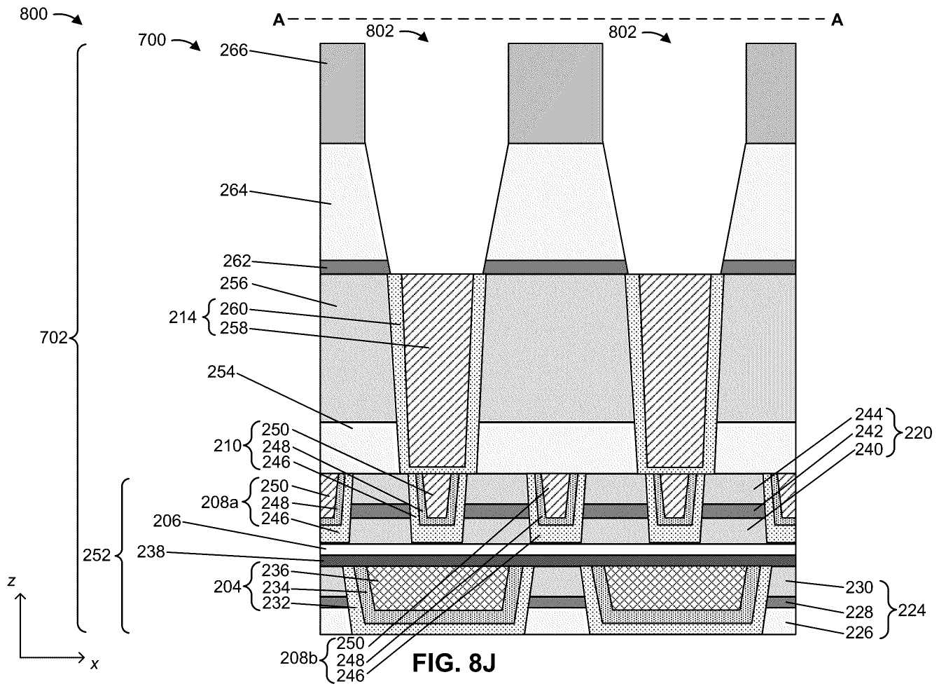

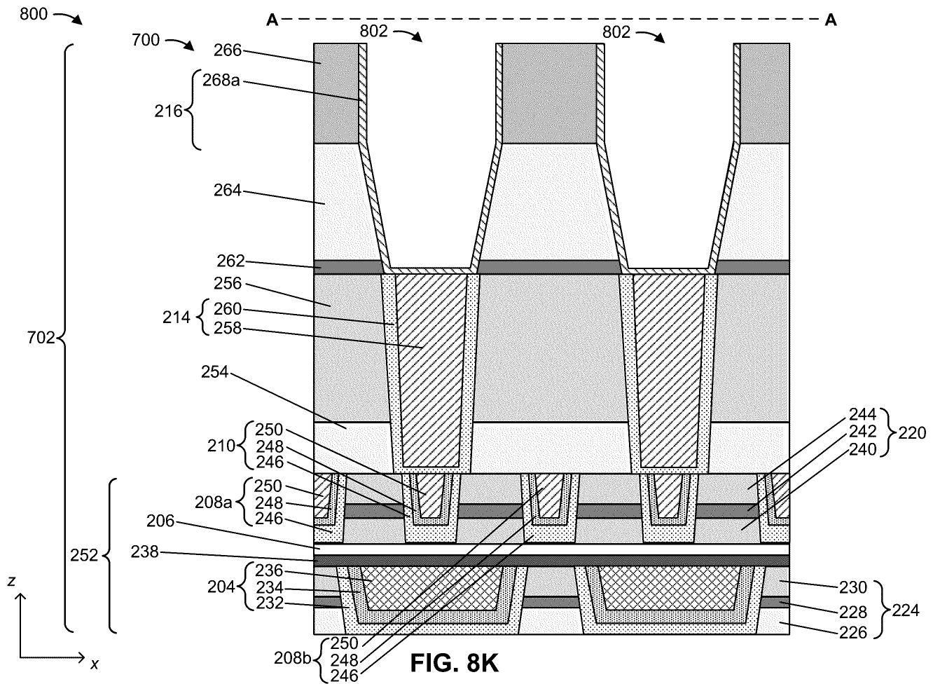

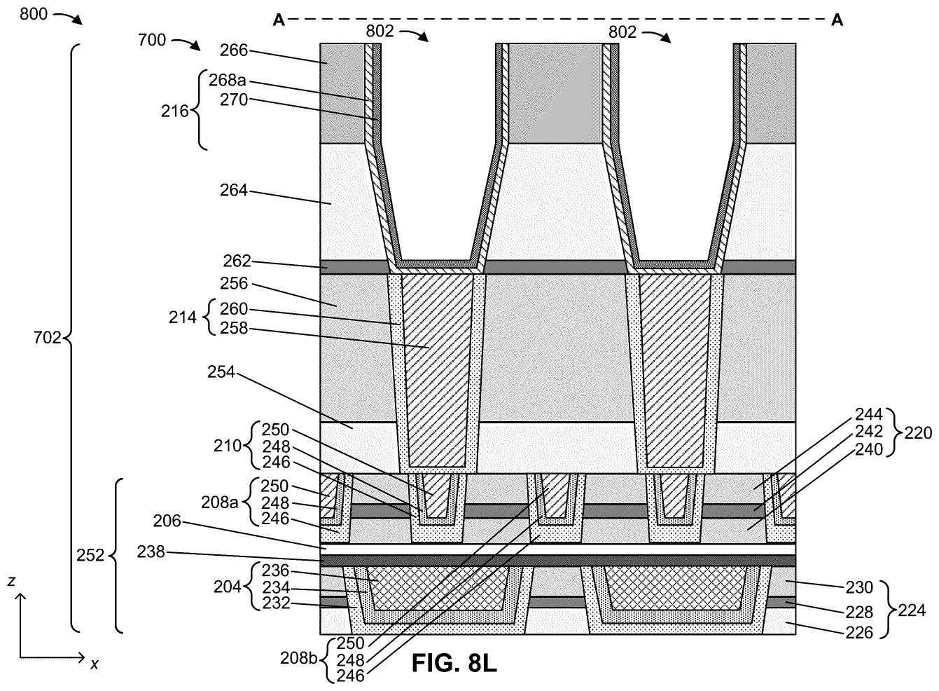

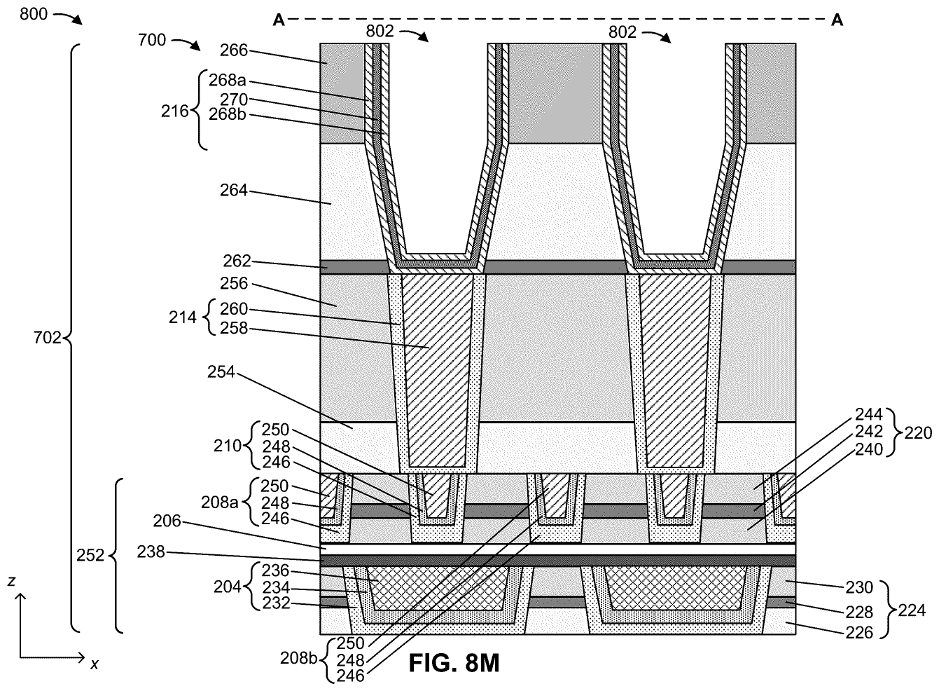

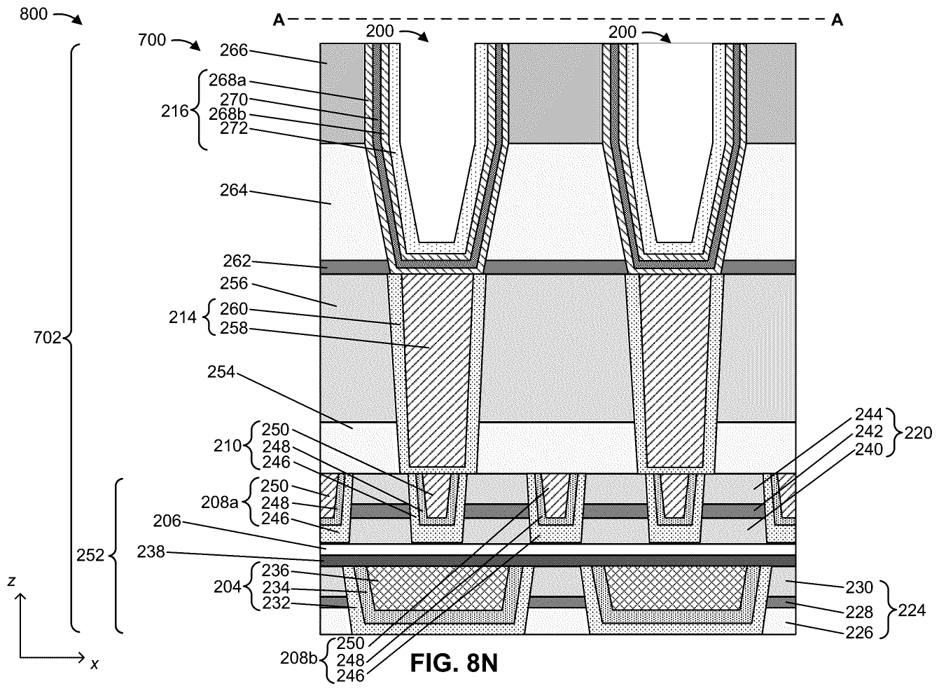

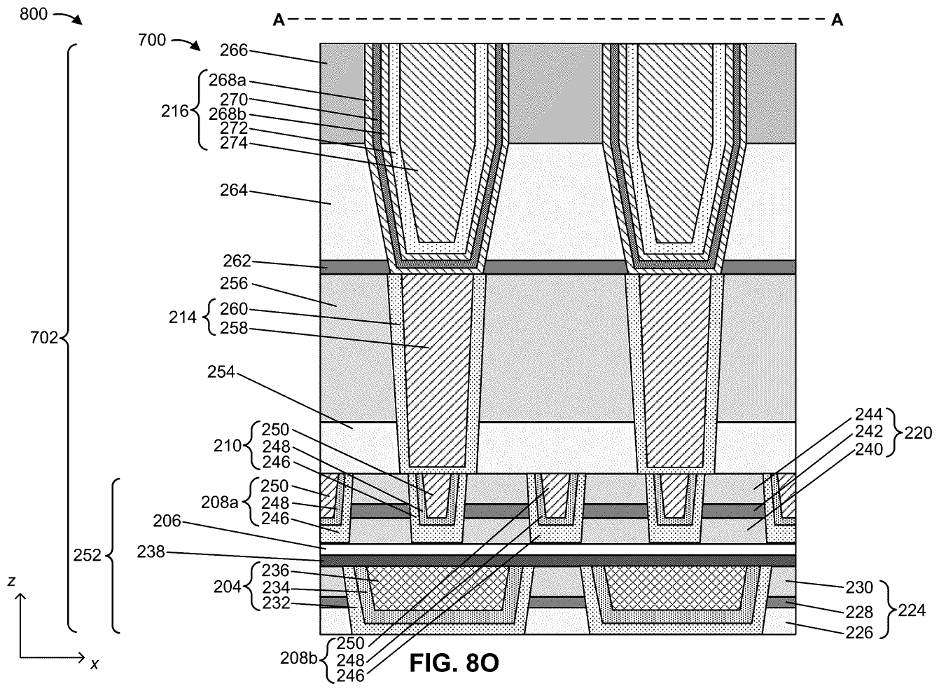

FIGS. 8A-8O are diagrams of an example implementation 800 of forming a memory cell structure 702 of the semiconductor device 700 described herein. In some implementations, one or more of the processing operations described in connection with FIGS. 8A-8O may be performed using one or more of the semiconductor processing tools 102-112 and/or the wafer/die transport tool 114. In some implementations, one or more of the processing operations described in connection with FIGS. 8A-8O may be performed using another semiconductor processing tool not shown in FIG. 1.

As shown in FIGS. 8A and 8B, one or more semiconductor processing operations described in connection with FIGS. 4A-4G may be performed to form components 204-210, 220-252 of the memory cell structure 702 of the semiconductor device 700. However, additional semiconductor processing operations may be performed to form a plurality of source/drain regions 208, including the source/drain region 208a above the gate structure 204 and a source/drain region 208b above the gate structure 204 in the memory cell structure 702. The source/drain region 208a may be formed adjacent to a first side of the gate structure 204, and the source/drain region 208b may be formed adjacent to a section side of the gate structure 204 opposing the first side. The source/drain region 210 may be formed directly above the gate structure 204 such that a first channel is formed in the channel layer 206 between the source/drain region 208a and the source/drain region 210, and a second channel is formed in the channel layer 206 between the source/drain region 208b and the source/drain region 210. In this way, the transistor structure 252 is a dual-channel transistor structure.

As shown in FIGS. 8C and 8D, interconnect structures 212 of the memory cell structure 702 may be formed over and/or on the source/drain regions 208a and 210b. The interconnect structures 212 may land on the source/drain regions 208a and 208b such that the interconnect structures 212 are physically coupled and/or electrically coupled with the source/drain regions 208a and 208b.

As shown in FIGS. 8E and 8F, a bit line conductive structure 218 of the memory cell structure 702 may be formed over the interconnect structures 212 such that the bit line conductive structure 218 is located above the transistor structure 252. The bit line conductive structure 218 may land on the interconnect structures 212 such that the interconnect structures 212 are coupled with the bit line conductive structure 218. In this way, the interconnect structures 212 electrically couple the transistor structure 252 with the bit line conductive structure 218 through the source/drain regions 208a and 208b. Alternatively, the source/drain regions 208a and 208b may each be electrically coupled with different bit line conductive structures 218. The bit line conductive structure 218 may extend in the x-direction in the semiconductor device 200.

As shown in FIGS. 8G-8O, one or more semiconductor processing operations described in connection with FIGS. 4L-4T may be performed to form components 214, 216, and 256-274 of the memory cell structure 702 of the semiconductor device 700, including forming the hydrogen absorption layer 270 in a recess 802 in which the capacitor structure 216 is formed.

Subsequent semiconductor processing operations may be performed for forming layers and/or structures in the semiconductor device 700 after formation of the capacitor structure 216. For example, additional dielectric layers and/or additional metallization layers may be formed above the capacitor structure 216. The subsequent semiconductor processing operations may involve the use of hydrogen (e.g., as a carrier gas, as a purge gas, as an element of a deposited material) and/or heat treatment, either of which can cause hydrogen to diffuse down into the memory cell structure 702 and contaminate the channel layer 206 of the transistor structure 252, which can lead to degraded performance and/or failure of the memory cell structure 702. However, the hydrogen absorption layer 270 in the capacitor structure 216 instead absorbs the hydrogen, thereby blocking, minimizing, and/or reducing the likelihood of the hydrogen diffusing past the capacitor structure 216 and into the transistor structure 252. In this way, the hydrogen absorption layer 270 of the capacitor structure 216 may minimize and/or reduce the likelihood of contamination of the channel layer 206, which may minimize and/or reduce the likelihood of degraded performance and/or failure of the memory cell structure 702.

As indicated above, FIGS. 8A-8O are provided as an example. Other examples may differ from what is described with regard to FIGS. 8A-8O.

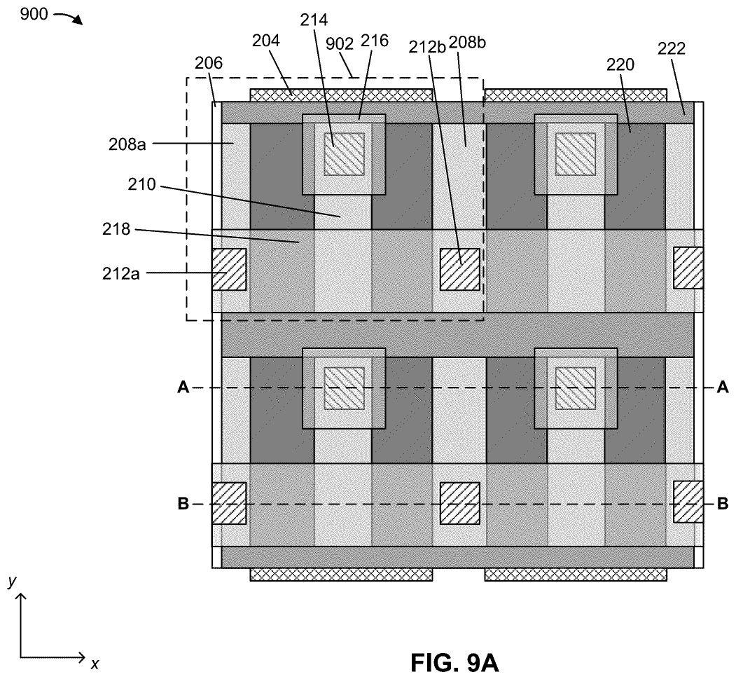

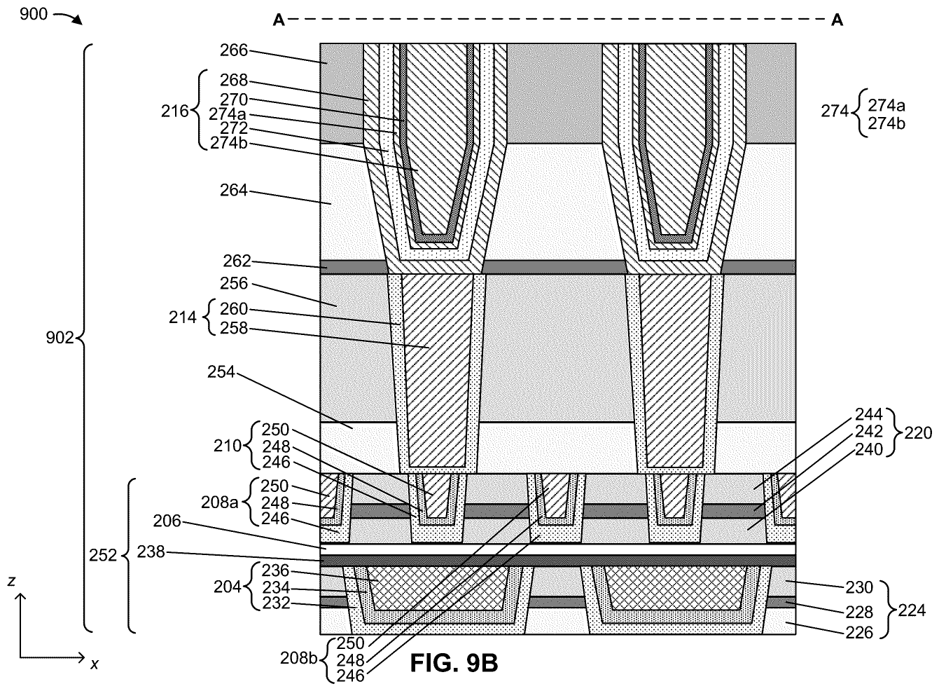

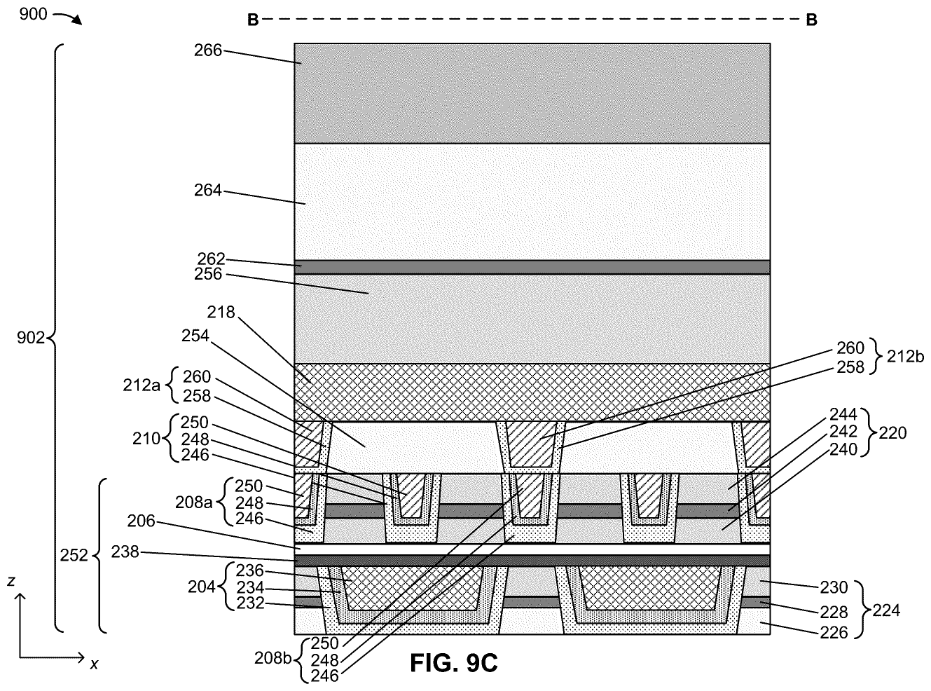

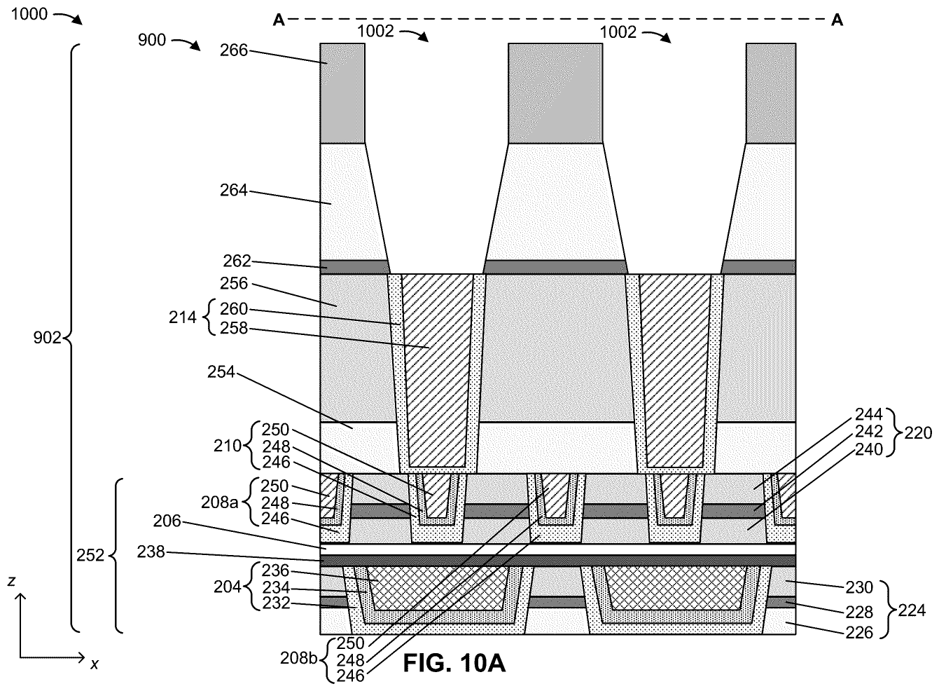

FIGS. 9A-9C are diagrams of an example semiconductor device 900 described herein. As shown in FIGS. 9A-9C, the semiconductor device 900 may include a memory array that includes a plurality of memory cell structures 902. The memory array may be included in one or more back end dielectric layers (e.g., BEOL dielectric layers) in the BEOL region of the semiconductor device 900. The memory cell structures 902 may include volatile memory structures, such as DRAM memory structures and/or another type of volatile memory structures.

As further shown in FIGS. 9A-9C, a memory cell structure 902 may include a similar combination and arrangement of components 204-276b as the memory cell structure 502. However, in the memory cell structure 902, the transistor structure 252 includes a dual-channel transistor structure as opposed to a single-channel transistor structure. In particular, and as illustrated in FIG. 9B, the source/drain region 210 that is coupled with the capacitor structure 216 through the interconnection structure 214 may be located directly over the gate structure 204, and the memory cell structure 902 may further include a plurality of source/drain regions 208a and 210b located above and adjacent to opposing sides of the gate structure 204. Thus, a first channel in the channel layer 206 of the transistor structure 252 is located between the source/drain region 208a and the source/drain region 210, and a second channel in the channel layer 206 of the transistor structure 252 is located between the source/drain region 208b and the source/drain region 210. The source/drain regions 208a and 210b may each be electrically coupled and/or physically coupled with the same bit line conductive structure 218, or may be electrically coupled and/or physically coupled with different bit line conductive structures 218.

The dual-channel configuration of the transistor structure 252 of the memory cell structure 902 enables an increased on current (e.g., approximately double the on current) to be achieved for the memory cell structure 902 relative to the memory cell structure 502. However, the memory cell structure 502 may offer reduced manufacturing complexity and increased memory cell density relative to the memory cell structure 902.

As indicated above, FIGS. 9A-9C are provided as an example. Other examples may differ from what is described with regard to FIGS. 9A-9C.

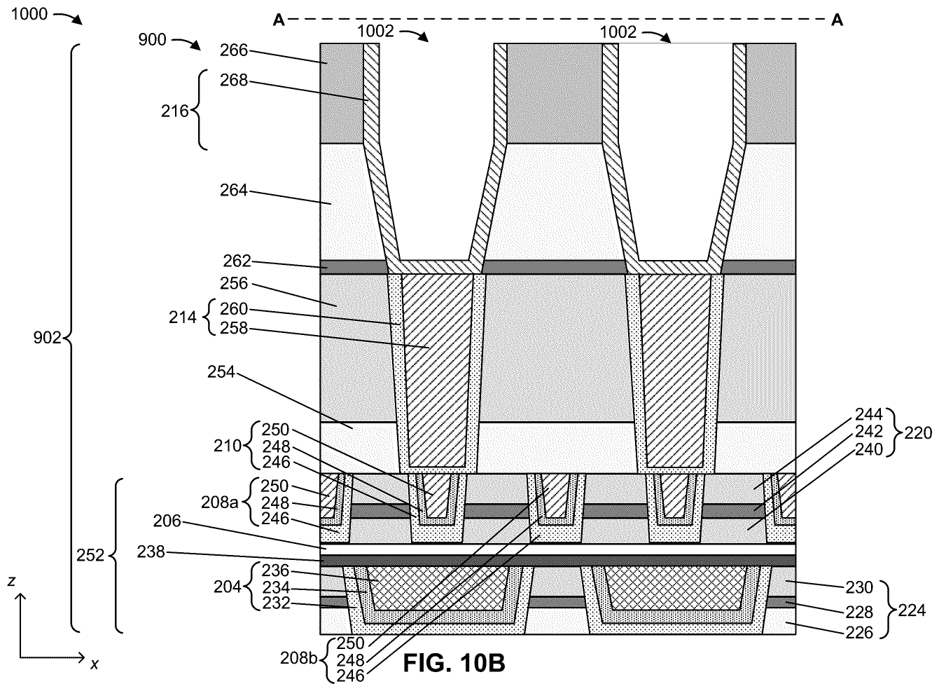

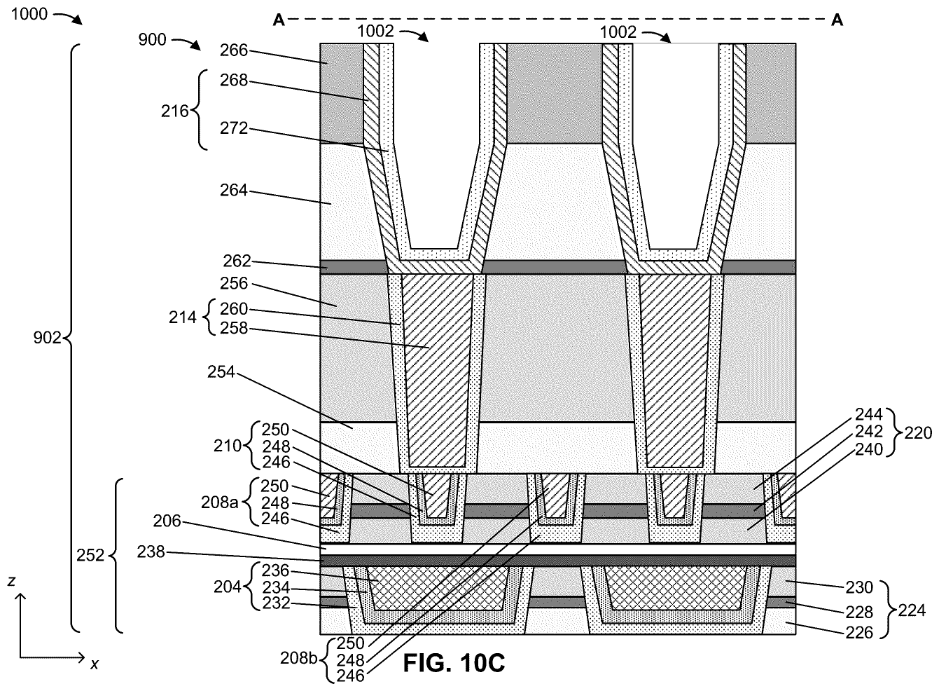

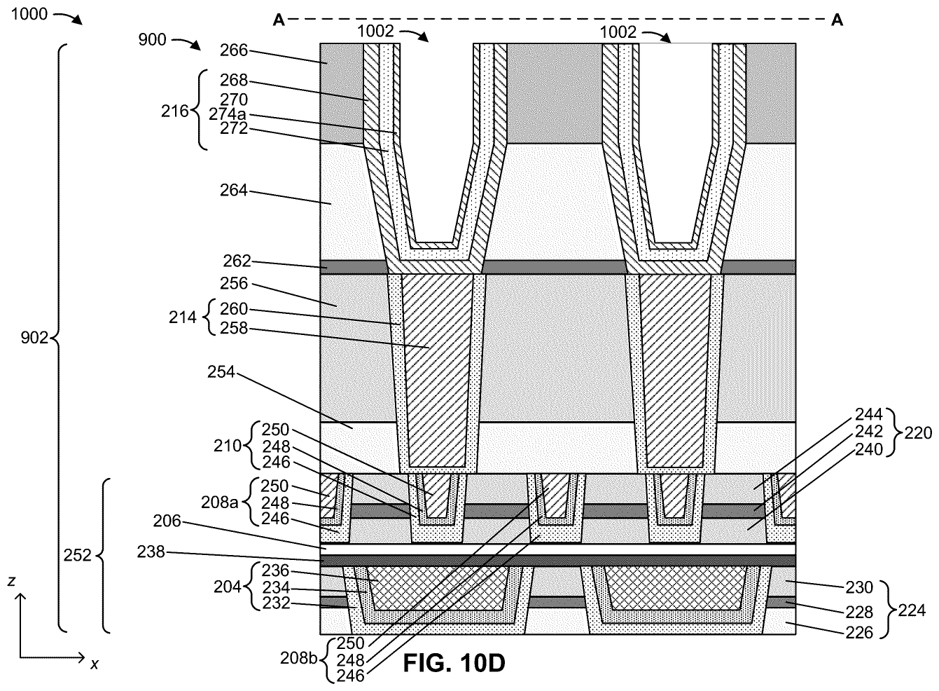

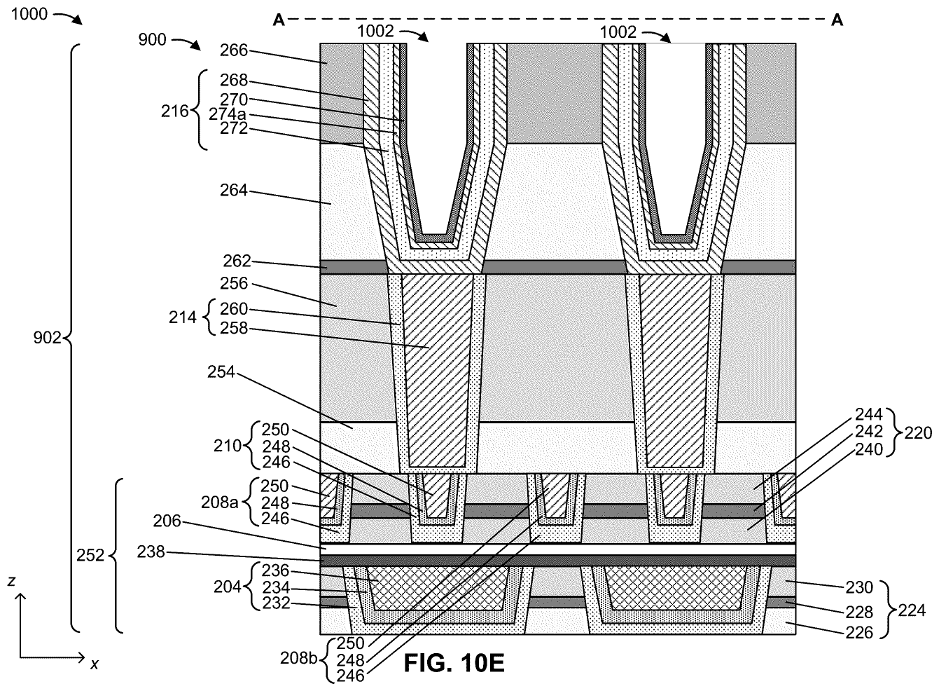

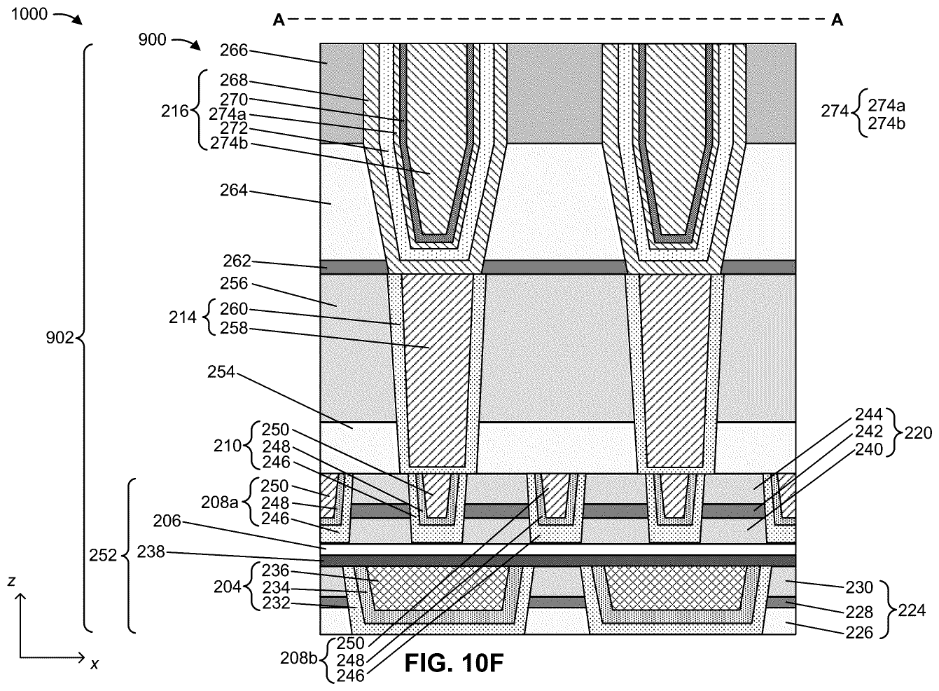

FIGS. 10A-10F are diagrams of an example implementation 1000 of forming a memory cell structure 902 of the semiconductor device 900 described herein. In some implementations, one or more of the processing operations described in connection with FIGS. 10A-10F may be performed using one or more of the semiconductor processing tools 102-112 and/or the wafer/die transport tool 114. In some implementations, one or more of the processing operations described in connection with FIGS. 10A-10F may be performed using another semiconductor processing tool not shown in FIG. 1.

As shown in FIG. 10A, one or more semiconductor processing operations described in connection with FIGS. 4A-4M and/or 8A-8H may be performed to form components 204-214 and 218-266 of the memory cell structure 902 of the semiconductor device 900. As further shown in FIG. 10A, a recess 1002 is formed through the ESL 262, the passivation layer 264, and/or the isolation layer 266. The recess 1002 may be formed over the interconnect structure 214 such that the top surface of the interconnect structure 214 is exposed through the recess 1002.

As shown in FIG. 10B, the bottom electrode 268 of the capacitor structure 216 of the memory cell structure 902 may be formed in the recess 1002. In particular, the bottom electrode 268 may be conformally deposited on the sidewalls and on the bottom surface of the recess 1002 such that the bottom electrode 268 conforms to the shape or profile of the recess 1002. The bottom surface of the recess 1002 may correspond to the top surface of the interconnect structure 214. Accordingly, the bottom electrode 268 is deposited on the top surface of the interconnect structure 214. A deposition tool 102 and/or a plating tool 112 may be used to deposit the bottom electrode 268 using a CVD technique, a PVD technique, an ALD technique, an electroplating technique, another deposition technique described above in connection with FIG. 1, and/or a deposition technique other than as described above in connection with FIG. 1.

As shown in FIG. 10C, the dielectric layer 272 of the capacitor structure 216 of the memory cell structure 902 may be formed over and/or on the bottom electrode 268. In particular, the dielectric layer 272 may be conformally deposited over the sidewalls and over the bottom surface of the recess 1002 such that the dielectric layer 272 conforms to the shape or profile of the recess 1002. A deposition tool 102 and/or a plating tool 112 may be used to deposit the dielectric layer 272 using a CVD technique, a PVD technique, an ALD technique, an oxidation technique, another deposition technique described above in connection with FIG. 1, and/or a deposition technique other than as described above in connection with FIG. 1.

As shown in FIG. 10D, the first top electrode layer 274a of the top electrode 274 of the capacitor structure 216 may be formed over and/or on the dielectric layer 272 in the recess 1002. In particular, the first top electrode layer 274a may be conformally deposited over the sidewalls and over the bottom surface of the recess 1002 such that the first top electrode layer 274a conforms to the shape or profile of the recess 1002. A deposition tool 102 and/or a plating tool 112 may be used to deposit the first top electrode layer 274a using a CVD technique, a PVD technique, an ALD technique, an electroplating technique, another deposition technique described above in connection with FIG. 1, and/or a deposition technique other than as described above in connection with FIG. 1.

As shown in FIG. 10E, the hydrogen absorption layer 270 of the capacitor structure 216 of the memory cell structure 902 may be formed over and/or on the first top electrode layer 274a. In particular, the hydrogen absorption layer 270 may be conformally deposited over the sidewalls and over the bottom surface of the recess 1002 such that the hydrogen absorption layer 270 conforms to the shape or profile of the recess 1002. A deposition tool 102 and/or a plating tool 112 may be used to deposit the second bottom electrode layer 268b using a CVD technique, a PVD technique, an ALD technique, an oxidation technique, another deposition technique described above in connection with FIG. 1, and/or a deposition technique other than as described above in connection with FIG. 1.

As shown in FIG. 10F, the second top electrode layer 274b of the top electrode 274 of the capacitor structure 216 may be formed over and/or on the hydrogen absorption layer 270 in the recess 1002. In particular, the second bottom electrode layer 268b may be deposited to fill the remaining volume in the recess 1002. A deposition tool 102 and/or a plating tool 112 may be used to deposit the second top electrode layer 274b using a CVD technique, a PVD technique, an ALD technique, an electroplating technique, another deposition technique described above in connection with FIG. 1, and/or a deposition technique other than as described above in connection with FIG. 1.

In some implementations, a planarization tool 110 may be used to planarize the bottom electrode 268, the hydrogen absorption layer 270, the dielectric layer 272, the first top electrode layer 274a, and/or the second top electrode layer 274b. In some implementations, the bottom electrode 268, the hydrogen absorption layer 270, the dielectric layer 272, the first top electrode layer 274a, and/or the second top electrode layer 274b are deposited over the top surface of the isolation layer 266, and the planarization tool 110 is used to remove the excess material from the top surface of the isolation layer 266.

Subsequent semiconductor processing operations may be performed for forming layers and/or structures in the semiconductor device 900 after formation of the capacitor structure 216. For example, additional dielectric layers and/or additional metallization layers may be formed above the capacitor structure 216. The subsequent semiconductor processing operations may involve the use of hydrogen (e.g., as a carrier gas, as a purge gas, as an element of a deposited material) and/or heat treatment, either of which can cause hydrogen to diffuse down into the memory cell structure 902 and contaminate the channel layer 206 of the transistor structure 252, which can lead to degraded performance and/or failure of the memory cell structure 902. However, the hydrogen absorption layer 270 in the capacitor structure 216 instead absorbs the hydrogen, thereby blocking, minimizing, and/or reducing the likelihood of the hydrogen diffusing past the capacitor structure 216 and into the transistor structure 252. In this way, the hydrogen absorption layer 270 of the capacitor structure 216 may minimize and/or reduce the likelihood of contamination of the channel layer 206, which may minimize and/or reduce the likelihood of degraded performance and/or failure of the memory cell structure 902.

As indicated above, FIGS. 10A-10F are provided as an example. Other examples may differ from what is described with regard to FIGS. 10A-10F.

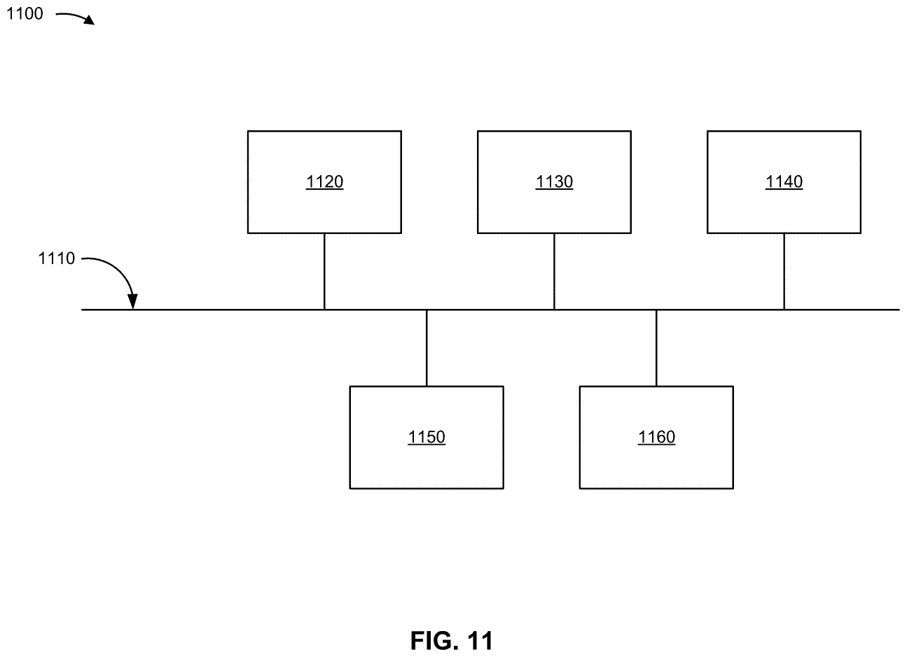

FIG. 11 is a diagram of example components of a device 1100 described herein. In some implementations, one or more of the semiconductor processing tools 102-112 and/or the wafer/die transport tool 114 may include one or more devices 1100 and/or one or more components of the device 1100. As shown in FIG. 11, the device 1100 may include a bus 1110, a processor 1120, a memory 1130, an input component 1140, an output component 1150, and/or a communication component 1160.

The bus 1110 may include one or more components that enable wired and/or wireless communication among the components of the device 1100. The bus 1110 may couple together two or more components of FIG. 11, such as via operative coupling, communicative coupling, electronic coupling, and/or electric coupling. For example, the bus 1110 may include an electrical connection (e.g., a wire, a trace, and/or a lead) and/or a wireless bus. The processor 1120 may include a central processing unit, a graphics processing unit, a microprocessor, a controller, a microcontroller, a digital signal processor, a field-programmable gate array, an application-specific integrated circuit, and/or another type of processing component. The processor 1120 may be implemented in hardware, firmware, or a combination of hardware and software. In some implementations, the processor 1120 may include one or more processors capable of being programmed to perform one or more operations or processes described elsewhere herein.

The memory 1130 may include volatile and/or nonvolatile memory. For example, the memory 1130 may include random access memory (RAM), read only memory (ROM), a hard disk drive, and/or another type of memory (e.g., a flash memory, a magnetic memory, and/or an optical memory). The memory 1130 may include internal memory (e.g., RAM, ROM, or a hard disk drive) and/or removable memory (e.g., removable via a universal serial bus connection). The memory 1130 may be a non-transitory computer-readable medium. The memory 1130 may store information, one or more instructions, and/or software (e.g., one or more software applications) related to the operation of the device 1100. In some implementations, the memory 1130 may include one or more memories that are coupled (e.g., communicatively coupled) to one or more processors (e.g., processor 1120), such as via the bus 1110. Communicative coupling between a processor 1120 and a memory 1130 may enable the processor 1120 to read and/or process information stored in the memory 1130 and/or to store information in the memory 1130.

The input component 1140 may enable the device 1100 to receive input, such as user input and/or sensed input. For example, the input component 1140 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1150 may enable the device 1100 to provide output, such as via a display, a speaker, and/or a light-emitting diode. The communication component 1160 may enable the device 1100 to communicate with other devices via a wired connection and/or a wireless connection. For example, the communication component 1160 may include a receiver, a transmitter, a transceiver, a modem, a network interface card, and/or an antenna.

The device 1100 may perform one or more operations or processes described herein. For example, a non-transitory computer-readable medium (e.g., memory 1130) may store a set of instructions (e.g., one or more instructions or code) for execution by the processor 1120. The processor 1120 may execute the set of instructions to perform one or more operations or processes described herein. In some implementations, execution of the set of instructions, by one or more processors 1120, causes the one or more processors 1120 and/or the device 1100 to perform one or more operations or processes described herein. In some implementations, hardwired circuitry may be used instead of or in combination with the instructions to perform one or more operations or processes described herein. Additionally, or alternatively, the processor 1120 may be configured to perform one or more operations or processes described herein. Thus, implementations described herein are not limited to any specific combination of hardware circuitry and software.

The number and arrangement of components shown in FIG. 11 are provided as an example. The device 1100 may include additional components, fewer components, different components, or differently arranged components than those shown in FIG. 11. Additionally, or alternatively, a set of components (e.g., one or more components) of the device 1100 may perform one or more functions described as being performed by another set of components of the device 1100.

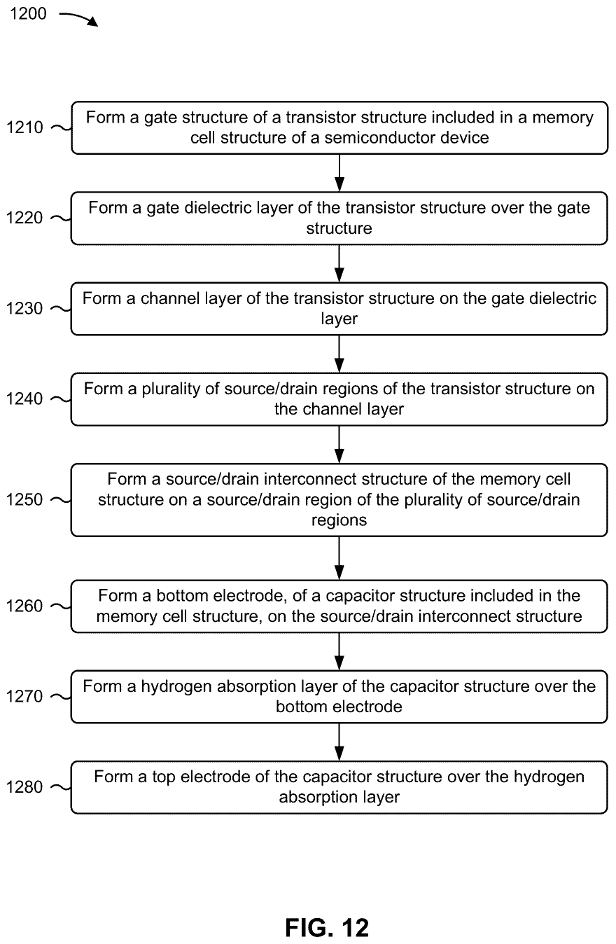

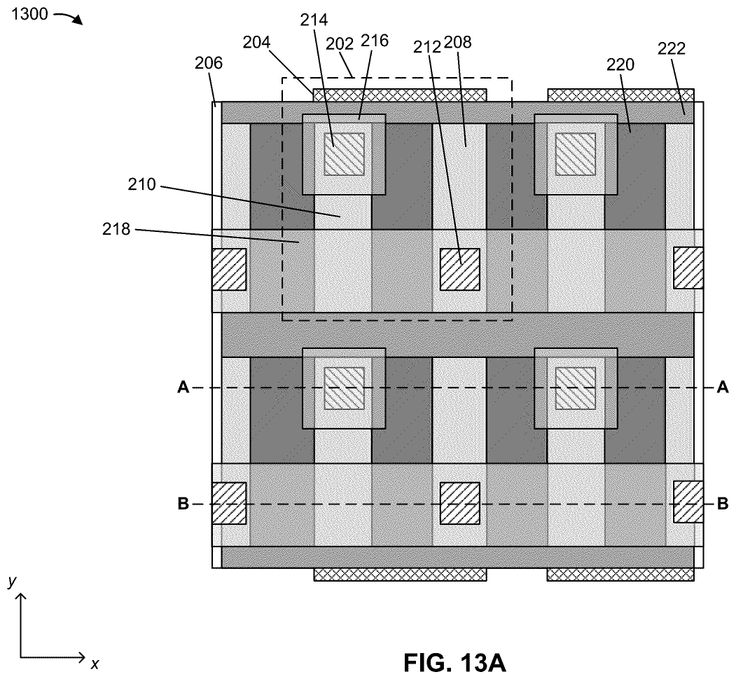

FIG. 12 is a flowchart of an example process 1200 associated with forming a memory cell structure described herein. In some implementations, one or more process blocks of FIG. 12 are performed using one or more semiconductor processing tools (e.g., one or more of the semiconductor processing tools 102-112). Additionally, or alternatively, one or more process blocks of FIG. 12 may be performed using one or more components of device 1100, such as processor 1120, memory 1130, input component 1140, output component 1150, and/or communication component 1160.

As shown in FIG. 12, process 1200 may include forming a gate structure of a transistor structure included in a memory cell structure of a semiconductor device (block 1210). For example, one or more of the semiconductor processing tools 102-112 may be used to form a gate structure 204 of a transistor structure 252 included in a memory cell structure (e.g., a memory cell structure 202, a memory cell structure 502, a memory cell structure 702, a memory cell structure 902) of a semiconductor device (e.g., a semiconductor device 200, a semiconductor device 500, a semiconductor device 700, a semiconductor device 900), as described herein.

As further shown in FIG. 12, process 1200 may include forming a gate dielectric layer of the transistor structure over the gate structure (block 1220). For example, one or more of the semiconductor processing tools 102-112 may be used to form a gate dielectric layer 238 of the transistor structure 252 over the gate structure 204, as described herein.

As further shown in FIG. 12, process 1200 may include forming a channel layer of the transistor structure on the gate dielectric layer (block 1230). For example, one or more of the semiconductor processing tools 102-112 may be used to form a channel layer 206 of the transistor structure 252 on the gate dielectric layer 238, as described herein.

As further shown in FIG. 12, process 1200 may include forming a plurality of source/drain regions of the transistor structure on the channel layer (block 1240). For example, one or more of the semiconductor processing tools 102-112 may be used to form a plurality of source/drain regions 208 and 210 of the transistor structure 252 on the channel layer 206, as described herein.

As further shown in FIG. 12, process 1200 may include forming a source/drain interconnect structure of the memory cell structure on a source/drain region of the plurality of source/drain regions (block 1250). For example, one or more of the semiconductor processing tools 102-112 may be used to form a source/drain interconnect structure (e.g., an interconnect structure 214) of the memory cell structure on a source/drain region 210 of the plurality of source/drain regions, as described herein.

As further shown in FIG. 12, process 1200 may include forming a bottom electrode, of a capacitor structure included in the memory cell structure, on the source/drain interconnect structure (block 1260). For example, one or more of the semiconductor processing tools 102-112 may be used to form a bottom electrode 268, of a capacitor structure 216 included in the memory cell structure, on the source/drain interconnect structure, as described herein.

As further shown in FIG. 12, process 1200 may include forming a hydrogen absorption layer of the capacitor structure over the bottom electrode (block 1270). For example, one or more of the semiconductor processing tools 102-112 may be used to form a hydrogen absorption layer 270 of the capacitor structure 216 over the bottom electrode 268, as described herein.

As further shown in FIG. 12, process 1200 may include forming a top electrode of the capacitor structure over the hydrogen absorption layer (block 1280). For example, one or more of the semiconductor processing tools 102-112 may be used to form a top electrode 274 of the capacitor structure over the hydrogen absorption layer 270, as described herein.

Process 1200 may include additional implementations, such as any single implementation or any combination of implementations described below and/or in connection with one or more other processes described elsewhere herein.

In a first implementation, forming the bottom electrode 268 includes forming a first bottom electrode layer 268a of the bottom electrode 268 on the source/drain interconnect structure, where forming the hydrogen absorption layer 270 includes forming the hydrogen absorption layer 270 on the first bottom electrode layer 268a, where forming the bottom electrode 268 includes forming a second bottom electrode layer 268b of the bottom electrode 268 on the hydrogen absorption layer 270, and where the process 1200 includes forming a high-k dielectric layer (e.g., a dielectric layer 272) on the second bottom electrode layer 268b, and where forming the top electrode 274 includes forming the top electrode 274 on the high-k dielectric layer.

In a second implementation, alone or in combination with the first implementation, forming the hydrogen absorption layer 270 includes forming the hydrogen absorption layer 270 of a metal-oxide material.

In a third implementation, alone or in combination with one or more of the first and second implementations, the hydrogen absorption layer 270 absorbs hydrogen in the semiconductor device during formation of one or more subsequent layers of the semiconductor device.

In a fourth implementation, alone or in combination with one or more of the first through third implementations, the metal-oxide material includes at least one of an indium oxide (InₓO_{y}), a titanium oxide (TiOₓ), an indium tin oxide (ITO), a cerium oxide (CeOₓ), a zinc oxide (ZnO), or an indium gallium zinc oxide (IGZO).

In a fifth implementation, alone or in combination with one or more of the first through fourth implementations, process 1200 includes forming a high-k dielectric layer (e.g., a dielectric layer 272) on the bottom electrode 268, where forming the top electrode 274 includes forming a first top electrode layer 274a of the top electrode 274 on the high-k dielectric layer, where forming the hydrogen absorption layer 270 includes forming the hydrogen absorption layer 270 on the first top electrode layer 274a, and where forming the top electrode 274 includes forming a second top electrode layer 274b of the top electrode 274 on the hydrogen absorption layer 270.

In a sixth implementation, alone or in combination with one or more of the first through fifth implementations, forming the hydrogen absorption layer 270 includes forming the hydrogen absorption layer 270 to a thickness that is included in a range of approximately 1 nanometer to approximately 100 nanometers.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

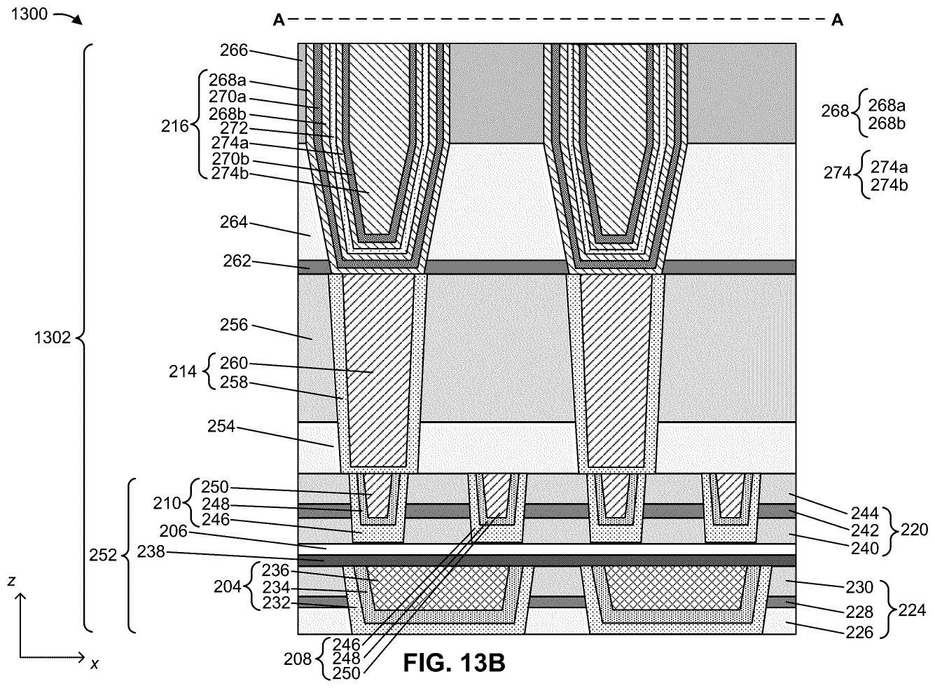

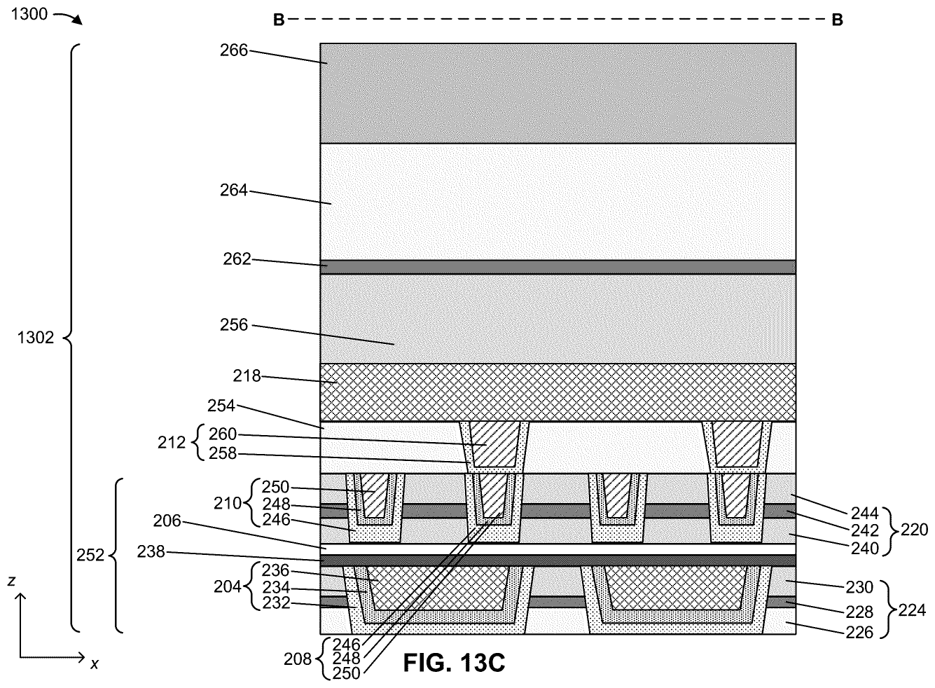

FIGS. 13A-13C are diagrams of an example semiconductor device 1300 described herein. As shown in FIGS. 13A-13C, the semiconductor device 1300 may include a memory array that includes a plurality of memory cell structures 1302. The memory array may be included in one or more back end dielectric layers (e.g., BEOL dielectric layers) in the BEOL region of the semiconductor device 1300. The memory cell structures 1302 may include volatile memory structures, such as DRAM memory structures and/or another type of volatile memory structures.

As further shown in FIGS. 13A-13C, a memory cell structure 1302 may include a similar combination and arrangement of components 204-276 as the memory cell structure 202. However, the memory cell structure 1302 includes a plurality of hydrogen absorption layers, including a hydrogen absorption layer 270a between a first bottom electrode 268a and a second bottom electrode 268b, and another hydrogen absorption layer 270b between a first top electrode layer 274a and a second top electrode layer 274b of the top electrode. Thus, the capacitor structure 216 of the memory cell structure 1302 may include a first bottom electrode 268a, a first hydrogen absorption layer 270a on the first bottom electrode 268a, a second bottom electrode 268b on the first hydrogen absorption layer 270a, a dielectric layer 272 between the second bottom electrode 268b and a first top electrode layer 274a, and the hydrogen absorption layer 270b between the first top electrode layer 274a and the second top electrode layer 274b. Including multiple hydrogen absorption layers in the memory cell structure 1302 may further enhance the hydrogen absorption in the capacitor structure 216 of the memory cell structure 1302.

As indicated above, FIGS. 13A-13C are provided as an example. Other examples may differ from what is described with regard to FIGS. 13A-13C.

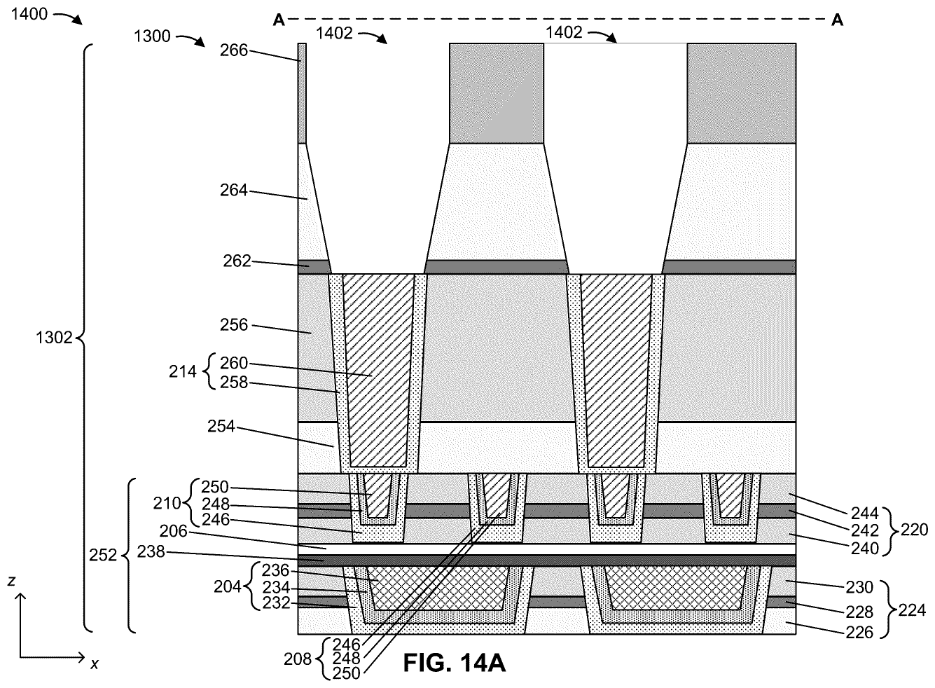

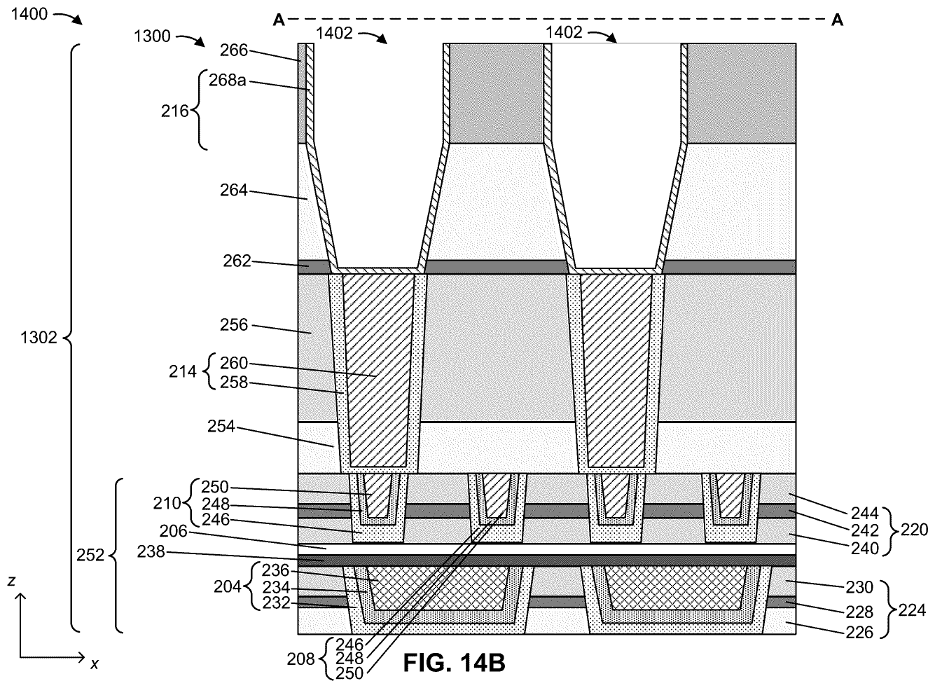

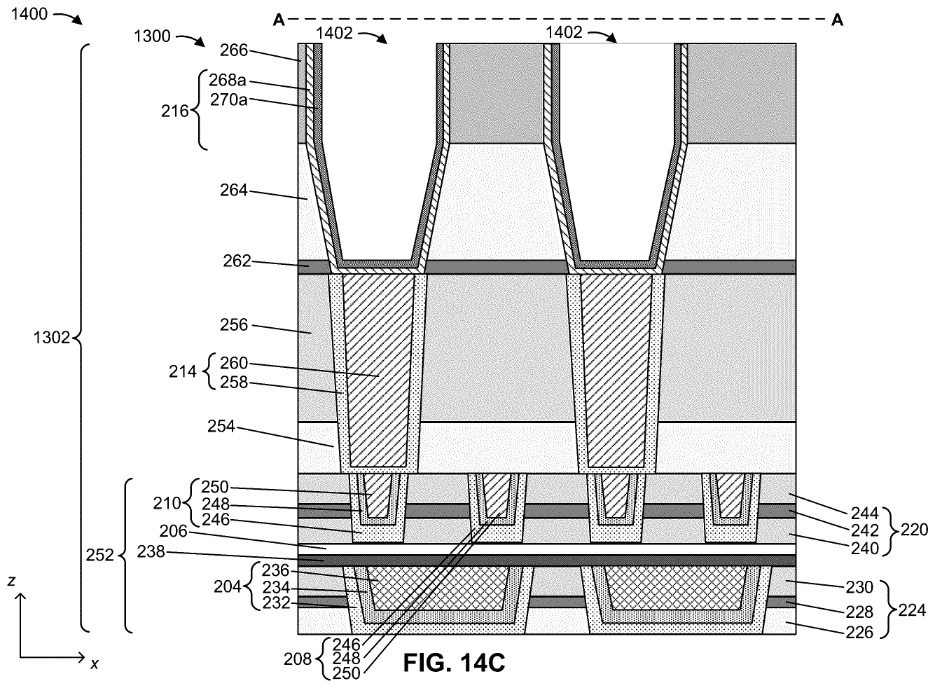

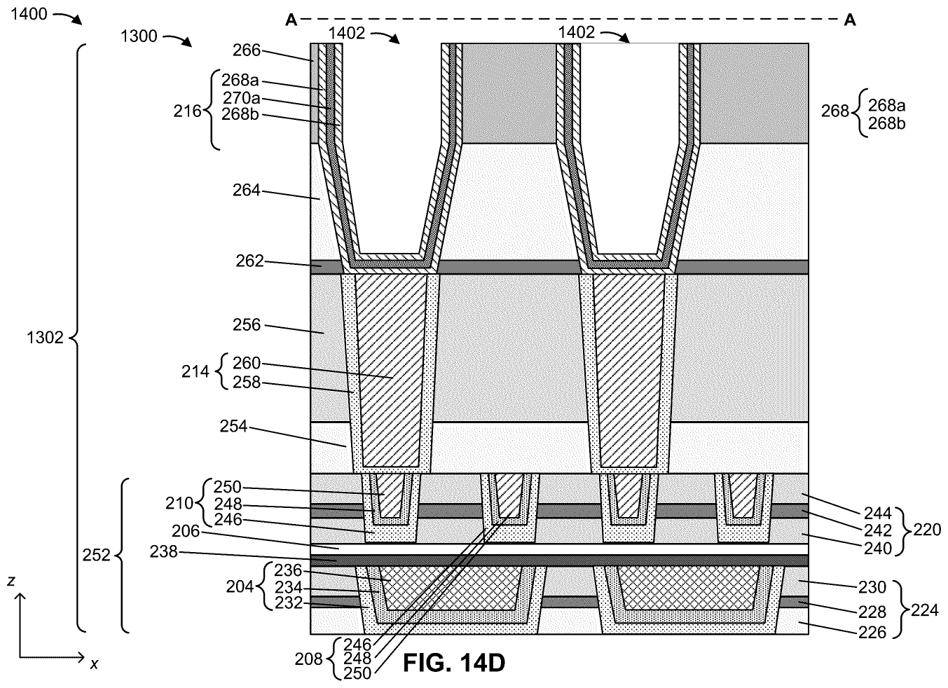

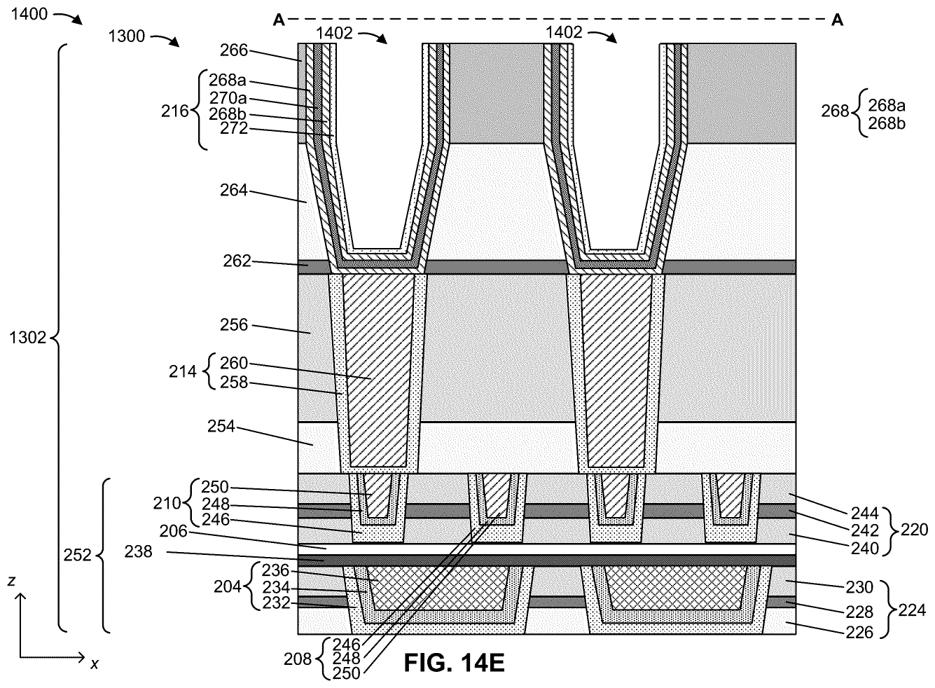

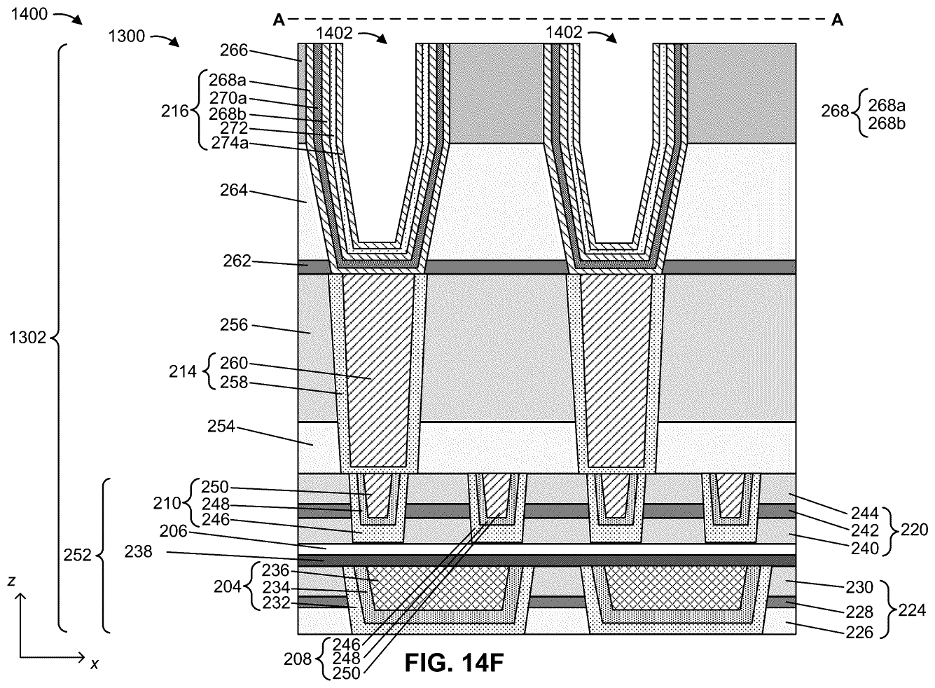

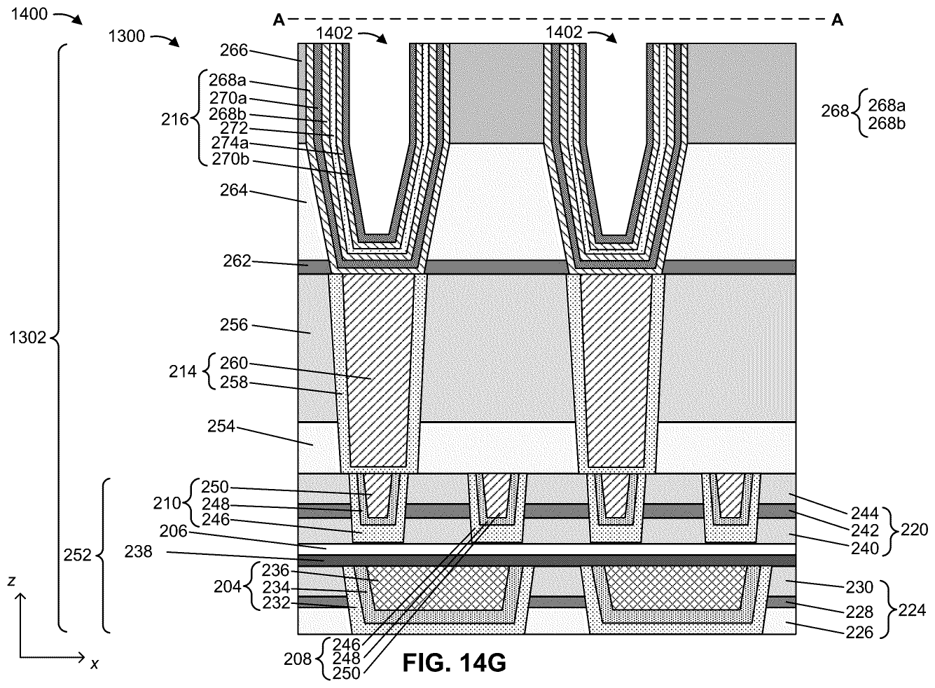

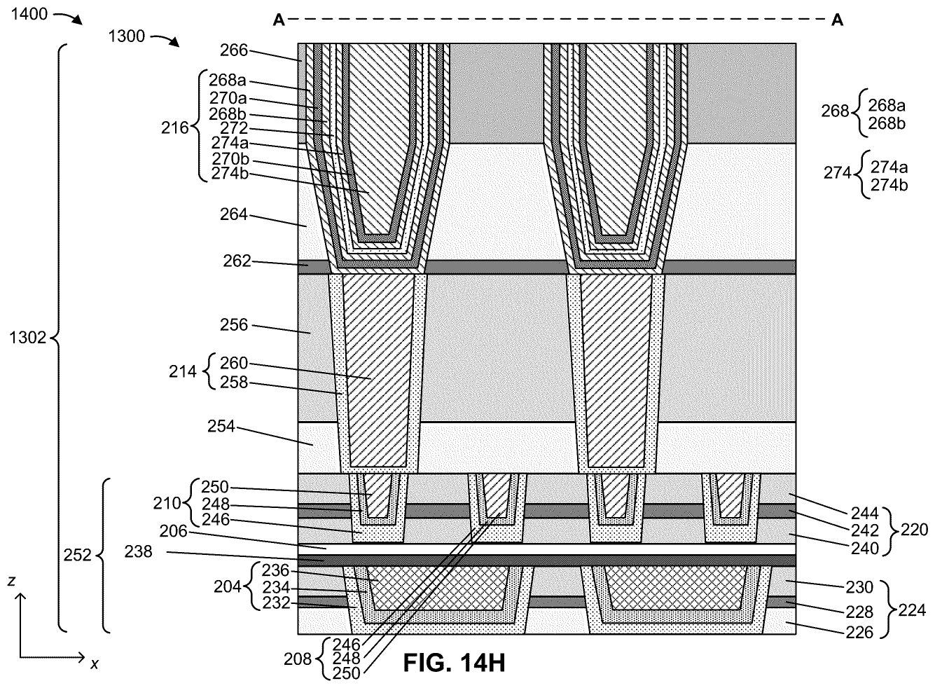

FIGS. 14A-14H are diagrams of an example implementation 1400 of forming a memory cell structure 1302 of the semiconductor device 1300 described herein. In some implementations, one or more of the processing operations described in connection with FIGS. 14A-14H may be performed using one or more of the semiconductor processing tools 102-112 and/or the wafer/die transport tool 114. In some implementations, one or more of the processing operations described in connection with FIGS. 14A-14H may be performed using another semiconductor processing tool not shown in FIG. 1.

As shown in FIG. 14A, one or more semiconductor processing operations described in connection with FIGS. 4A-4M may be performed to form components 204-214 and 218-266 of the memory cell structure 1302 of the semiconductor device 1300. As further shown in FIG. 14A, a recess 1402 is formed through the ESL 262, the passivation layer 264, and/or the isolation layer 266. The recess 1402 may be formed over the interconnect structure 214 such that the top surface of the interconnect structure 214 is exposed through the recess 1402.

As shown in FIG. 14B, the first bottom electrode 268a of the capacitor structure 216 of the memory cell structure 1302 may be formed in the recess 1402. In particular, the first bottom electrode 268a may be conformally deposited on the sidewalls and on the bottom surface of the recess 1402 such that the first bottom electrode 268a conforms to the shape or profile of the recess 1402. The bottom surface of the recess 1402 may correspond to the top surface of the interconnect structure 214. Accordingly, the first bottom electrode 268a is deposited on the top surface of the interconnect structure 214. A deposition tool 102 and/or a plating tool 112 may be used to deposit the first bottom electrode 268a using a CVD technique, a PVD technique, an ALD technique, an electroplating technique, another deposition technique described above in connection with FIG. 1, and/or a deposition technique other than as described above in connection with FIG. 1.

As shown in FIG. 14C, the hydrogen absorption layer 270a of the capacitor structure 216 of the memory cell structure 1302 may be formed over and/or on the first bottom electrode layer 268a. In particular, the hydrogen absorption layer 270a may be conformally deposited over the sidewalls and over the bottom surface of the recess 1402 such that the hydrogen absorption layer 270a conforms to the shape or profile of the recess 1402. A deposition tool 102 and/or a plating tool 112 may be used to deposit the hydrogen absorption layer 270a using a CVD technique, a PVD technique, an ALD technique, an oxidation technique, another deposition technique described above in connection with FIG. 1, and/or a deposition technique other than as described above in connection with FIG. 1.

As shown in FIG. 14D, the second bottom electrode layer 268b of the bottom electrode 268 of the capacitor structure 216 may be formed over and/or on the hydrogen absorption layer 270a in the recess 1402. A deposition tool 102 and/or a plating tool 112 may be used to deposit the second bottom electrode layer 268b using a CVD technique, a PVD technique, an ALD technique, an electroplating technique, another deposition technique described above in connection with FIG. 1, and/or a deposition technique other than as described above in connection with FIG. 1.

As shown in FIG. 14E, the dielectric layer 272 of the capacitor structure 216 of the memory cell structure 1302 may be formed over and/or on the second bottom electrode layer 268b. In particular, the dielectric layer 272 may be conformally deposited over the sidewalls and over the bottom surface of the recess 1402 such that the dielectric layer 272 conforms to the shape or profile of the recess 1402. A deposition tool 102 and/or a plating tool 112 may be used to deposit the dielectric layer 272 using a CVD technique, a PVD technique, an ALD technique, an oxidation technique, another deposition technique described above in connection with FIG. 1, and/or a deposition technique other than as described above in connection with FIG. 1.

As shown in FIG. 14F, the first top electrode layer 274a of the top electrode 274 of the capacitor structure 216 may be formed over and/or on the dielectric layer 272 in the recess 1402. In particular, the first top electrode layer 274a may be conformally deposited over the sidewalls and over the bottom surface of the recess 1402 such that the first top electrode layer 274a conforms to the shape or profile of the recess 1402. A deposition tool 102 and/or a plating tool 112 may be used to deposit the first top electrode layer 274a using a CVD technique, a PVD technique, an ALD technique, an electroplating technique, another deposition technique described above in connection with FIG. 1, and/or a deposition technique other than as described above in connection with FIG. 1.

As shown in FIG. 14G, the hydrogen absorption layer 270b of the capacitor structure 216 of the memory cell structure 502 may be formed over and/or on the first top electrode layer 274a. In particular, the hydrogen absorption layer 270b may be conformally deposited over the sidewalls and over the bottom surface of the recess 1402 such that the hydrogen absorption layer 270 conforms to the shape or profile of the recess 1402. A deposition tool 102 and/or a plating tool 112 may be used to deposit the hydrogen absorption layer 270b using a CVD technique, a PVD technique, an ALD technique, an oxidation technique, another deposition technique described above in connection with FIG. 1, and/or a deposition technique other than as described above in connection with FIG. 1.

As shown in FIG. 14H, the second top electrode layer 274b of the top electrode 274 of the capacitor structure 216 may be formed over and/or on the hydrogen absorption layer 270b in the recess 1402. In particular, the second bottom electrode layer 268b may be deposited to fill the remaining volume in the recess 1402. A deposition tool 102 and/or a plating tool 112 may be used to deposit the second top electrode layer 274b using a CVD technique, a PVD technique, an ALD technique, an electroplating technique, another deposition technique described above in connection with FIG. 1, and/or a deposition technique other than as described above in connection with FIG. 1.

In some implementations, a planarization tool 110 may be used to planarize the first bottom electrode 268a, the hydrogen absorption layer 270a, the second bottom electrode 268b, the dielectric layer 272, the first top electrode layer 274a, the hydrogen absorption layer 270b, and/or the second top electrode layer 274b. In some implementations, the first bottom electrode 268a, the hydrogen absorption layer 270a, the second bottom electrode 268b, the dielectric layer 272, the first top electrode layer 274a, the hydrogen absorption layer 270b, and/or the second top electrode layer 274b are deposited over the top surface of the isolation layer 266, and the planarization tool 110 is used to remove the excess material from the top surface of the isolation layer 266.

Subsequent semiconductor processing operations may be performed for forming layers and/or structures in the semiconductor device 1300 after formation of the capacitor structure 216. For example, additional dielectric layers and/or additional metallization layers may be formed above the capacitor structure 216. The subsequent semiconductor processing operations may involve the use of hydrogen (e.g., as a carrier gas, as a purge gas, as an element of a deposited material) and/or heat treatment, either of which can cause hydrogen to diffuse down into the memory cell structure 1302 and contaminate the channel layer 206 of the transistor structure 252, which can lead to degraded performance and/or failure of the memory cell structure 1302. However, the hydrogen absorption layers 270a and 270b in the capacitor structure 216 instead absorbs the hydrogen, thereby blocking, minimizing, and/or reducing the likelihood of the hydrogen diffusing past the capacitor structure 216 and into the transistor structure 252. In this way, the hydrogen absorption layers 270a and 270b of the capacitor structure 216 may minimize and/or reduce the likelihood of contamination of the channel layer 206, which may minimize and/or reduce the likelihood of degraded performance and/or failure of the memory cell structure 1302.

As indicated above, FIGS. 14A-14H are provided as an example. Other examples may differ from what is described with regard to FIGS. 14A-14H.

In this way, a memory cell structure includes a transistor structure and a capacitor structure, where the capacitor structure includes a hydrogen absorption layer. The hydrogen absorption layer absorbs hydrogen such as atmospheric hydrogen and/or hydrogen that is used in various types of deposition processes. The hydrogen absorption layer absorbs the hydrogen, which prevents or reduces the likelihood of the hydrogen diffusing into the underlying metal-oxide channel of the transistor structure. In this way, the hydrogen absorption layer minimizes and/or reduces the likelihood of hydrogen contamination in the metal-oxide channel, which may enable a low current leakage to be achieved for the memory cell structure and reduces the likelihood of data corruption and/or failure of the memory cell structure, among other examples.

As described in greater detail above, some implementations described herein provide a semiconductor device. The semiconductor device includes a plurality of back end dielectric layers. The semiconductor device includes a memory cell structure, in the plurality of back end dielectric layers, comprising, a transistor structure a capacitor structure, above the transistor structure, comprising: a first bottom electrode layer a second bottom electrode layer over the first bottom electrode layer a hydrogen absorption layer between the first bottom electrode layer and the second bottom electrode layer a dielectric layer over the second bottom electrode layer a top electrode layer over the dielectric layer.

As described in greater detail above, some implementations described herein provide a semiconductor device. The semiconductor device includes a plurality of back end dielectric layers. The semiconductor device includes a memory cell structure, in the plurality of back end dielectric layers, comprising, a transistor structure a capacitor structure, above the transistor structure, comprising: a bottom electrode layer a dielectric layer over the bottom electrode layer a first top electrode layer over the dielectric layer a second top electrode layer over the first top electrode layer a hydrogen absorption layer between the first top electrode layer and the second top electrode layer.

As described in greater detail above, some implementations described herein provide a method. The method includes forming a gate structure of a transistor structure included in a memory cell structure of a semiconductor device. The method includes forming a gate dielectric layer of the transistor structure over the gate structure. The method includes forming a channel layer of the transistor structure on the gate dielectric layer. The method includes forming a plurality of source/drain regions of the transistor structure on the channel layer. The method includes forming a source/drain interconnect structure of the memory cell structure on a source/drain region of the plurality of source/drain regions. The method includes forming a bottom electrode, of a capacitor structure included in the memory cell structure, on the source/drain interconnect structure. The method includes forming a hydrogen absorption layer of the capacitor structure over the bottom electrode. The method includes forming a top electrode of the capacitor structure over the hydrogen absorption layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of back end dielectric layers; and
a memory cell structure, in the plurality of back end dielectric layers, comprising:
a transistor structure; and
a capacitor structure, above the transistor structure, comprising:
a first bottom electrode layer;
a second bottom electrode layer over the first bottom electrode layer;
a hydrogen absorption layer between the first bottom electrode layer and
the second bottom electrode layer;
a dielectric layer over the second bottom electrode layer; and
a top electrode layer over the dielectric layer.

2. The semiconductor device of claim 1, wherein the hydrogen absorption layer comprises one or more metal-oxide materials.

3. The semiconductor device of claim 1, wherein the hydrogen absorption layer comprises at least one of:
an indium oxide (InₓO_{y}),
a titanium oxide (TiOₓ),
an indium tin oxide (ITO),
a cerium oxide (CeOₓ),
a zinc oxide (ZnO), or
an indium gallium zinc oxide (IGZO).

4. The semiconductor device of claim 1, wherein a thickness of the hydrogen absorption layer is included in a range of approximately 1 nanometer to approximately 100 nanometers.

5. The semiconductor device of claim 1, wherein the capacitor structure comprises a deep trench capacitor structure; and
wherein the hydrogen absorption layer conforms to a profile of the deep trench capacitor structure.

6. The semiconductor device of claim 1, wherein the transistor structure comprises a single-channel transistor structure that includes:
a gate structure;
a channel layer over the gate structure;
a first source/drain region on the channel layer and directly above the gate structure; and
a second source/drain region on the channel layer and directly above the gate structure.

7. The semiconductor device of claim 1, wherein the transistor structure comprises a dual-channel transistor structure that includes:
a gate structure;
a channel layer over the gate structure;
a first source/drain region on the channel layer and directly above the gate structure;
a second source/drain region on the channel layer above the gate structure,
wherein the second source/drain region is adjacent to a first side of the gate structure; and
a third source/drain region on the channel layer above the gate structure,
wherein the third source/drain region is adjacent to a second side of the gate structure opposing the first side.

8. A semiconductor device, comprising:
a plurality of back end dielectric layers; and
a memory cell structure, in the plurality of back end dielectric layers, comprising:
a transistor structure; and
a capacitor structure, above the transistor structure, comprising:
a bottom electrode layer;
a dielectric layer over the bottom electrode layer;
a first top electrode layer over the dielectric layer;
a second top electrode layer over the first top electrode layer; and
a hydrogen absorption layer between the first top electrode layer and the second top electrode layer.

9. The semiconductor device of claim 8, wherein the hydrogen absorption layer comprises one or more metal-oxide materials.

10. The semiconductor device of claim 8, wherein the hydrogen absorption layer comprises one or more metal-hydroxide materials.

11. The semiconductor device of claim 8, wherein the transistor structure comprises a single-channel transistor structure that includes:
a gate structure;
a channel layer over the gate structure;
a first source/drain region on the channel layer and directly above the gate structure; and
a second source/drain region on the channel layer and directly above the gate structure.

12. The semiconductor device of claim 8, wherein the transistor structure comprises a dual-channel transistor structure that includes:
a gate structure;
a channel layer over the gate structure;
a first source/drain region on the channel layer and directly above the gate structure;
a second source/drain region on the channel layer above the gate structure,
wherein the second source/drain region is adjacent to a first side of the gate structure; and
a third source/drain region on the channel layer above the gate structure,
wherein the third source/drain region is adjacent to a second side of the gate structure opposing the first side.

13. The semiconductor device of claim 8, wherein a thickness of the hydrogen absorption layer is included in a range of approximately 1 nanometer to approximately 100 nanometers.

14. A method, comprising:
forming a gate structure of a transistor structure included in a memory cell structure of a semiconductor device;
forming a gate dielectric layer of the transistor structure over the gate structure;
forming a channel layer of the transistor structure on the gate dielectric layer;
forming a plurality of source/drain regions of the transistor structure on the channel layer;
forming a source/drain interconnect structure of the memory cell structure on a source/drain region of the plurality of source/drain regions;
forming a bottom electrode, of a capacitor structure included in the memory cell structure, on the source/drain interconnect structure;
forming a hydrogen absorption layer of the capacitor structure over the bottom electrode; and
forming a top electrode of the capacitor structure over the hydrogen absorption layer.

15. The method of claim 14, wherein forming the bottom electrode comprises:
forming a first bottom electrode layer of the bottom electrode on the source/drain interconnect structure;
wherein forming the hydrogen absorption layer comprises:
forming the hydrogen absorption layer on the first bottom electrode layer;
wherein forming the bottom electrode comprises:
forming a second bottom electrode layer of the bottom electrode on the hydrogen absorption layer;
wherein the method further comprises:
forming a high dielectric constant (high-k) dielectric layer on the second bottom electrode layer; and
wherein forming the top electrode comprises:
forming the top electrode on the high-k dielectric layer.

16. The method of claim 14, wherein forming the hydrogen absorption layer comprises:
forming the hydrogen absorption layer of a metal-oxide material.

17. The method of claim 16, wherein the hydrogen absorption layer absorbs hydrogen in the semiconductor device during formation of one or more subsequent layers of the semiconductor device.

18. The method of claim 16, wherein the metal-oxide material comprises at least one of:
an indium oxide (InₓO_{y}),
a titanium oxide (TiOₓ),
an indium tin oxide (ITO),
a cerium oxide (CeOₓ),
a zinc oxide (ZnO), or
an indium gallium zinc oxide (IGZO).

19. The method of claim 14, further comprising:
forming a high dielectric constant (high-k) dielectric layer on the bottom electrode,
wherein forming the top electrode comprises:
forming a first top electrode layer of the top electrode on the high-k dielectric layer;
wherein forming the hydrogen absorption layer comprises:
forming the hydrogen absorption layer on the first top electrode layer; and
wherein forming the top electrode comprises:
forming a second top electrode layer of the top electrode on the hydrogen absorption layer.

20. The method of claim 14, wherein forming the hydrogen absorption layer comprises:
forming the hydrogen absorption layer to a thickness that is included in a range of approximately 1 nanometer to approximately 100 nanometers.
